(19) United States
(12) Patent Application Publication
(10) Pub. No.: US 2015/0132539 A1
(43) Pub. Date: May 14, 2015

(54) Process for Applying a Friction Reducing Coating

(71) Applicants: Jeffrey R. Bailey, Houston, TX (US); Srinivasan Rajagopalan, Easton, PA (US); Mehmet Deniz Ertas, Bethlehem, PA (US); Adnan Ozekcin, Bethlehem, PA (US); Bo Zhao, Rochester, MI (US)

(72) Inventors: Jeffrey R. Bailey, Houston, TX (US); Srinivasan Rajagopalan, Easton, PA (US); Mehmet Deniz Ertas, Bethlehem, PA (US); Adnan Ozekcin, Bethlehem, PA (US); Bo Zhao, Rochester, MI (US)

(21) Appl. No.: 14/471,987

(22) Filed: Aug. 28, 2014

Related U.S. Application Data
(60) Provisional application No. 61/871,749, filed on Aug. 29, 2013.

(51) Int. Cl. B05D 5/08; B05D 1/32; C23C 16/27; C23C 16/02; C23C 16/50; C23C 14/02; C23C 4/12; C23C 16/48; B05D 1/38; C23C 4/02; C23C 8/02; B05D 3/12; C23C 14/48

(52) U.S. Cl. CPC B05D 5/08; B05D 3/12; B05D 1/32; C23C 16/27; C23C 16/0254; C23C 16/50; C23C 14/48; C23C 4/12; C23C 16/483; B05D 1/38; C23C 4/02; C23C 8/02; C23C 14/028
USPC 428/141; 427/290; 427/258; 427/249.14; 427/255.28; 427/569; 427/523; 427/446; 427/596; 427/249.7; 427/577; 205/80; 204/192.15; 428/143; 428/148

(57) ABSTRACT

A coated device comprising a body, a coating on at least a portion of a surface of the body, wherein the coating comprises, a terminal layer, and at least one underlayer positioned between the terminal layer and the body, the underlayer comprising a hardness of greater than 61 HRc, wherein prior to the addition of the terminal layer, at least one of the body and the underlayer is polished to a surface roughness of less than or equal to 1.0 micrometer Ra.

### CROSS-REFERENCE TO RELATED APPLICATIONS

This application claims benefit of U.S. Provisional Patent Application No. 61/871,749 filed Aug. 29, 2013 and incorporated by reference herein in its entirety.

### FIELD

The present disclosure relates to the field of metal and related tools and equipment used in friction-wear environments, such as, for example, the oil and gas well production, solids handling, heavy equipment, pumping equipment, and mining operations. It more particularly relates to processes for coating such equipment and tools to reduce friction, wear, corrosion, erosion, and/or deposits on oil and gas tools, excavation tools, surface mining devices and related equipment. Such coated devices may be used, for example in the oil and gas industry in well drilling tools, marine riser systems, tubular goods (casing, tubing, and drill strings), wellheads, valves, completion strings and equipment, completion tools, artificial lift equipment, well intervention equipment, rig equipment, and slurry handling equipment and facilities.

### BACKGROUND

Oil and gas well production and surface mining resource extraction operations suffer from basic mechanical problems that may be costly, or even prohibitive, to correct, repair, or mitigate. Friction is ubiquitous in these operations, devices that are in moving contact wear and lose their original dimensions, devices are degraded by erosion and corrosion, and deposits on devices can stick and impede their operation. These are all potential impediments to successful operations that may be mitigated by selective use of coatings. Manufacturing processes and specifications, as described below, will provide for coatings that yield maximum performance and longevity.

### Drilling Rig Equipment

Following the identification of a specific location as a prospective hydrocarbon area, production operations commence with the mobilization and operation of a drilling rig. In rotary drilling operations, a drill bit is attached to the end of a bottom hole assembly, which is attached to a drill string comprising drill pipe and tool joints. The drill string may be rotated at the surface by a rotary table or top drive unit, and the weight of the drill string and bottom hole assembly causes the rotating bit to bore a hole in the earth. As the operation progresses, new sections of drill pipe are added to the drill string to increase its overall length. Periodically during the drilling operation, the open borehole is cased to stabilize the walls, and the drilling operation is resumed. As a result, the drill string usually operates both in the open borehole (“open-hole”) and within the casing which has been installed in the borehole (“cased-hole”). Alternatively, coiled tubing may replace drill string in the drilling assembly. The combination of a drill string and bottom hole assembly or coiled tubing and bottom hole assembly is referred to herein as a drill stem assembly. Rotation of the drill string provides power through the drill string and bottom hole assembly to the bit. In coiled tubing drilling, power is delivered to the bit by the drilling fluid. The amount of power which can be transmitted by rotation is limited to the maximum torque a drill string or coiled tubing can sustain.

In an alternative and unusual drilling method, the casing itself is used to drill into the earth formations. Cutting elements are affixed to the bottom end of the casing, and the casing may be rotated to turn the cutting elements. In the discussion that follows, reference to the drill stem assembly will include a “drilling casing string” that is used to drill the earth formations in this “casing-while-drilling” method.

During the drilling of a borehole through underground formations, the drill stem assembly undergoes considerable sliding contact with both the steel casing and rock formations. This sliding contact results primarily from the rotational and axial movements of the drill stem assembly in the borehole. Friction between the moving surface of the drill stem assembly and the stationary surfaces of the casing and formation creates considerable drag on the drill stem and results in excessive torque and drag during drilling operations. The problem caused by friction is inherent in any drilling operation, but it is especially troublesome in directionally drilled wells or extended reach drilling (ERD) wells. Directional drilling or ERD is the intentional deviation of a wellbore from the vertical. In some cases the inclination (angle from the vertical) may be as great as ninety degrees. Such wells are commonly referred to as horizontal wells and may be drilled to a considerable depth and considerable distance from the drilling platform.

In all drilling operations, the drill stem assembly has a tendency to rest against the side of the borehole or the well casing, but this tendency is much greater in directionally drilled wells because of the effect of gravity. The drill stem may also locally rest against the borehole wall or casing in areas where the local curvature of the borehole wall or casing is high. As the drill string increases in length or degree of vertical deflection, the amount of friction created by the rotating drill stem assembly also increases. Areas of increased local curvature may increase the amount of friction generated by the rotating drill stem assembly. To overcome this increase in friction, additional power is required to rotate the drill stem assembly. In some cases, the friction between the drill stem assembly and the casing wall or borehole exceeds the maximum torque that can be tolerated by the drill stem assembly and/or maximum torque capacity of the drill rig and drilling operations must cease. Consequently, the depth to which wells can be drilled using available directional drilling equipment and techniques is ultimately limited by friction.

One string of pipe in sliding contact motion relative to an outer pipe, or more generally, an inner cylinder moving within an outer cylinder, is a common geometric configuration in several of these operations. One prior art method for reducing the friction caused by the sliding contact between strings of pipe is to improve the lubricity of the annular fluid. In industry operations, attempts have been made to reduce friction through, mainly, using water and/or oil based mud solutions containing various types of expensive and often environmentally unfriendly additives. For many of these additives the increased lubricity gained from these additives decreases as the temperature of the borehole increases. Diesel and other mineral oils are also often used as lubricants, but there may be problems with the disposal of the mud, and these fluids also lose lubricity at elevated temperatures. Certain minerals such as bentonite are known to help reduce friction between the drill stem assembly and an open borehole. Materials such as Teflon have been used to reduce sliding contact friction; however, these lack durability and strength. Other additives include vegetable oils, asphalt, graphite, detergents, glass beads, and walnut hulls, but each has its own limitations.

Another prior art method for reducing the friction between pipes is to use aluminum material for the drill string because aluminum is lighter than steel. However, aluminum is expensive and may be difficult to use in drilling operations, it is less abrasion-resistant than steel, and it is not compatible with many fluid types (e.g. fluids with high pH). To run casing and liners in extended-reach wells, the industry has developed means to “float” an inner casing string within an outer string, but circulation is restricted during this operation and it is not amenable to the hole-making process.

Yet another method for reducing the friction between strings of pipe is to use a hard facing material (also referred to herein as hardbanding or hardfacing) on the inner string. U.S. Pat. No. 4,665,996, herein incorporated by reference in its entirety, discloses the use of hardfacing applied to the principal bearing surface of a drill pipe, with an alloy having the composition of: 50-65% cobalt, 25-35% molybdenum, 1-18% chromium, 2-10% silicon, and less than 0.1% carbon for reducing the friction between a string and the casing or rock. As a result, the torque needed for the rotary drilling operation, especially directional drilling, is decreased. The disclosed alloy also provides excellent wear resistance on the drill string while reducing the wear on the well casing. Another form of hardbanding is WC-cobalt cermets applied to the drill stem assembly. Other hardbanding materials include TiC, Cr-carbide, and other mixed carbide and nitride systems. A tungsten carbide containing alloy, such as Stellite 6 and Stellite 12 (trademark of Cabot Corporation), has excellent wear resistance as a hardfacing material but may cause excessive abrading of the opposing device. Hardbanding may be applied to portions of the drill stem assembly using weld overlay or thermal spray methods. In a drilling operation, the drill stem assembly, which has a tendency to rest on the well casing, continually abrades the well casing as the drill string rotates.

U.S. Patent Publication No. 2002/0098298 discloses hardbanding applied in a pattern on the surface of a tool joint for the purpose of reducing hydraulic drag. “By providing wear-reducing material in separate, defined spaced-apart areas, fluid flow in a wellbore annulus past a tool joint is enhanced, i.e. flow between deposit areas is facilitated.” This reference further discloses low friction materials wherein the low friction material is a component element of the hardbanding material such as chromium. “The minimal admixture of the base material permits an extremely accurate pre-engineering of the matrix chemistry, allowing customization of the material and tailoring the tool joint to address drilling needs, such as severe abrasion, erosion, and corrosion, as seen, e.g., in open hole drilling conditions. It also permits modification of the deposit to adjust to coefficient of friction needs in metal-to-metal friction, e.g. as encountered in rotation of the drill string within the casing. In certain aspects the deposited material is modified by replacing galling material, e.g., iron and nickel, with non-galling elements, such as e.g., but not limited to, molybdenum, cobalt and chromium and combinations thereof.”

U.S. Pat. No. 5,010,225 discloses the use of grooves in the hardbanding to prevent casing wear. The protruding area is free of tungsten carbide particles so that tungsten carbide particle contact with the casing is avoided. The recessed area is about 80% of the total surface area.

U.S. Pat. Nos. 7,182,160B2, 6,349,779B1, and 6,056,073 disclose the designs of grooved segments in drill strings for the purpose of improving fluid flow in the annulus and reducing contact and friction with the borehole wall. U.S. Pat. No. 4,296,973 discloses a hardfaced collar for tool joints, where the hardfacing material is applied to an arrangement of holes around the collar, for the purpose of extending tool joint life.

In addition to hardbanding on tool joints, certain sleeved devices have been used in the industry. A polymer-steel based wear device is disclosed in U.S. Pat. No. 4,171,560 (Garrett, “Method of Assembling a Wear Sleeve on a Drill Pipe Assembly.”) Western Well Tool subsequently developed and currently offers Non-Rotating Protectors to control contact between pipe and casing in deviated wellbores, the subject of U.S. Pat. Nos. 5,803,193, 6,250,405, and 6,378,633.

Downhole Products has disclosed metallic casing centralizers that may be fitted with low friction pads for running pipe in the hole, as described in U.S. Pat. No. 6,830,102.

Strand et al. have patented a metal “Wear Sleeve” device (U.S. Pat. No. 7,028,788) that is a means to deploy hardbanding material on removable sleeves. This device is a ring that is typically of less than one-half inch in wall thickness that is threaded onto the pin connection of a drill pipe tool joint over a portion of the pin that is of reduced diameter, up to the bevel diameter of the connection. The ring has internal threads over a portion of the inner surface that are of left-hand orientation, opposite to that of the tool joint. Threaded this way, the ring does not bind against the pin connection body, but instead it drifts down to the box-pin connection face as the drill string turns to the right. Arnco markets this device under the trade name “WearSleeve.” After several years of availability in the market and at least one field test, this system has not been used widely.

Arnco has devised a fixed hardbanding system typically located in the middle of a joint of drill pipe as described in U.S. Patent Publication No. 2007/0209839, “System and Method for Reducing Wear in Drill Pipe Sections.”

Separately, a tool joint configuration in which the pin connection is held in the slips has been deployed in the field, as opposed to the standard petroleum industry configuration in which the box connection is held by the slips. Certain benefits have been claimed, as documented in exemplary publications SPE 18667 (1989) Dudman, R. A. et. al, “Pin-up Drillstring Technology: Design, Application, and Case Histories,” and SPE 52848 (1999) Dudman, R. A. et. al, “Low-Stress Level PinUp Drillstring Optimizes Drilling of 20,000 ft Slim-Hole in Southern Oklahoma.” Dudman discloses larger pipe diameters and connection sizes for certain hole sizes than may be used in the standard pin-down convention, because the pin connection diameter can be made smaller than the box connection diameter and still satisfy fishing requirements.

There are many additional pieces of equipment that have metal-to-metal contact on a drilling rig that are subject to friction, wear, erosion, corrosion, and/or deposits. These devices include but are not limited to the following list: valves, pistons, cylinders, and bearings in pumping equipment; wheels, skid beams, skid pads, skid jacks, and pallets for moving the drilling rig and drilling materials and equipment; topdrive and hoisting equipment; mixers, paddles, compressors, blades, and turbines; and bearings of rotating equipment and bearings of roller cone bits.

Certain operations other than hole-making are often conducted during the drilling process, including logging of the open-hole (or of the cased-hole section) to evaluate formation properties, coring to remove portions of the formation for scientific evaluation, capture of formation fluids at downhole conditions for fluids analyses, placing tools against the wellbore to record acoustic signals, and other operations and methods known to those skilled in the art. Most of these operations comprise the axial or torsional motion of one body relative to another, wherein the two bodies are in mechanical contact with a certain contact force and contact friction that resists the relative motion, causing friction and wear.

### Marine Riser Systems

In a marine environment, a further complication is that the wellhead tree may be “dry” (located above sea level on the platform) or “wet” (located on the seafloor). In either case, conductor pipes known as “risers” are placed between the surface and seafloor, with drill stem equipment run internal to the riser and with drilling fluid returns in the annular space. Risers may be particularly susceptible to the issues associated with rotating an inner pipe within an outer stationary pipe since the risers are not fixed but may also move due to contact with not only the drill string but also the sea environment. Drag and vortex shedding of a marine riser causes loads and vibrations that are due in part to frictional resistance of the ocean current around the outer surface of the marine riser.

Operations within marine riser systems often involve the axial or torsional motion of one body relative to another, wherein the two bodies are in mechanical contact with a certain contact force and contact friction that resists the relative motion causing friction and wear.

Marine risers and subsea BOPs provide many possible applications for coatings, including valves, rams, chokes, and riser booster pumps, in addition to devices listed elsewhere that may be used in marine production systems.

### Tubular Goods

Oil-country tubular goods (OCTG) comprise drill stem equipment, casing, tubing, work strings, coiled tubing, and risers. Common to most OCTG (but not coiled tubing) are threaded connections, which are subject to potential failure resulting from improper thread and/or seal interference, leading to galling in the mating connectors that can inhibit use or reuse of the entire joint of pipe due to a damaged connection. Threads may be shot-peened, cold-rolled, and/or chemically treated (e.g., phosphate, copper plating, etc.) to improve their anti-galling properties, and application of an appropriate pipe thread compound provides benefits to connection usage. However, there are still problems today with thread galling and interference issues, particularly with the more costly OCTG material alloys for extreme service requirements.

Operations using OCTG often involve the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

### Wellhead, Trees, and Valves

At the top of the casing, the fluids are contained by wellhead equipment, which typically includes multiple valves and blowout preventers (BOP) of various types. Subsurface safety valves are critical pieces of equipment that must function properly in the event of an emergency or upset condition. Subsurface safety valves are installed downhole, usually in the tubing string, and may be closed to prevent flow from the subsurface. Chokes and flowlines connected to the wellhead (particularly joints and elbows) are subject to friction, wear, corrosion, erosion, and deposits. Chokes may be cut out by sand flowback, for example, rendering the measurement of flow rates inaccurate.

Many of these devices rely on seals and very close mechanical tolerances, including both metal-to-metal and elastomeric seals. Many devices (sleeves, pockets, nipples, needles, gates, balls, plugs, crossovers, couplings, packers, stuffing boxes, valve stems, centrifuges, etc.) are subject to friction and mechanical degradation due to corrosion and erosion, and even potential blockage resulting from deposits of scale, asphaltenes, paraffins, and hydrates. Some of these devices may be installed downhole or on the sea floor, and it may be impossible or very costly at best to gain service access for repair or restoration.

Operations involving wellhead, trees, and valves often involve the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation. Several of these systems also establish static or dynamic seals which require close tolerances and smooth surfaces for leak resistance.

### Completion Strings and Equipment

With the drill well cased to prevent hole collapse and uncontrolled fluid flow, the completion operation must be performed to make the well ready for production. This operation involves running equipment into and out of the wellbore to perform certain operations such as cementing, perforating, stimulating, and logging. Two common means of conveyance of completion equipment are wireline and pipe (drill pipe, coiled tubing, or tubing work strings). These operations may include running logging tools to record formation and fluid properties, perforating guns to make holes in the casing to allow hydrocarbon production or fluid injection, temporary or permanent plugs to isolate fluid pressure, packers to facilitate setting pipe to provide a seal between the pipe interior and annular areas, and additional types of equipment needed for cementing, stimulating, and completing a well. Wireline tools and work strings may include packers, straddle packers, and casing patches, in addition to packer setting tools, devices to install valves and instruments in sidepockets, and other types of equipment to perform a downhole operation. The placement of these tools, particularly in extended-reach wells, may be impeded by friction drag. The final completion string left in the hole for production is commonly referred to as the production tubing string.

Installation and use of completion strings and equipment often involves the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

### Formation and Sandface Completions

In many wells, there is a tendency for sand or formation material to flow into the wellbore. To prevent this from occurring, “sand screens” are placed in the well across the completion interval. This operation may involve deploying a special-purpose large diameter assembly comprising one of several types of sand screen mesh designs over a central “base pipe.” The screen and basepipe are frequently subject to erosion and corrosion and may fail due to sand “cutout.” Also, in high inclination wells, the frictional drag resistance encountered while running screens into the wellbore may be excessive and limit the application of these devices, or the length of the wellbore may be limited by the maximum depth to which screen running operations may be conducted due to friction resistance.

In those wells that require sand control, a sand-like propping material, “proppant,” is pumped in the annular area between the screen and formation to prevent the formation grains from flowing through the screens. This operation is called a “gravel pack” or, if conducted at fracturing conditions, may be called a “frac pack.” In many other formations, often in wellbores without sand screens, fracture stimulation treatments may be conducted in which this same or different type of propping material is injected at fracturing conditions to create large propped fracture wings extending a significant distance away from the wellbore to increase the production or injection rate. Frictional resistance occurs while pumping the treatment as the proppant particles contact each other and the constraining walls. Furthermore, the proppant particles are subject to crushing and generating “fines” that increase the resistance to fluid flow during production. The proppant properties, including the strength, friction coefficient, shape, and roughness of the grain, are important to the successful execution of this treatment and the ultimate increase in well productivity or injectivity.

Installation of sand screens and subsequent workover operations often involves the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

### Artificial Lift Equipment

When production from a well is initiated, it may flow at satisfactory rates under its own pressure. However, many wells at some point in their life require assistance in lifting fluids out of the wellbore. Many methods are used to lift fluids from a well, including: sucker rod, progressive cavity pumps, Corod™, and electric submersible pumps to remove fluids from the well, plunger lifts to displace liquids from a predominantly gas well, and “gas lift” or injection of a gas along the tubing to reduce the density of a liquid column. Alternatively, specialty chemicals may be injected through valves spaced along the tubing to prevent buildup of scale, asphaltene, paraffin, or hydrate deposits.

The production tubing string may include devices to assist fluid flow. Several of these devices may rely on seals and very close mechanical tolerances, including turbulent, metal-to-metal, and elastomeric seals. Interfaces between parts (sleeves, pockets, plugs, packers, crossovers, couplings, bores, mandrels, etc.) are subject to friction and mechanical degradation due to corrosion and erosion, and even potential blockage or mechanical fit interference resulting from deposits of sand, scale, asphaltenes, paraffins, and hydrates. In particular, gas lift, submersible pumps, and other artificial lift equipment may include valves, seals, rotors, stators, and other devices that may fail to operate properly due to friction, wear, corrosion, erosion, or deposits.

Installation and operation of artificial lift equipment and subsequent workover operations often involves the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

### Well Intervention Equipment

Downhole operations on a wellbore near the reservoir formation interval are often required to gather data or to initiate, restore, or increase production or injection rate. These operations involve running equipment into and out of the wellbore. Two common means of conveyance of completion equipment and tools are wireline and pipe. These operations may include running logging tools to record formation and fluid properties, perforating guns to make holes in the casing to allow hydrocarbon production or fluid injection, temporary or permanent plugs to isolate fluid pressure, packers to facilitate a seal between intervals of the completion, and additional types of highly specialized equipment. The operation of running equipment into and out of a well involves sliding contact due to the relative motion of two bodies, thus creating frictional drag resistance.

Workover operations often involve the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

### Surface Mining Equipment

Certain deposits of hydrocarbons and minerals are extracted using large-scale mining processes. These mining methods are used for shallow hydrocarbon deposits, typically of bitumen-containing sands. Enormous deposits of bitumen are found in certain areas, such as Alberta, Canada, and Venezuela.

Surface mining equipment includes shovels, augers, and other devices to move material, components of the equipment used to operate the mining devices, including trucks, shovels, slurry flow lines, pipelines, and slurry processing loops, in addition to facilities equipment for handling the slurries and tailings. Processing of these slurries also has components in common with oil and gas wells, including valves, pumps, flow equipment, etc. The slurry materials can be very erosive and high rate of wear is a major equipment challenge.

### Other Related Art

In addition to the prior art disclosed above, U.S. Patent Publication No. 2008/0236842, “Downhole Oilfield Apparatus Comprising a Diamond-Like Carbon Coating and Methods of Use,” discloses applicability of DLC coatings to downhole devices with internal surfaces that are exposed to the downhole environment.

Saenger and Desroches describe in EP 2090741 A1 a “coating on at least a portion of the surface of a support body” for downhole tool operation. The types of coatings that are disclosed include DLC, diamond carbon, and Cavidur (a proprietary DLC coating from Bekaert). The coating is specified as “an inert material selected for reducing friction.” Specific applications to logging tools and O-rings are described. Specific benefits that are cited include friction and corrosion reduction.

Van Den Brekel et al. disclose in WO 2008/138957 A2 a drilling method in which the casing material is 1 to 5 times harder than the drill string material, and friction reducing additives are used in the drilling fluid. The drill string may have poly-tetra-fluor-ethene (PTFE) applied as a friction-reducing outer layer.

Wei et al. also discloses the use of coatings on the internal surfaces of tubular structures (U.S. Pat. No. 6,764,714, “Method for Depositing Coatings on the Interior Surfaces of Tubular Walls,” and U.S. Pat. No. 7,052,736, “Method for Depositing Coatings on the Interior Surfaces of Tubular Structures”). Tudhope et al. also have developed means to coat internal surfaces of an object, including for example U.S. Pat. No. 7,541,069, “Method and System for Coating Internal Surfaces Using Reverse-Flow Cycling.”

Griffo discloses the use of superabrasive nanoparticles on bits and bottom-hole assembly components in U. S. Patent Publication No. 2008/0127475, “Composite Coating with Nanoparticles for Improved Wear and Lubricity in Downhole Tools.”

Gammage et al. discloses spray metal application to the external surface of downhole tool components in U.S. Pat. No. 7,487,840.

Thornton discloses the use of Tungsten Disulphide (WS₂) on downhole tools in WO 2007/091054, “Improvements In and Relating to Downhole Tools.”

The use of coatings on bits and bit seals has been disclosed, for example in U.S. Pat. No. 7,234,541, “DLC Coating for Earth-Boring Bit Seal Ring,” U.S. Pat. No. 6,450,271, “Surface Modifications for Rotary Drill Bits,” and U.S. Pat. No. 7,228,922, “Drill Bit.”

In addition, the use of DLC coatings in non-oilfield applications has been disclosed in U.S. Pat. No. 6,156,616, “Synthetic Diamond Coatings with Intermediate Bonding Layers and Methods of Applying Such Coatings” and U.S. Pat. No. 5,707,717, “Articles Having Diamond-Like Protective Film.”

U.S. Pat. No. 6,087,025 discloses the application of diamond-like carbon coatings to cutting surfaces of metal cutting tools. It also discloses metal working tools with metal working surfaces bearing a coating of diamond-like carbon that is strongly adhered to the surface via the following gradient: metal alloy or cobalt-cemented tungsten carbide base; cobalt or metal silicide and/or cobalt or metal germanide; silicon and/or germanium; silicon carbide and/or germanium carbide; and, diamond-like carbon.

GB 454,743 discloses the application of binary, graded TiCr coatings on metallic substrates. More specifically, the coating disclosed preferably comprises either a layer of TiCr with a substantially constant composition or a graded TiCr layer, e.g. a base layer (adhesion layer) of Cr and a layer of graded composition consisting of Cr and Ti with the proportion of Ti in the layer increasing from the interface with the base layer to a proportion of Ti greater than that of Cr at the boundary of the graded layer remote from the base layer.

U.S. Pat. No. 5,989,397 discloses an apparatus and method for generating graded layers in a coating deposited on a metallic substrate. More specifically, it discloses a process control scheme for generating graded multilayer films repetitively and consistently using both pulsed laser sputtering and magnetron sputtering deposition techniques as well as an apparatus which allows for set up of an ultrahigh vacuum in a vacuum chamber automatically, and then execution of a computer algorithm or “recipe” to generate desired films. Software operates and controls the apparatus and executes commands which control digital and analog signals which control instruments.

In a recent development, drilling operations using casing or liners in the drill stem assembly has been used for various purposes, including eliminating the risk associated with the time delay to run the pipe in the hole. After completing the drilling of the interval, the bit and BHA may optionally be removed (depending on the specific casing drilling equipment configuration), and then the casing can be cemented in the borehole. Two representative industry papers on this subject include: “Running Casing on Conventional Wells with Casing Drilling™ Technology,” T. M. Warren, et al., Petroleum Society 2004-183; and “Directional Drilling with Casing,” T. M. Warren et al., SPE 79914.

### Need for the Disclosed Solutions

Given the expansive nature of these broad requirements for resource extraction operations, there remains need for the improved coating material technologies and manufacturing methods that better protect devices from wear due to friction, corrosion, erosion, and deposits resulting from sliding or rotating surface to surface contact between two or more devices and/or fluid streams that may contain solid particles traveling at high velocities. This need requires novel materials that combine high hardness with a capability for low coefficient of friction (COF) when in contact with an opposing surface. If such coating material can also provide a low energy surface and low friction coefficient against the opposing surface, then this novel material coating may enable ultra-extended reach drilling, reliable and efficient operations in difficult environments, including offshore, deepwater, and mining applications, and generate cost reduction, safety, and operational improvements throughout resource extraction operations. As envisioned, the use of these coatings could have widespread application and provide significant improvements and extensions to existing equipment and operational practices.

The above discussion of technical issues involved in resource extraction describes the broad potential for coatings to be used in these applications. The utility of coatings applies both to extracting hydrocarbons from wells and in surface mining processes and equipment.

To achieve maximum benefit from these coated devices, the manufacturing processes and specifications need to be modified to maximize the utility of the coatings. Appropriate adjustments to the manufacturing of resource extraction devices, for the purpose of optimizing the benefits from the coating, will improve the durability and longevity of the coating, thus increasing the economic benefits of the coating application.

### SUMMARY

The properties of the advanced coatings such as disclosed herein can benefit from the herein disclosed advanced manufacturing process to produce improved coated tools. Thereby, the benefits of the advanced coatings and the correspondingly coated tools and wear components may be extended as compared to coatings applied via the prior art processes.

According to one aspect of the present disclosure, an advantageous method of manufacturing a drilling tool includes: A coated device comprising: a body; a coating on at least a portion of a surface of the body, wherein the coating comprises, a terminal layer, and at least one underlayer positioned between the terminal layer and the body, the underlayer comprising a hardness of greater than 61 HRc; wherein prior to the addition of the terminal layer, at least one of the body and the underlayer is polished to a surface roughness of less than or equal to 1.0 micrometer Ra.

In another aspect, the disclosure also provides a coated device wherein prior to application of the terminal layer the at least one underlayer comprises at least one of a hardbanding, boriding, nitriding, or carburizing and is polished to a surface roughness of less than or equal to 0.5 micrometer Ra.

In still another aspect, the disclosure teaches preparation of a coated device wherein prior to application of the terminal layer the at least one underlayer comprises at least one of a hardbanding, boriding, nitriding, or carburizing and has a Rockwell hardness of at least 61 HRc or at least 63 HRc, and is polished to a surface roughness of less than or equal to 1.0 micrometer Ra.

In another aspect, portions of the body are coated and selected portions of the body are not coated. In yet another aspect a coated portion of the body comprises a body edge that provides a chamfered, rounded, or smoothed body shape transition across the body edge to avoid coating on or in sharp body edges, thereby mitigating stress concentrations at the edge or corner. In many embodiments, the terminal layer comprises a diamond like coating.

The present disclosure also presents a method of preparing a coated device. A coated device may be prepared according to a method comprising: A method of preparing a coated device, the method comprising: providing a body to be coated on at least a portion of a surface of the body; polishing the body to comprise a surface roughness of less than or equal to 1.0 micrometer Ra; applying a coating to the at least a portion of the surface of the body, wherein applying the coating comprises; applying at least one underlayer to the polished body, the at least one underlayer comprising a hardness of at least 61 HRc; polishing at least one of the at least one underlayer and the body to comprise a surface roughness of less than or equal to 1.0 micrometers Ra; thereafter, applying a terminal layer to the polished at least one of the underlayer and the body.

In other methods, prior to application of the terminal layer the at least one underlayer comprises at least one of a hardbanding, boriding, nitriding, and carburizing. Alternatively, the at least one of a hardbanding, boriding, nitriding, and carburizing may be polished to a surface roughness of less than or equal to 0.5 micrometers Ra or less than or equal to 0.25 micrometers Ra. Thereby, the terminal layer provides may provide an outer layer to the coating that brings improved performance verses prior art outer layers by having mitigated stress concentrations within the terminal layer (both during coating application and use) and uniform stress distribution throughout the terminal layer and its interface with the underlayer.

These and other features and attributes of the disclosed methods of making drilling tools with multilayer low friction coatings will be apparent from the detailed description which follows, particularly when read in conjunction with the figures appended hereto.

### BRIEF DESCRIPTION OF DRAWINGS

To assist those of ordinary skill in the relevant art in making and using the subject matter hereof, reference is made to the appended drawings, wherein:

FIGS. 1A-1F depict an oil and gas well production system that employs well production devices in the individual well construction, completion, stimulation, workover, and production phases of the overall production process.

FIGS. 2A-2D depict exemplary application of a coating applied to a drill stem assembly for subterraneous drilling applications.

FIG. 3 illustrates some possible patterns for hardband application on a component of a drill stem assembly.

FIGS. 4A-4E depict exemplary application of coatings applied to bottom hole assembly devices, in this case reamers, stabilizers, mills, and hole openers.

FIGS. 5A-5C illustrate the areas of drilling tools that are subject to balling with FIG. 5A illustrating balling of the junk slot of a PDC bit; FIG. 5B showing balling of a junk slot in a stabilizer blade; and FIG. 5C depicting balling occurring in the junk slots of a tricone bit and a hole opener.

FIG. 6 depicts exemplary application of a coating applied to a marine riser system.

FIGS. 7A-7C depict exemplary application of a coating applied to polished rods, sucker rods, and pumps used in downhole pumping operations.

FIGS. 8A-8D depict exemplary application of a coating applied to perforating guns, packers, and logging tools.

FIGS. 9A-9B depict exemplary application of coatings applied to wire rope and wire line and bundles of stranded cables.

FIGS. 10A-10C depict exemplary application of a coating applied to a basepipe and screen assembly used in gravel pack sand control operations and screens used in solids control equipment.

FIGS. 11A-11E depict exemplary application of a coating applied to wellhead and valve assemblies.

FIGS. 12A-12C depict exemplary application of coatings applied to an orifice meter, a choke, and a turbine meter.

FIGS. 13A-13B depict exemplary application of a coating applied to the grapple and overshot of a washover fishing tool.

FIGS. 14A-14B depict exemplary application of a coating applied to prevent deposition of a scale deposit.

FIGS. 15A-15D depict exemplary application of a coating applied to a threaded connection and illustrates thread galling.

FIG. 16 depicts, schematically, a surface mining operation for processing a shallow accumulation of hydrocarbons.

FIG. 17 depicts the friction and wear performance of DLC coating in a dry sliding wear test.

FIG. 18 depicts the friction and wear performance of the DLC coating in oil based mud.

FIG. 19 depicts the friction and wear performance of DLC coating at elevated temperature (150° F.) sliding wear test in oil based mud.

FIG. 20 depicts the friction performance of DLC coating at elevated temperatures (150° F. and 200° F.) in comparison to that of uncoated bare steel and hardbanding in oil based mud.

FIG. 21 depicts the velocity-weakening performance of DLC coating in comparison to an uncoated bare steel substrate.

FIG. 22 depicts SEM cross-sections of single layer and multi-layered DLC coatings disclosed herein.

FIG. 23 depicts water contact angle for DLC coatings versus uncoated 4142 steel.

FIGS. 24A-24-C depict the roughness results obtained using an optical profilometer from the following: a) unpolished ring; b) polished ring; and c) Ni—P buttering layer/DLC coated ring, where optical images of the scanned area are shown on the left and surface profiles are shown on the right.

FIG. 25 depicts the average friction coefficient as a function of speed for Ni—P buttering layer/DLC coated ring and unpolished bare ring.

FIG. 26 depicts an exemplary image (left-SEM, right-HAADF-STEM) showing structure in a candidate multilayered DLC material.

FIG. 27 depicts an HAADF-STEM (left) and Bright-Field STEM (right) image showing a 2-period Ti-DLC structure.

FIG. 28 depicts EELS (electron energy-loss spectroscopy) composition profiles showing the compositionally graded interface between Ti-layer 1 and DLC and the abrupt compositional transition at the interface between Ti-layer 2 and DLC.

FIG. 29 depicts SEM images showing failure occurring through delamination at the interface between the DLC and the 2^{nd} titanium adhesion-promoting layer.

FIG. 30 depicts the friction response as a function of time for several coating adhesion-promoting layer types at a given test condition.

FIGS. 31A-31F depict cross-sectional micrographs of test specimens deposited with different coating architectures after high-sand CETR-BOR testing wherein the bottom layer constitutes a (ferrous) substrate, an adhesion promoting (toughness enhancing) CrN (nitrided) layer separates the top functional layer(s) (the top functional layer including the outer terminal ultra-low friction layer) from the substrate. More detailed information on the architectures can be found in Table 2 below.

### DEFINITIONS

“Annular isolation valve” is a valve at the surface to control flow from the annular space between casing and tubing.

“Asphaltenes” are heavy hydrocarbon chains that may be deposited on the walls of pipes and other flow equipment and therefore create a flow restriction.

“Basepipe” is a liner that serves as the load-bearing device of a sand control screen. The screens are attached to the outside of the basepipe. At least a portion of the basepipe may be pre-perforated, slotted, or equipped with an inflow control device. The basepipe is fabricated in jointed sections that are threaded for makeup while running in hole.

“Bearings and bushings” are used to provide a low friction surface for two devices to move relative to each other in sliding contact, especially to allow relative rotational motion.

“Blast joints” are thicker-walled pipe used across flowing perforations or in a wellhead across a fluid inlet during a stimulation treatment. The greater wall thickness and/or material hardness resists being completely eroded through due to sand or proppant impingement.

“Bottom hole assembly” (BHA) is comprised of one or more devices, including but not limited to: stabilizers, variable-gauge stabilizers, back reamers, drill collars, flex drill collars, rotary steerable tools, roller reamers, shock subs, mud motors, logging while drilling (LWD) tools, measuring while drilling (MWD) tools, coring tools, under-reamers, hole openers, centralizers, turbines, bent housings, bent motors, drilling jars, acceleration jars, crossover subs, bumper jars, torque reduction tools, float subs, fishing tools, fishing jars, washover pipe, logging tools, survey tool subs, non-magnetic counterparts of any of these devices, and combinations thereof and their associated external connections.

“Casing” is pipe installed in a wellbore to prevent the hole from collapsing and to enable drilling to continue below the bottom of the casing string with higher fluid density and without fluid flow into the cased formation. Typically, multiple casing strings are installed in the wellbore of progressively smaller diameter.

“Casing centralizers” are banded to the outside of casing as it is being run in hole. Centralizers are often equipped with steel springs or metal fingers that push against the formation to achieve standoff from the formation wall, with an objective to centralize the casing to provide a more uniform annular space around the casing to achieve a better cement seal. Centralizers may include finger-like devices to scrape the wellbore to dislodge drilling fluid filtercake that may inhibit direct cement contact with the formation.

“Casing-while-drilling” refers to a relatively new and unusual method to drill using the casing instead of a removable drill string. When the hole section has reached depth, the casing is left in position, an operation is performed to remove or displace the cutting elements at the bottom of the casing, and a cement job may then be pumped.

“Chemical injection system” is used to inject chemical inhibitors into the wellbore to prevent buildup of scale, methane hydrates, or other deposits in the wellbore that would restrict production.

“Choke” is a device to restrict the rate of flow. Wells are commonly tested on a specific choke size, which may be as simple as a plate with a hole of specified diameter. When sand or proppant flow through a choke, the hole may be eroded and the choke size may change, rendering inaccurate flow rate measurements.

“Coaxial” refers to two or more objects having axes which are substantially identical or along the same line. “Non-coaxial” refers to objects which have axes that may be offset but substantially parallel or may otherwise not be along the same line.

“Completion sliding sleeves” are devices that are installed in the completion string that selectively enable orifices to be opened or closed, allowing productive intervals to be put into communication with the tubing or not, depending on the state of the sleeve. In long term use, the success of operating sliding sleeves depends on the resistance to operating the sleeve due to friction, wear, deposits, erosion, and corrosion.

“Complex geometry” refers to an object that is not substantially comprised of a single primitive geometry such as a sphere, cylinder, or cube. Complex geometries may be comprised of multiple simple geometries, such as a cylinder, cube, or sphere with many different radii, or may be comprised of simple primitives and other complex geometries.

“Connection pin” is a piece of pipe with the threads on the external surface of the pipe.

“Connection box” is a piece of pipe with the threads on the internal surface of the pipe.

“Contact rings” are devices attached to components of logging tools to achieve standoff of the tool from the wall of the casing or formation. For example, contact rings may be installed at joints in a perforating gun to achieve a standoff of the gun from the casing wall, for applications such as “Just-In-Time Perforating” (PCT Application No. WO 2002/103161 A2).

“Contiguous” refers to objects which are adjacent to one another such that they may share a common edge or face. “Non-contiguous” refers to objects that do not have a common edge or face because they are offset or displaced from one another. For example, tool joints are larger diameter cylinders that are non-contiguous because a smaller diameter cylinder, the drill pipe, is positioned between the tool joints.

“Control lines” and “conduits” are small diameter tubing that may be run external to a tubing string to provide hydraulic pressure, electrical voltage or current, or a fiberoptic path, to one or more downhole devices. Control lines are used to operate subsurface safety values, chokes, and valves. An injection line is similar to a control line and may be used to inject a specialty chemical to a downhole valve for the purpose of inhibition of scale, asphaltene, paraffin, or hydrate formation, or for friction reduction.

“Corod™” is a continuous coiled tubular used as a sucker rod in rod pumping production operations.

“Coupling” is a connecting device between two pieces of pipe, often but not exclusively a separate piece that is threadably adapted to two longer pieces that the coupling joins together. For example, a coupling is used to join two pieces of sucker rods in artificial lift rod pumping equipment.

“Cylinder” is (1) a surface or solid bounded by two parallel planes and generated by a straight line moving parallel to the given planes and tracing a curve bounded by the planes and lying in a plane perpendicular or oblique to the given planes, and/or (2) any cylinderlike object or part, whether solid or hollow (source: www.dictionary.com).

“Downhole tools” are devices that are often run retrievably into a well, or possibly fixed in a well, to perform some function in the wellbore. Some downhole tools may be run on a drill stem, such as Measurement While Drilling (MWD) devices, whereas other downhole tools may be run on wireline, such as formation logging tools or perforating guns. Some tools may be run on either wireline or pipe. A packer is a downhole tool that may be run on pipe or wireline to be set in the wellbore to block flow, and it may be removable or fixed. There are many downhole tool devices that are commonly used in the industry.

“Drill collars” are heavy wall pipe in the bottom hole assembly near the bit. The stiffness of the drill collars help the bit to drill straight, and the weight of the collars are used to apply weight to the bit to drill forward.

“Drill stem” is defined as the entire length of tubular pipes, comprised of the kelly (if present), the drill pipe, and drill collars, that make up the drilling assembly from the surface to the bottom of the hole. The drill stem does not include the drill bit. In the special case of casing-while-drilling operations, the casing string that is used to drill into the earth formations will be considered part of the drill stem.

“Drill stem assembly” is defined as a combination of a drill string and bottom hole assembly or coiled tubing and bottom hole assembly. The drill stem assembly does not include the drill bit.

“Drill string” is defined as the column, or string, of drill pipe with attached tool joints, transition pipe between the drill string and bottom hole assembly including tool joints, heavy weight drill pipe including tool joints and wear pads that transmits fluid and rotational power from the top drive or kelly to the drill collars and the bit. In some references, but not in this document, the term “drill string” includes both the drill pipe and the drill collars in the bottom hole assembly.

“Elastomeric seal” is used to provide a barrier between two devices, usually metal, to prevent flow from one side of the seal to the other. The elastomeric seal is chosen from one of a class of materials that are elastic or resilient.

“Elbows, tees, and couplings” are commonly used pipe equipment for the purpose of connecting flowlines to complete a flowpath for fluids, for example to connect a wellbore to surface production facilities.

“Expandable tubulars” are tubular goods such as casing strings and liners that are slightly undergauge while running in hole. Once in position, a larger diameter tool, or expansion mandrel, is forced down the expandable tubular to deform it to a larger diameter.

“Gas lift” is a method to increase the flow of hydrocarbons in a wellbore by injecting gas into the tubing string through gas lift valves. This process is usually applied to oil wells, but could be applied to gas wells with high fractions of water production. The added gas reduces the hydrostatic head of the fluid column.

“Glass fibers” are often run in small control lines, both downhole and return to surface, for the measurement of downhole properties, such as temperature or pressure. Glass fibers may be used to provide continuous readings at fine spatial samplings along the wellbore. The fiber is often pumped down one control line, through a “turnaround sub,” and up a second control line. Friction and resistance passing through the turnaround sub may limit some fiberoptic installations.

“Inflow control device” (ICD) is an adjustable orifice, nozzle, or flow channel in the completion string across the formation interval to enable the rate of flow of produced fluids into the wellbore. This may be used in conjunction with additional measurements and automation in a “smart” well completion system.

“Jar” is a downhole tool that is used to apply a large axial load, or shock, when triggered by the operator. Some jars are fired by setting weight down, and others are fired when pulled up. The firing of the jar is usually done to move pipe that has become stuck in the wellbore.

“Kelly” is a flat-sided polygonal piece of pipe that passes through the drilling rig floor on rigs equipped with older rotary table equipment. Torque is applied to this four-, six-, or perhaps eight-sided piece of pipe to rotate the drill pipe that is connected below.

“Logging tools” are instruments that are typically run in a well to make measurements; for example, during drilling on the drill stem or in open or cased hole on wireline. The instruments are installed in a series of carriers configured to run into a well, such as cylindrical-shaped devices, that provide environmental isolation for the instruments.

“Makeup” is the process of screwing together the pin and box of a pipe connection to effect a joining of two pieces of pipe and to make a seal between the inner and outer portions of the pipe.

“Mandrel” is a cylindrical bar or shaft that fits within an outer cylinder. A mandrel may be the main actuator in a packer that causes the gripping units, or “slips,” to move outward to contact the casing. The term mandrel may also refer to the tool that is forced down an expandable tubular to deform it to a larger diameter. Mandrel is a generic term used in several types of oilfield devices.

“Metal mesh” for a sand control screen is comprised of woven metal filaments that are sized and spaced in accordance with the corresponding formation sand grain size distribution. The screen material is generally corrosion resistant alloy (CRA) or carbon steel.

“Mazeflo™” completion screens are sand screens with redundant sand control and baffled compartments. MazeFlo self-mitigates any mechanical failure of the screen to the local compartment maze, while allowing continued hydrocarbon flow through the undamaged sections. The flow paths are offset so that the flow makes turns to redistribute the incoming flow momentum (for example, refer to U.S. Pat. No. 7,464,752).

“Moyno™ pumps” and “progressive cavity pumps” are long cylindrical pumps installed in downhole motors that generate rotary torque in a shaft as the fluid flows between the external stator and the rotor attached to the shaft. There is usually one more lobe on the stator than the rotor, so the force of the fluid traveling to the bit forces the rotor to turn. These motors are often installed close to the bit. Alternatively, in a downhole pumping device, power can be applied to turn the rotor and thereby pump fluid. Augers are devices that are similar to progressive cavity pumps that are used to move slurries and solids, often in surface equipment. Augers may or may not include an outer cylinder.

“Packer” is a tool that may be placed in a well on a work string, coiled tubing, production string, or wireline. Packers provide fluid pressure isolation of the regions above and below the packer. In addition to providing a hydraulic seal that must be durable and withstand severe environmental conditions, the packer must also resist the axial loads that develop due to the fluid pressure differential above and below the packer.

“Packer latching mechanism” is used to operate a packer, to make it release and engage the slips by axial movement of the pipe to which it is connected. When engaged, the slips are forced outwards into the casing wall, and the teeth of the slips are pressed into the casing material with large forces. A wireline packer is run with a packer setting tool that pulls the mandrel to engage the slips, after which the packer setting tool is disengaged from the packer and retrieved to the surface.

“MP35N” is a metal alloy consisting primarily of nickel, cobalt, chromium, and molybdenum. MP35N is considered highly corrosion resistant and suitable for hostile downhole environments.

“Paraffin” is a waxy component of some crude hydrocarbons that may be deposited on the walls of wellbores and flowlines and thereby cause flow restrictions.

“Pin-down connection” is currently the standard drilling configuration in which the box connection is held by the slips at the surface and the pin connection is facing down during connection makeup.

“Pin-up connection” is a drilling tool assembly that is oriented such that the pin connection is held in the slips at surface while making a connection, instead of the standard configuration in which the box connection is held by the slips. This reconfiguration may or may not require a change in the thread direction of the connection, i.e. left-handed or right-handed threads.

“Pistons” and “piston liners” are cylinders that are used in pumps to displace fluids from an inlet to an outlet with corresponding fluid pressure increase. The liner is the sleeve within which the piston reciprocates. These pistons are similar to the pistons found in the engine of a car.

“Plunger lift” is a device that moves up and down a tubing string to purge the tubing of water, similar to a pipeline “pigging” operation. With the plunger lift at the bottom of the tubing, the pig device is configured to block fluid flow, and therefore it is pushed uphole by fluid pressure from below. As it moves up the wellbore it displaces water because the water is not allowed to separate and flow past the plunger lift. At the top of the tubing, a device triggers a change in the plunger lift configuration such that it now bypasses fluids, whereupon gravity pulls it down the tubing against the upwards flowstream. Friction and wear are important parameters in plunger lift operation. Friction reduces the speed of the plunger lift falling or rising, and wear of the outer surface provides a gap that reduces the effectiveness of the device when traveling uphole.

“Production device” is a broad term defined to include any device related to the drilling, completion, stimulation, workover, or production of an oil and/or gas well. A production device includes any device described herein used for the purpose of oil or gas production. For convenience of terminology, injection of fluids into a well is defined to be production at a negative rate. Therefore, references to the word “production” will include “injection” unless stated otherwise.

“Reciprocating seal assembly” is a seal that is designed to maintain pressure isolation while two devices are displaced axially.

“Roller cone bit” is an earth-boring device equipped with conical shaped cutting elements, usually three, to make a hole in the ground.

“Rotating seal assembly” is a seal that is designed to maintain pressure isolation while two devices are displaced in rotation.

“Sand probe” is a small device inserted into a flowstream to assess the amount of sand content in the stream. If the sand content is high, the sand probe may be eroded.

“Scale” is a deposit of minerals (e.g. calcium carbonate) on the walls of pipes and other flow equipment that may build up and cause a flow restriction.

“Service tools” for gravel pack operations include a packer crossover tool and tailpipe to circulate down the workstring, around the liner and tailpipe, and back to the annulus. This permits placement of slurry opposite the formation interval. More generally, the gravel pack service tool is a group of tools that carry the gravel pack screens to TD, sets and tests the packer, and controls the flow path of the fluids pumped during gravel pack operations. The service tool includes the setting tool, the crossover, and the seals that seal into a packer bore. It can include an anti-swab device and a fluid loss or reversing valve.

“Shock sub” is a modified drill collar that has a shock absorbing spring-like element to provide relative axial motion between the two ends of the shock sub. A shock sub is sometimes used for drilling very hard formations in which high levels of axial shocks may occur.

“Shunt tubes” are external or internal tubes run in a sand control screen to divert the gravel pack slurry flow over long or multi-zone completion intervals until a complete gravel pack is achieved. See, for example, U.S. Pat. Nos. 4,945,991, 5,113,935, and PCT Patent Publication Nos. WO 2007/092082, WO 2007/092083, WO 2007/126496, and WO 2008/060479.

“Sidepocket” is an offset heavy-wall sub in the tubing for placing gas lift valves, temperature and pressure probes, injection line valves, etc.

“Sleeve” is a tubular part designed to fit over another part. The inner and outer surfaces of the sleeve may be circular or non-circular in cross-section profile. The inner and outer surfaces may generally have different geometries, i.e. the outer surface may be cylindrical with circular cross-section, whereas the inner surface may have an elliptical or other non-circular cross-section. Alternatively, the outer surface may be elliptical and the inner surface circular, or some other combination. The use of pins, slots, and other means may be used to constrain the sleeve to a body in one or more degrees of freedom, and seal elements may be used if there are fluid differential pressure or containment issues. More generally, a sleeve may be considered to be a generalized hollow cylinder with one or more radii or varying cross-sectional profiles along the axial length of the cylinder.

“Sliding contact” refers to frictional contact between two bodies in relative motion, whether separated by fluids or solids, the latter including particles in fluid (bentonite, glass beads, etc.) or devices designed to cause rolling to mitigate friction. A portion of the contact surface of two bodies in relative motion will always be in a state of slip, and thus sliding.

“Smart well” is a well equipped with devices, instrumentation, and controls to enable selective flow from specified intervals to maximize production of desirable fluids and minimize production of undesirable fluids. The flow rates may be adjusted for additional reasons, such as to control the drawdown or pressure differential for geomechanics reasons.

“Stimulation treatment” lines are pipe used to connect pumping equipment to the wellhead for the purpose of conducting a stimulation treatment.

“Subsurface safety valve” is a valve installed in the tubing, often below the seafloor in an offshore operation, to shut off flow. Sometimes these valves are set to automatically close if the rate exceeds a set value, for instance if containment was lost at the surface.

“Sucker rods” are steel rods that connect a beam-pumping unit at the surface with a sucker-rod pump at the bottom of a well. These rods may be jointed and threaded or they may be continuous rods that are handled like coiled tubing. As the rods reciprocate up and down, there is friction and wear at the locations of contact between the rod and tubing.

“Surface flowlines” are pipe used to connect the wellhead to production facilities, or alternatively, for discharge of fluid to the pits or flare stack.

“Threaded connection” is a means to connect pipe sections and achieve a hydraulic seal by mechanical interference between interlaced threaded, or machined (e.g., metal-to-metal seal), parts. A threaded connection is made up, or assembled, by rotating one device relative to another. Two pieces of pipe may be adapted to thread together directly, or a connector piece referred to as a coupling may be screwed onto one pipe, followed by screwing a second pipe into the coupling.

“Tool joint” is a tapered threaded coupling element for pipe that is usually made of a special steel alloy wherein the pin and box connections (externally and internally threaded, respectively) are fixed to either ends of the pipe. Tool joints are commonly used on drill pipe but may also be used on work strings and other OCTG, and they may be friction welded to the ends of the pipe.

“Top drive” is a method and equipment used to rotate the drill pipe from a drive system located on a trolley that moves up and down rails attached to the drilling rig mast. Top drive is the preferred means of operating drill pipe because it facilitates simultaneous rotation and reciprocation of pipe and circulation of drilling fluid. In directional drilling operations, there is often less risk of sticking the pipe when using top drive equipment.

“Tubing” is pipe installed in a well inside casing to allow fluid flow to the surface.

“Valve” is a device that is used to control the rate of flow in a flowline. There are many types of valve devices, including check valve, gate valve, globe valve, ball valve, needle valve, and plug valve. Valves may be operated manually, remotely, or automatically, or a combination thereof. Valve performance is highly dependent on the seal established between close-fitting mechanical devices.

“Valve seat” is the static surface upon which the dynamic seal rests when the valve is operated to prevent flow through the valve. For example, a flapper of a subsurface safety valve will seal against the valve seat when it is closed.

“Wash pipe” in a sand control operation is a smaller diameter pipe that is run inside the basepipe after the screens are placed in position across the formation interval. The wash pipe is used to facilitate annular slurry flow across the entire completion interval, take the return flow during the gravel packing treatment, and leave gravel pack in the screen-wellbore annulus.

“Washer” is typically a flat ring that is used to prevent leakage, distribute pressure, or make a joint tight, as under the head of a nut or bolt, or perhaps in a threaded connection of another part, such as a valve. A washer may be considered to be either a plate or a degenerate form of a cylinder in which the diametral dimension is greater than the axial dimension.

“Wireline” is a cable that is used to run tools and devices in a wellbore. Wireline is often comprised of many smaller strands twisted together, but monofilament wireline, or “slick line,” also exists. Wireline is usually deployed on large drums mounted on logging trucks or skid units.

“Work strings” are jointed pieces of pipe used to perform a wellbore operation, such as running a logging tool, fishing materials out of the wellbore, or performing a cement squeeze job.

A “coating” is comprised of one or more adjacent layers and any included interfaces. A coating may be placed on the base substrate material of a body assembly, on the hardbanding placed on a base substrate material, or on another coating.

A “low friction coating” is a coating for which the coefficient of friction is less than 0.15 under reference conditions. A typical low friction coating can include one or more underlayer(s), adhesion promoting layer(s), functional layer(s), and a terminal layer.

A “layer” is a thickness of a material that may serve a specific functional purpose such as reduced coefficient of friction, high stiffness, or mechanical support for overlying layers or protection of underlying layers.

A “low friction layer” or “functional layer” is a layer that provides low friction in a low friction coating. It can also provide for improved abrasion and wear resistance.

An “adhesion promoting layer” provides enhanced adhesion between functional layer(s) and/or underlayer(s) in a multi-layer coating. It can also provide enhanced toughness.

An “underlayer” is applied between the outer surface of body assembly substrate material or hardbanding or buttering layer and adhesion promoting layer or functional layer or between functional layer(s) and/or adhesion promoting layer(s) in a multi-layer coating.

A “graded layer” is a layer in which at least one constituent, element, component, or intrinsic property of the layer tapers or changes over the thickness of the layer or some fraction thereof, thereby avoiding sharp transitions at layer edges.

A “buttering layer” is a layer interposed between the outer surface of the body assembly substrate material or hardbanding and a layer, which may be another buttering layer, or a layer comprising the low friction coating. There may be one or more buttering layers interposed in such a manner. The buttering layer can include, but is not limited to, underlayer(s) that comprise the low friction coating or other layers such as an adhesive, toughening, and/or bonding layer.

A “terminal layer” is the final coating layer of the coating structure. It is immediately exposed to the counterface on initial use of the device and remains in contact with the environment as long as the coating surface is intact.

A “hardbanding” layer is interposed between the outer surface of the body assembly substrate material and the buttering layer(s), or one of the layers comprising the low friction coating. Hardbanding may be utilized in the oil and gas drilling industry to prevent tool joint and casing wear.

A “spraymetal alloy” is a material with high amounts of chromium and nickel that is flame sprayed onto the substrate and then induction fused. The resulting piece is hard (about 56 Rc) and is resistant to abrasion and corrosion.

An “interface” is a transition region from one layer to an adjacent layer wherein one or more constituent material composition and/or property value changes from 5% to 95% of the values that characterize each of the adjacent layers.

A “graded interface” is an interface that is designed to have a gradual change of constituent material composition and/or property value from one layer to the adjacent layer. For example, a graded interface may be created as a result of gradually stopping the processing of a first layer while simultaneously gradually commencing the processing of a second layer.

A “non-graded interface” is an interface that has a sudden change of constituent material composition and/or property value from one layer to the adjacent layer. For example, a non-graded interface may be created as a result of stopping the processing of one layer and subsequently commencing the processing of a second layer.

The process of “cleaning” a portion of a device to be coated comprises cleaning the device to remove oil, organic compounds, and/or adsorbates prior to one or more coating processing steps.

The process of “polishing” a portion of a device to be coated comprises some means of reducing the roughness of the surface, as measured by a profilometer. Polishing may occur prior to the initial coating step, between coating steps, or after the final coating step.

A “bevel” is a gradual slanted profile that enables one object to slide against another with low resistance, other than friction. The bevel may also be smoothed to further reduce the resistance to motion.

In certain coating operations, it is necessary to apply a “mask” to those areas that are not to be coated. The mask is removed after the coating operation, exposing the original substrate material.

A CETR (Center for Tribology) Tribometer is lab-scale test equipment for evaluating friction and wear in a controlled, repeatable environment.

The ASTM G65 test is a “Standard Test Method for Measuring Abrasion Using the Dry Sand/Rubber Wheel Apparatus.”

The ASTM G105 test is a “Standard Test Method for Conducting Wet Sand/Rubber Wheel Abrasion Tests.”

(Note: Several of the above definitions are from A Dictionary for the Petroleum Industry, Third Edition, The University of Texas at Austin, Petroleum Extension Service, 2001.)

### DETAILED DESCRIPTION

All numerical values within the detailed description and the claims herein are modified by “about” or “approximately” the indicated value, and take into account experimental error and variations that would be expected by a person having ordinary skill in the art.

Disclosed herein are broad application areas for the use of coated devices in resource extraction methods, including oil and gas well production and surface mining equipment and processes for applying coatings to such devices. Further disclosed are manufacturing steps to maximize the benefits obtainable by the disclosed coatings. The coatings described herein provide significant performance improvement of the oil and gas well and surface mining devices and operations disclosed herein.

DLC coatings have the following advantages over other types of coatings: (1) They have excellent adhesion to the device because they are deposited in a way which creates chemical bonds at the bit-coating interface; (2) They are harder than polymeric coatings and therefore last longer; and (3) When the coatings do eventually wear, they are abraded away or delaminate in small micron-sized pieces, which do not risk clogging in the well.

The disclosed coatings will provide more benefit if the device manufacturing process is modified to accommodate DLC coating properties. For example, depending on the coating applied, the temperature of the device should be limited after the coating has been applied. Additionally, polishing the surface that will be coated may best be accomplished prior to installation and assembly of auxiliary components, such as cutters, inserts, seals, etc. Also, hardfacing may be applied generously to the surface of a steel device, including not only areas subject to wear but also those areas that may be subject to balling and require coating durability. Hardfacing provides a harder substrate for the coating and has been found to be conducive to longer DLC coating life in laboratory and field tests.

For these and other reasons to be disclosed herein, modifications to the process of manufacturing coated devices will provide the greatest benefit that may be derived from the use of these coatings.

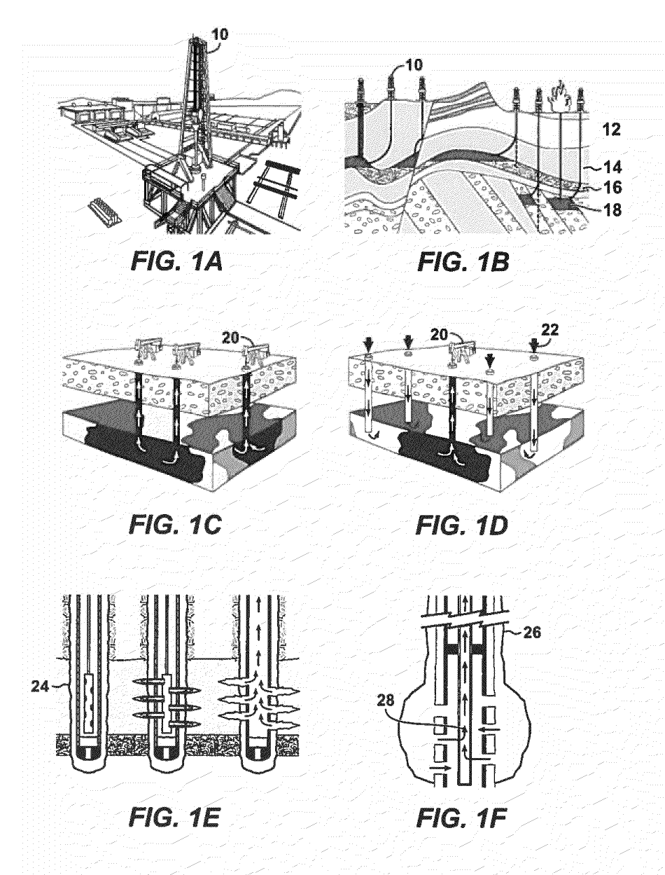

FIG. 1 illustrates the overall oil and gas well production system, for which the application of coatings to certain production devices as described herein may provide improved performance of these devices. FIG. 1A is a schematic of a land based drilling rig 10. FIG. 1B is a schematic of drilling rigs 10 drilling directionally through sand 12, shale 14, and water 16 into oil fields 18. FIGS. 1C and 1D are schematics of producing wells 20 and injection wells 22. FIG. 1E is a schematic of a perforating gun 24. FIG. 1F is a schematic of gravel packing 26 and screen liner 28. With no loss of generality, different inventive coatings may be preferred for different well production devices. A broad overview of production operations in its entirety shows the extent of the possible field applications for coated devices to mitigate friction, wear, erosion, corrosion, and deposits.

The method of coating such devices disclosed herein includes applying a suitable coating to a portion of the inner surface, outer surface, or a combination thereof on the device that will be subject to friction, wear, corrosion, erosion, and/or deposits. A coating is applied to at least a portion of the surface that is exposed to contact with another solid or with a fluid flowstream, wherein: the coefficient of friction of the coating is less than or equal to 0.15; the hardness of the coating is greater than 400 VHN; the roughness is less than 0.25 micrometer Ra, wear resistance of the coated device is at least 3 times that of the uncoated device; and/or the surface energy of the coating is less than 1 J/m². There is art to choosing the appropriate coating from the disclosed coatings for the specific application to maximize the technical and economic advantages of this technology.

A drill stem assembly is one example of a production device that may benefit from the use of coatings. The geometry of an operating drill stem assembly is one example of a class of applications comprising a cylindrical body. In the case of the drill stem, the actual drill stem assembly is an inner cylinder that is in sliding contact with the casing or open hole, an outer cylinder. These devices may have varying radii and alternatively may be described as comprising multiple contiguous cylinders of varying radii. As described below, there are several other instances of cylindrical bodies in oil and gas well production operations, either in sliding contact due to relative motion or stationary subject to contact by fluid flowstreams. The inventive coatings may be used advantageously for each of these applications by considering the relevant problem to be addressed, by evaluating the contact or flow problem to be solved to mitigate friction, wear, corrosion, erosion, or deposits, and by judicious consideration of how to apply such coatings for maximum utility and benefit to achieve an advantageous coated oil and gas production device.

There are many more examples of oil and gas well production devices that provide opportunities for beneficial use of coatings, as described in the background, including: stationary devices with coated elements for low friction on initial installation, and for resistance to wear, corrosion and erosion, and resistance to deposits on external or internal surfaces; and bearings, bushings, and other geometries wherein the device is coated for friction and wear reduction and resistance to corrosion and erosion.

In each case, there may be primary and secondary motivations for the use of coated devices to mitigate friction, wear, corrosion, erosion, and deposits. The same device may include more than one part with different coatings applied to address different coatings design aspects, including the problem to be addressed, the technology available for application of the coatings to the parts, and the economics associated with each type of coating. There will likely be many tradeoffs and compromises that govern the ultimate design of the coated device.

### Overview of Use of Coated Devices and Associated Benefits

In the wide range of operations and equipment that are required during the various stages of preparing for and producing hydrocarbons from a wellbore, there are several prototypical applications that appear in various contexts. These applications may be seen as various geometries of bodies in sliding mechanical contact and fluid flows interacting with the surfaces of solid objects. The designs of these components may be adapted to include coatings to reduce friction, wear, erosion, corrosion, and deposits. In this sense, the components then become “coated oil and gas well production devices.” Several specific geometries and exemplary applications are enumerated below, but a person skilled in the art will understand the broad scope of the applications of coatings and this list does not limit the range of the inventive methods disclosed herein:

### A. Coated Cylindrical Bodies in Sliding Contact Due to Relative Motion:

In an application that is ubiquitous throughout production operations, two cylindrical bodies are in contact, and friction and wear occur as one body moves relative to the other. The bodies may be comprised of multiple cylindrical sections that are placed contiguously with varying radii, and the cylinders may be placed coaxially or non-coaxially. The component design may be adapted to include coatings at the point of contact between the two cylindrical bodies. The coating may be on at least a portion of the one or more bodies to beneficially reduce the contact friction and wear. The coated element may optionally be removable and may be subsequently serviced or replaced, as necessary and appropriate for the device application.

For example, coating portions of the tool joints of drill pipe may be an effective means to utilize coatings to reduce the contact friction between drill stem and casing or open-hole. For casing, tubing, and sucker rod strings, the pipe coupling may have coatings applied to a portion of the inner or outer surface area, or a combination thereof. In other applications for smaller devices, for example plunger-type artificial lift devices, it may be advantageous to coat the entire surface area of the device. Wireline tools, mud motors, and frac sleeves are also cylinder-in-cylinder geometries. In addition to friction reduction, wear performance may also be enhanced via the coatings disclosed herein. The coated cylindrical bodies in sliding contact relative motion may also exhibit improved hardness, which provides improved wear resistance.

### An Exemplary List of Such Applications is as Follows

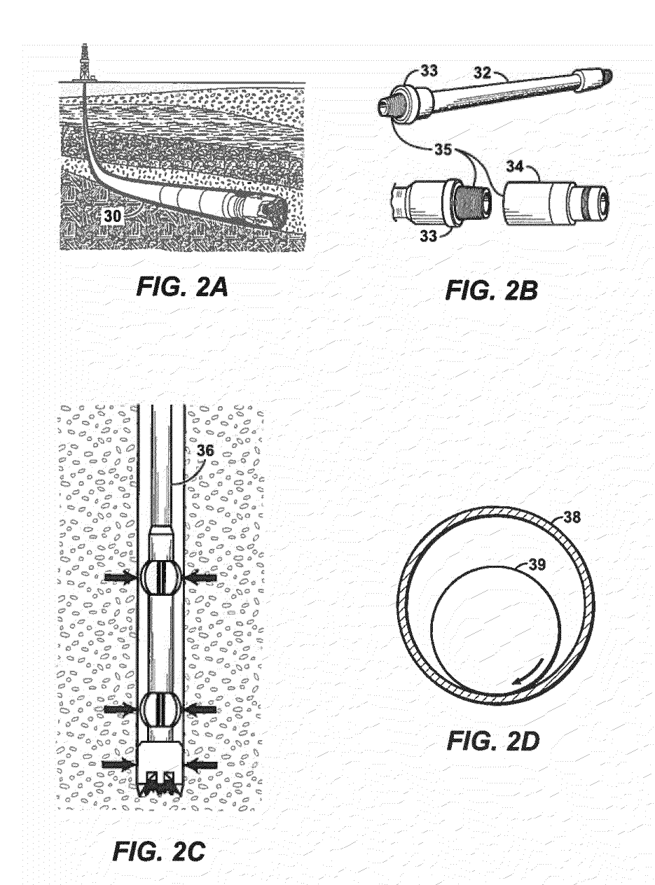

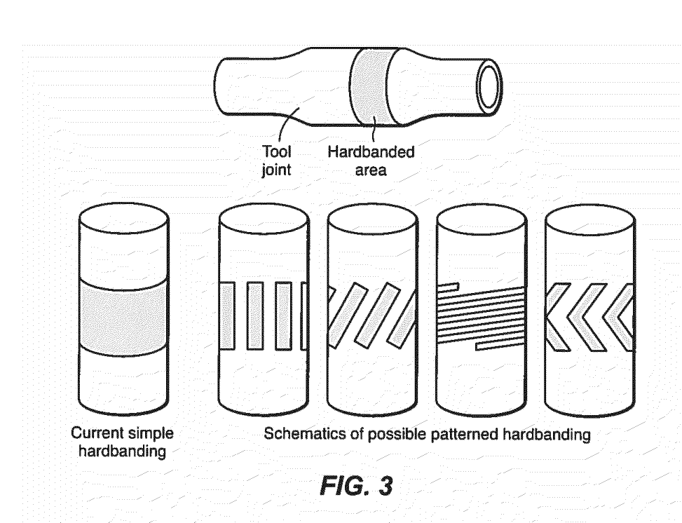

Drill pipe may be picked up or slacked off causing longitudinal motion and may be rotated within casing or open hole. Friction forces and device wear increase as the well inclination increases, as the local wellbore curvature increases, and as the contact loads increase. These friction loads cause significant drilling torque and drag which must be overcome by the rig and drill string devices (see FIG. 2). FIG. 2A exhibits deflection occurring in a drill string assembly 30 in a directional or horizontal well. FIG. 2B is a schematic of a drill pipe 32 and a tool joint 34, with threaded connection 35, and hardbanding 33. Note that the hardbanding 33 may be applied to the body of the tool joint or it may alternatively be applied to a sleeve 33 that is affixed to the tool joint. In either case, patterning of the hardbanding (FIG. 3) may be designed to alleviate the entrainment of foreign particles into the contact area. Multiple types of patterns are envisioned for this feature.

FIG. 2C is a schematic of a bit and bottom hole assembly 36. FIG. 2D is a schematic of a casing 38 and a tool joint 39 showing the contact that occurs between the two cylindrical bodies. Friction reducing coatings disclosed herein may be used to reduce the friction and wear between the two components as the tool joint 39 rotates within the casing 38, also reducing the torque required to turn the tool joint 39 for drilling lateral wells. The coatings may also be used in the pipe threaded connections 35.

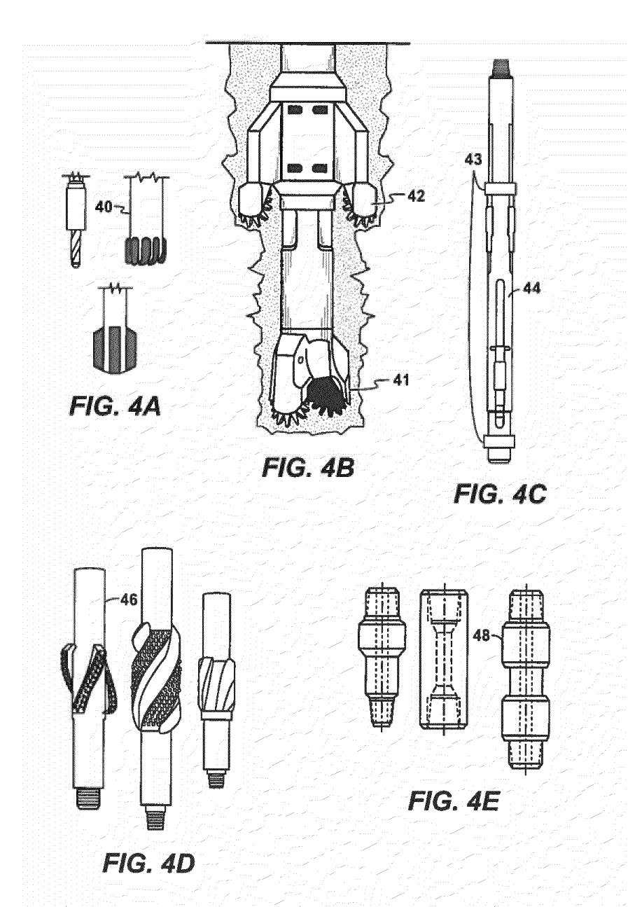

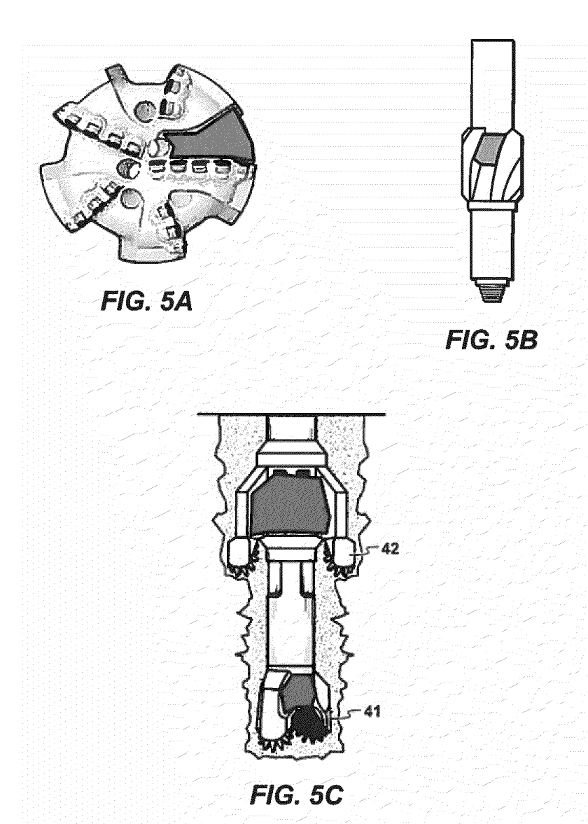

Bottom hole assembly (BHA) devices are located below the drill pipe on the drill stem assembly and may be subjected to similar friction and wear, and thus the coatings disclosed herein may provide a reduction in these mechanical problems (see FIG. 4). In particular, the coatings disclosed herein applied to the BHA devices may reduce friction and wear at contact points with the open hole and lengthen the tool life. Low surface energy of the coatings disclosed herein may also inhibit sticking of formation cuttings to the tools and corrosion and erosion limits may also be extended. It may also reduce the tendency for differential sticking. FIG. 4A is a schematic of mills 40 used in bottom hole assembly devices. FIG. 4B is a schematic of a bit 41 and a hole opener 42 used in bottom hole assembly devices. FIG. 4C is a schematic of a reamer 44 used in bottom hole assembly devices. Coated elements 43 are illustrated in this figure. FIG. 4D is a schematic of stabilizers 46 used in bottom hole assembly devices. FIG. 4E is a schematic of subs 48 used in bottom hole assembly devices. FIG. 5 further provides illustrative, non-exclusive locations where such coatings may be placed on a bit (FIG. 5A), on a stabilizer (FIG. 5B), and on a hole-opening tool (FIG. 5C).

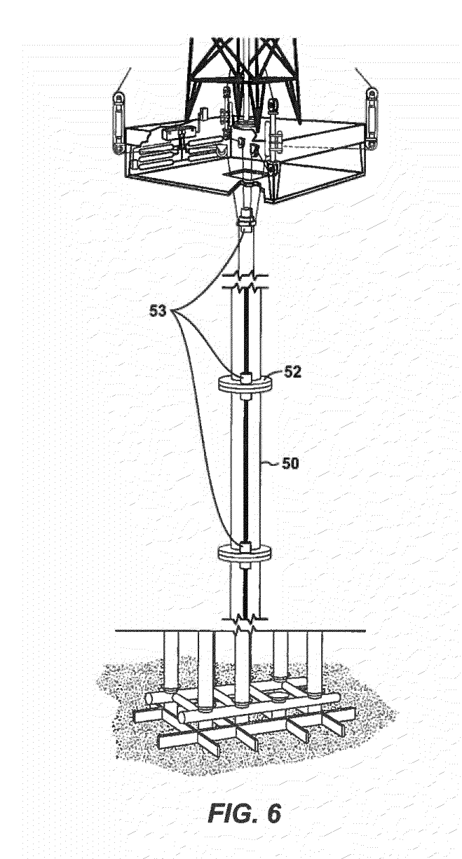

Drill strings are operated within marine riser systems and may cause wear to the riser as a result of the drilling operation. Use of coatings on wear pads and other devices within the riser and on tool joints on the drill string will reduce riser wear due to drilling (see FIG. 6). The vibrations of the riser due to ocean currents may be mitigated by coatings, and marine growth may also be inhibited, further reducing the drag associated with flowing currents. Referring to FIG. 6, use of the coatings disclosed herein on the riser pipe exterior 50 may be used to reduce friction and vibrations due to marine growth and ocean currents. In addition, the use of the coatings disclosed herein on internal bushings 52 and other contact points which may be used to reduce friction and wear. Furthermore, the riser booster pump is rotating machinery with seals, cavities, and other areas that could benefit from coatings.

Plunger lifts remove water from a well by running up and down within a tubing string. Both the plunger lift outer diameter and the tubing inner diameter may be affected by wear, and the efficiency of the plunger lift decreases with wear and contact friction. Reducing friction will increase the maximum allowable deviation for plunger lift operation and increase the range of applicability of this technology. Reducing the wear of both tubing and plunger lift will increase the time interval between required servicing. From an operations perspective, reducing the wear of the tubing inner diameter is highly desirable. Furthermore, coating the internal surface of a plunger lift may be beneficial. Coated elements may be banded to the outside of the plunger lift tool, wherein the outer diameter created by such elements would be nearly equal to the inner diameter of the tubing in which the device is operated, minus some tolerance to allow the plunger to slide within the tubing string. Depending on the plunger lift design, these elements could be replaced in the field and the tool returned to service. Alternatively, the entire surface area of the plunger lift device could be coated to reduce friction and wear. In the bypass state, fluid will flow through the tool more easily if the flow resistance is reduced by coatings on the internal portions of the tool, allowing the tool to drop faster. (See also WO 2011/002562 A1, “Plunger Lift Systems and Methods.”)

Completion and fracturing sliding sleeves may be moved axially, for example by stroking coiled tubing to displace the cylindrical sleeve up or down relative to the tool body that may also be cylindrical. These sleeves become susceptible to friction, wear, erosion, corrosion, and sticking due to damage from formation materials and buildup of scale and deposits. Coating portions of these elements to enable movement within these sliding sleeve systems will help to ensure that the sliding sleeve device will not stick when it is required to be moved.

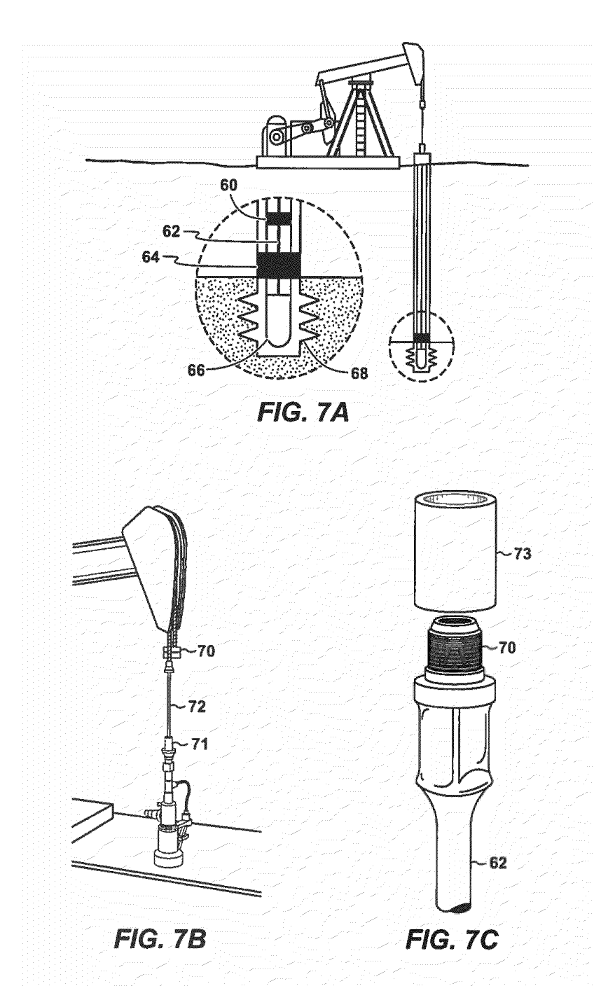

Sucker rods and Corod™ tubulars are used in pumping jacks to pump oil to the surface in low pressure wells, and they may also be used to pump water out of gas wells. Friction and wear occur continuously as the rods move relative to the tubing string. A reduction in friction may enable selection of smaller pumping jacks and reduce the power requirements for well pumping operations (see FIG. 7). Referring to FIG. 7A, the coatings disclosed herein may be used at the contact points of rod pumping devices, including, but not limited to, the sucker rod coupling, which is a device attached to the sucker rod 62, the sucker rod guide 60, the sucker rod 62, the tubing packer 64, the downhole pump 66, and the perforations 68 or means to provide perforations. Referring to FIG. 7B, the coatings disclosed herein may be used on polished rod clamp 70 and the polished rod 72 to provide smooth durable surfaces as well as good seals. Coating of stuffing box components may be beneficial in some designs. FIG. 7C is a schematic of a sucker rod 62 wherein the coatings disclosed herein may be used to prevent friction and wear and on the threaded connections 74. A sucker rod coupling 73 may be coated to provide a low-friction durable surface in contact with the tubing string in which it reciprocates.

In particular, the sucker rod coupling may be steel or covered with a spraymetal alloy prior to coating. Operators will choose spraymetal alloy sucker rod couplings in applications where a standard steel coupling wears out too quickly. However, the spraymetal alloy is more aggressive to the counterface material, which in this case is the tubing string installed in the well. Application of a friction reducing coating on a spraymetal alloy coupling is particularly beneficial because of the significant reduction in wear rates of the tubing string as a result of the counterface-friendly property of the coating, as well as increased longevity of the coupling itself

Pistons and/or piston liners in pumps for drilling fluids on drilling rigs and in pumps for stimulation fluids in well stimulation activities may be coated to reduce friction and wear, enabling improved pump performance and longer device life. Since certain equipment is used to pump acid, the coatings may also reduce corrosion and erosion damage to these devices. Packoffs and lubricators have common geometries and may also benefit from low friction coatings.

Expandable tubulars are typically run in hole, supported with a hanging assembly, and then expanded by running a mandrel through the pipe. Coating the surface of the mandrel may greatly reduce the mandrel load and enable expandable tubular applications in higher inclination wells or at higher expansion ratios than would otherwise be possible. The speed and efficiency of the expansion operation may be improved by significant friction reduction. The mandrel may be configured to have coatings on removable portions located at areas of highest contact stress. If removable, these coated portions would enable possible redressing in the field and longer mandrel tool life. The mandrel is a tapered cylinder and may be considered to be comprised of contiguous cylinders of varying radii; alternatively, a tapered mandrel may be considered to have a complex geometry.

Control lines and conduits may be internally coated for reduced flow resistance and corrosion/erosion benefits. Glass filament fibers may be pumped down internally coated conduits and turnaround subs with reduced resistance. Cable clamps and control line clamps may also use coatings on contact areas.

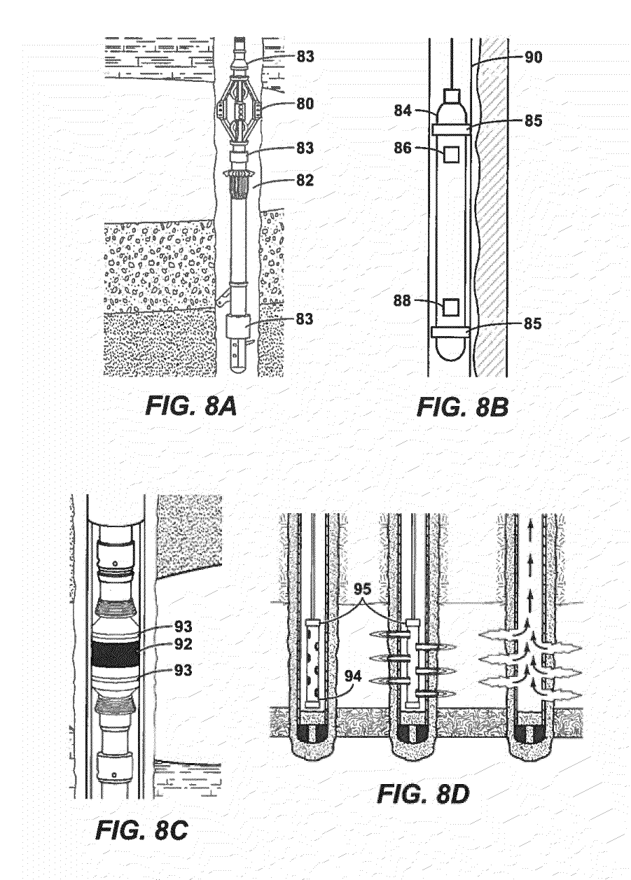

Tools operated in wellbores are typically cylindrical bodies or bodies comprised of contiguous cylinders of varying radii that are operated in casing, tubing, and open hole, either on wireline or rigid pipe. Friction resistance increases as the wellbore inclination increases or local wellbore curvature increases, rendering operation of such tools to be unreliable on wireline. Coatings applied to the contact surfaces may enable such tools to be reliably operated on wireline at higher inclinations or reduce the force to push tools down a horizontal well using coiled tubing, tractors, or pump-down devices. A list of such tools includes but is not limited to: logging tools, perforating guns, and packers (see FIG. 8). Referring to FIG. 8A, the coatings disclosed herein may be used on the external surfaces of a caliper logging tool 80 to reduce friction and wear with the open hole 82 or casing (not shown). The components of large diameter 83 may be coated to enable the tool to run in hole with less resistance and wear. Referring to FIG. 8B, the coatings disclosed herein may be used on the external surfaces 85 of an acoustic logging sonde 84, including, but not limited to, the signal transmitter 86 and signal receiver 88 to reduce friction and wear with the casing 90 or in open hole. Referring to FIGS. 8C and 8D, the coatings disclosed herein may be used on the external surfaces 93 of packer tools 92 and on surfaces 95 of perforating gun 94 to reduce friction and wear with the open hole. Low surface energy of the coatings will inhibit sticking of formation to the tools, and corrosion and erosion limits may also be extended.

Coatings may be applied to the internal portions of critical pipe sections that are subject to high curvature and contact loads during drilling and other tool running operations. These coatings may be applied prior to running the casing into the wellbore or, alternatively, after the pipe is in position.

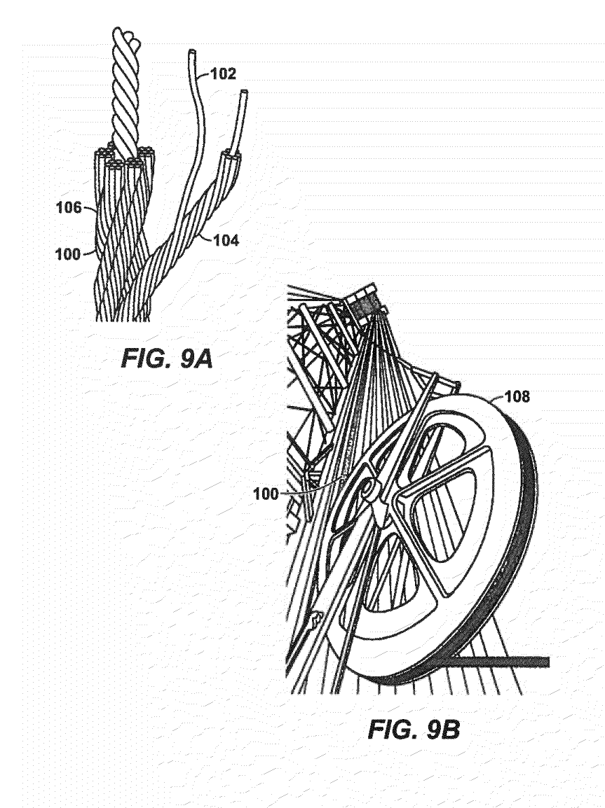

Wireline is a slender cylindrical body that is operated within casing, tubing, and open hole. At a higher level of detail, each strand is a cylinder, and the twisted strands are a bundle of non-coaxial cylinders that together comprise the effective cylinder of the wireline. Friction forces are present at the contact points between wireline and wellbore, and therefore coating the wireline with low-friction coatings will enable operation with reduced friction and wear. Braided line, multi-conductor, single conductor, and slickline may all be beneficially coated with low-friction coatings (see FIG. 9). Referring to FIG. 9A, the coatings disclosed herein may be applied to the wire line 100 by application to the wire 104, the individual strands of wire 102 or to the bundle of strands 106. A pulley type device 108 as seen in FIG. 9B may be used to run logging tools conveyed by wireline 100 into casing, tubing and open hole. The pulley device may also use coatings advantageously in the areas of the pulley and bearings that are subject to load and wear due to friction.

Casing centralizers and contact rings for downhole tools may be coated to reduce the friction resistance of placing these devices in a wellbore and providing movement downhole, particularly in high wellbore inclination angles.

B. Coated Cylindrical Bodies that are Primarily Stationary:

There are diverse applications for coating portions of the exterior, interior, or both of cylindrical bodies (e.g., pipe or modified pipe), primarily for erosion, corrosion, and wear resistance, but also for friction reduction of fluid flow. The cylindrical bodies may be coaxial, contiguous, non-coaxial, non-contiguous, or any combination thereof. In these applications, the coated cylindrical device may be essentially stationary for long periods of time, although perhaps a secondary benefit or application of the coatings is to reduce friction loads when the production device is installed.

### An Exemplary List of Such Applications is as Follows

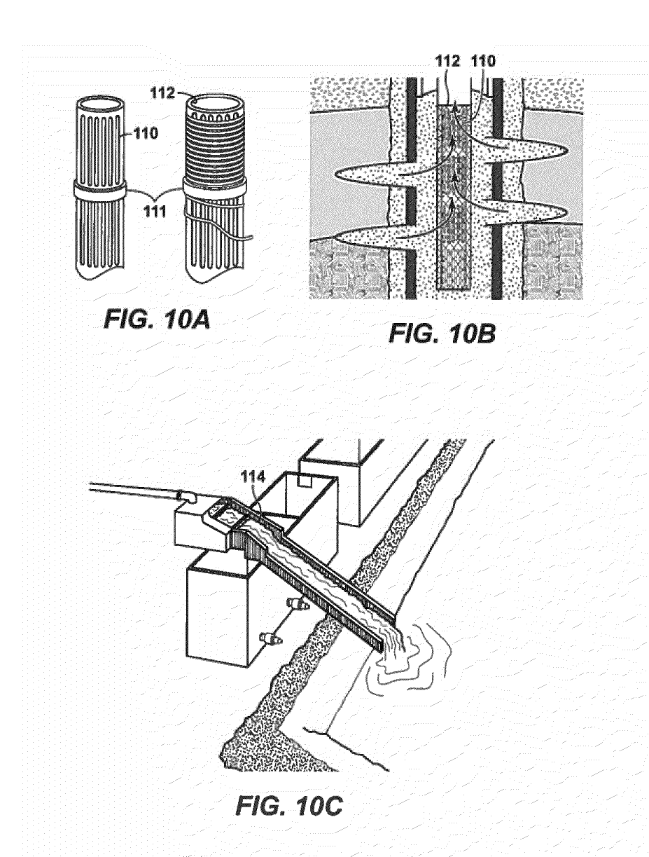

Perforated basepipe, slotted basepipe, or screen basepipe for sand control are often subject to erosion and corrosion damage during the completion and stimulation treatment (e.g., gravel pack or frac pack treatment) and during the well productive life. For example, a coating obtained with the inventive method will provide a larger inner diameter for the flow and reduce the flowing pressure drop relative to thicker plastic coatings. In another example, corrosive produced fluids may attack materials and cause material loss over time. Furthermore, highly productive formation intervals may provide fluid velocities that are sufficiently high to cause erosion. These fluids may also carry solid particles, such as fines or formation sand with a tendency to fail the completion device. It is further possible for deposits of asphaltenes, paraffins, scale, and hydrates to form on the completion equipment such as basepipes. Coatings can provide benefits in these situations by reducing the effects of friction, wear, corrosion, erosion, and deposits. (See FIG. 10.) Certain coatings for screen applications have been disclosed in U.S. Pat. No. 6,742,586 B2. The use of coatings in this application facilitates installation of the sand control device due to reduced friction and wear. Coatings may also be used on “blast joints” where high sand and proppant particle velocities may be expected to reduce the useful life of the sand screen material.

Wash pipes, shunt tubes, and service tools used in gravel pack operations may be coated internally, externally, or both to reduce erosion and flow resistance. Fluids with entrained solids for the gravel pack are pumped at high rates through these devices. Coatings may be used at specific locations in these tools to protect the main body of the device from erosion due to sand and proppant flow.

Blast joints may be advantageously coated for greater resistance to erosion resulting from impingement of fluids and solids at high velocity. Coatings may be used advantageously on blast joints at the specific locations where the greatest amount of wear damage may be expected.

Thin metal meshes may be coated for friction reduction and resistance to corrosion and erosion. The coating process may be applied to individual cylindrical strands prior to weaving or to the collective mesh after the weave has been performed, or both, or in combination. A screen may be considered to be comprised of many cylinders. Wire strands may be drawn through a coating device to enable coating application of the entire surface area of the wire. The coating applications include but are not limited to: sand screens disposed within completion intervals, Mazeflo™ completion screens, sintered screens, wirewrap screens, shaker screens for solids control, and other screens used as oil and gas well production devices. The coating can be applied to at least a portion of filtering media, screen basepipe, or both. (See FIG. 10.) FIG. 10 depicts exemplary application of the coatings disclosed herein on screens and basepipe. In particular, the coatings disclosed herein may be applied to the slotted liner of screens 110 as well as basepipe 112 as shown in FIGS. 10A and 10B to prevent erosion, corrosion, and deposits thereon. The detailed closeup of FIG. 10A shows coated element 111 external to the screen to allow it to slide downhole with reduced friction resistance. The coatings disclosed herein may also be applied to screens in the shale shaker 114 of solids control equipment as shown in FIG. 10C. Coatings may be used in a variety of ways with these devices as described above to reduce friction at the wellbore contact during installation and to reduce erosion damage due to sand and proppant flow during stimulation and production at specific locations where the coating is applied.

Coating devices may reduce material hardness requirements and mitigate the effects of corrosion and erosion for certain devices and components, enabling lower cost materials to be used as substitute for stellite, tungsten carbide, MP35N, high alloy materials, and other costly materials selected for this purpose.

### C. Plates, Disks, and Complex Geometries:

There are many coating applications that may be considered for non-cylindrical devices such as plates and disks or for more complex geometries. One exemplary application of a disk geometry is a washer device that may be coated on one or both sides to reduce friction during operation of the device. The benefits of coatings may be derived from a reduction in sliding contact friction and wear resulting from relative motion with respect to other devices, or perhaps a reduction in erosion, corrosion, and deposits from the interaction with fluid streams, or in many cases by a combination of both. These applications may benefit from the use of coatings as described below.

### An Exemplary List of Such Applications is as Follows

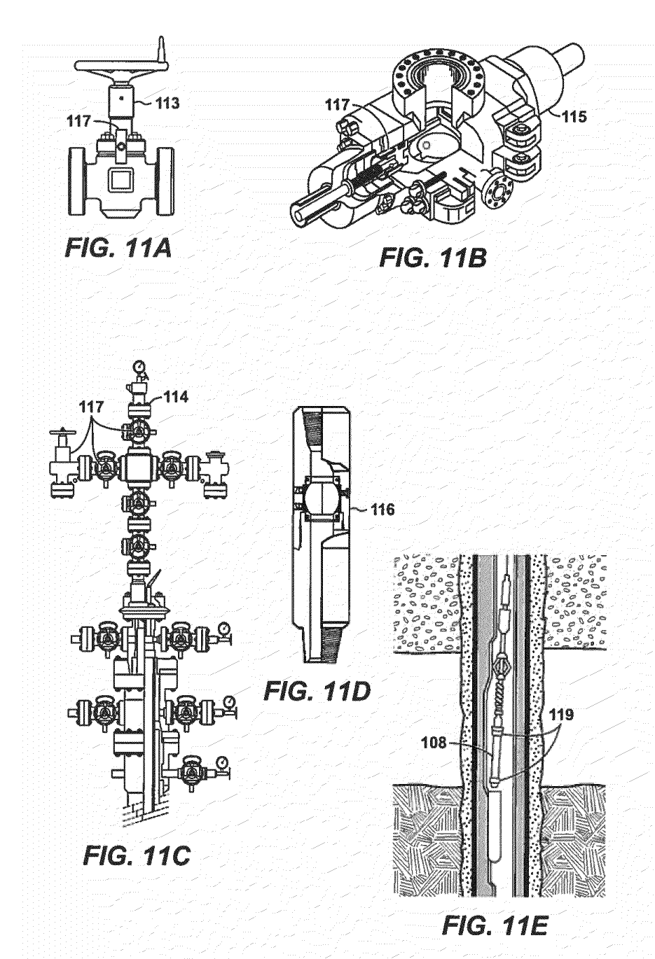

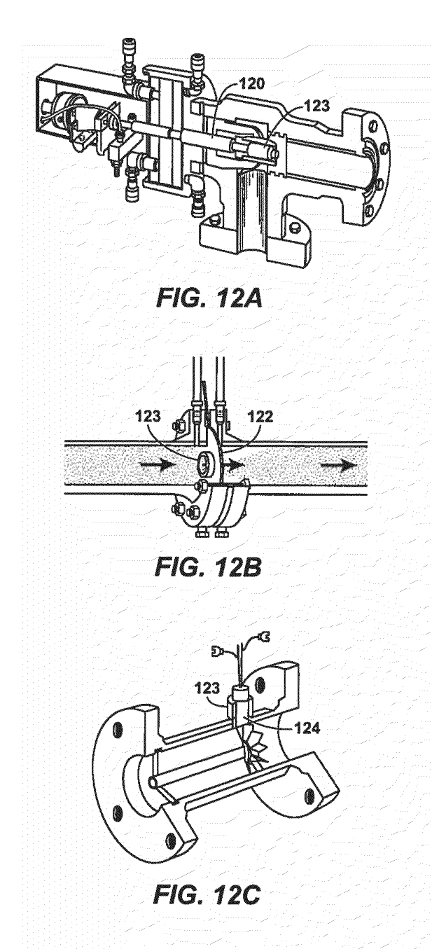

Chokes, valves, valve seats, mechanical seals, ball valves, inflow control devices, smart well valves, and annular isolation valves may beneficially use coated parts such as washers to reduce friction, erosion, corrosion, and damage due to deposits. Many of these devices are used in wellhead equipment (see FIGS. 11 and 12). In particular, referring to FIGS. 11A, 11B, 11C, 11D and 11E, valves 113, blowout preventers 115, wellheads 114, lower Kelly cocks 116, and gas lift valves 118 may use coated washers 117 with the coatings disclosed herein to provide resistance to friction, erosion, and corrosion in high velocity components, and the smooth surfaces of these coated devices provides enhanced sealability. In FIG. 11E, coated parts 119 may be used to ease entry of the gas lift device into the side pocket and to seal properly. In addition, referring to FIGS. 12A, 12B and 12C, chokes 120, orifice meters 122, and turbine meters 124 may have flow restrictions and other components (i.e. impellers and rotors) that use coated parts and washers 123 with the coatings disclosed herein to provide further resistance to friction, erosion, and corrosion. Other surface areas of the same production device may be protected by coatings for reduced friction and wear by using the same or different coating on a different portion of the production device.

Seats, nipples, valves, sidepockets, mandrels, packer slips, packer latches, etc. may beneficially use low-friction coatings.

Subsurface safety valves are used to control flow in the event of possible loss of containment at the surface. These valves are routinely used in offshore wells to increase operational integrity and are often required by regulation. Improvements in the reliability and effectiveness of subsurface safety valves provide substantial benefits to operational integrity and may avoid a costly workover operation in the event that a valve fails a test. Enhanced sealability, resistance to erosion, corrosion, and deposits, and reduced friction and wear in moving valve devices may be highly beneficial for these reasons. The use of coatings in subsurface safety valves will enhance their operability and obtain the benefits described above.

Gas lift and chemical injection valves are commonly used in tubing strings to enable injection of fluids, and coating portions of these devices will improve their performance. Gas lift is used to reduce the hydrostatic head and increase flow from a well, and chemicals are injected, for example, to inhibit formation of hydrates or scale in the well that would impede flow. The use of coatings in gas lift and chemical injection valves will enhance their operability and obtain the benefits described above.

Elbows, tees, and couplings may be internally coated for fluid flow friction reduction and the prevention of buildup of scale and deposits. Coatings may be used in these applications at specific locations of high erosion, such as at bends, unions, tees, and other areas of fluid mixing and wall impingement of entrained solids.

The ball bearings, sleeve bearings, or journal bearings of rotating equipment may be coated to provide low friction and wear resistance, and to enable longer life of the bearing devices.

Bearings of roller cone bits may be beneficially coated with low-friction coatings.

Wear bushings may utilize coatings for reduced friction and wear, and for enhanced operability.

Coatings in dynamic metal-to-metal seals may be used to enhance or replace elastomers in reciprocating and/or rotating seal assemblies.

Moyno™ and progressive cavity pumps, including “mud motors”, comprise a vaned rotor turning within a fixed stator. Augers are devices that are similar to progressive cavity pumps that are used to move slurries and solids, often in surface and mud mixing equipment. Augers may or may not include an outer cylinder. Coatings on these components will enable improved operation and increase the pump efficiency and durability.

Impellers and stators in rotating pump equipment may incorporate coatings for erosion and wear resistance, and for durability where fine solids may be present in the flowstream. Such applications include submersible pumps.

Coatings in a centrifuge device for drilling fluids solids control enhance the effectiveness of these devices by preventing plugging of the centrifuge discharge. The service life of the centrifuge may be extended by the erosion resistance provided by coatings.

Springs in tools that are coated may have reduced contact friction and long service life reliability. Examples include safety valves, gas lift valves, shock subs, and jars.

Logging tool devices may use coatings to improve operations involving deployment of arms, coring tubes, fluid sampling flasks, and other devices into the wellbore. Devices that are extended from and then retracted back into the tool may be less susceptible to jamming due to friction and solid deposits if coatings are applied.

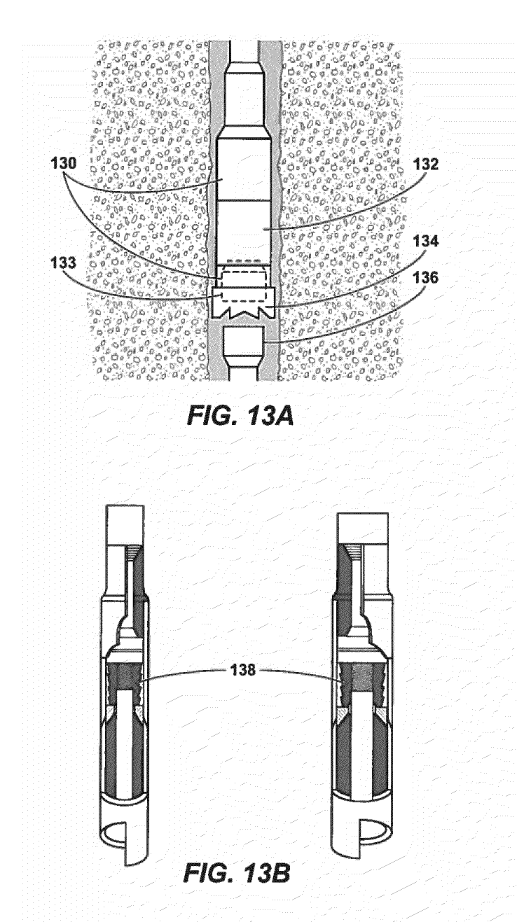

Fishing equipment, including but not limited to, washover pipe, grapple, and overshot, may beneficially use coatings to facilitate latching onto and removing a disconnected piece of equipment, or “fish,” from the wellbore. Low friction entry into the washover pipe may be facilitated by coatings, and a hard coating on the grapple may improve the bite of the tool. (See FIG. 13.) In particular, referring to FIG. 13A, the coatings disclosed herein may be applied to washover pipe 130, washover pipe connectors 132, rotary shoes 134, and fishing devices to reduce friction of entry of fish 136 into the washover string. In addition, referring to FIG. 13B, the coatings disclosed herein may be applied to grapple 138 to maintain material hardness for good grip.

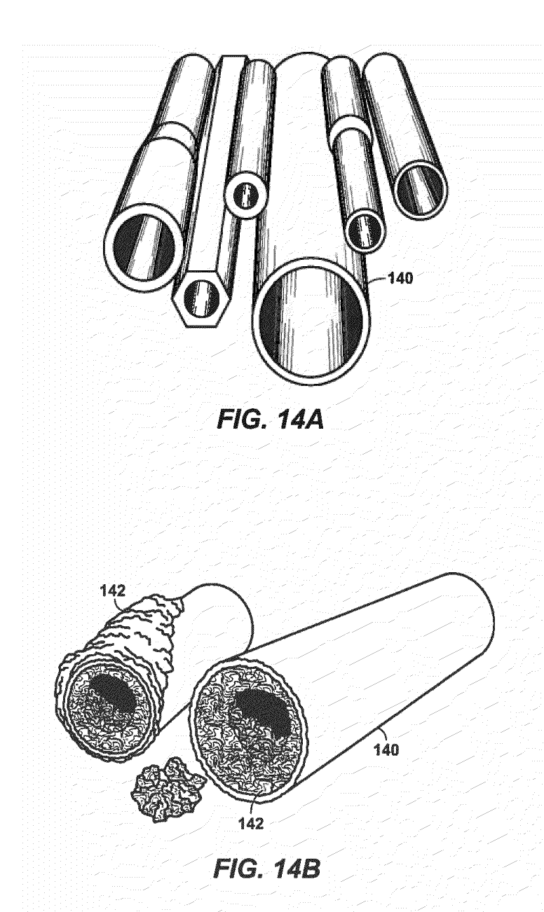

Sand probes and wellstream gauges to monitor pressure, temperature, flow rates, fluid concentrations, density, and other physical or chemical properties may be beneficially coated to extend life and resist damage due to wear, erosion, corrosion, and deposition of scale, asphaltenes, paraffin, and hydrates. An exemplary figure showing the absence of scale deposits and the presence of scale deposits in tubular goods 140 may be found in FIGS. 14A and 14B, respectively. In particular, FIG. 14A depicts tubulars 140 with full inner diameters because there is no scale, asphaltene, paraffin, or hydrate deposits due to the use of the coatings disclosed herein on the inside and/or outside surfaces of the tubulars 140. In contrast, FIG. 14B depicts tubulars 140 with restricted flow capacity due to the build-up of scale and other deposits 142 on the inside and/or outside surfaces of the tubulars 140 because the low surface energy coatings disclosed herein were not utilized. The build-up of scale and other deposits 142 in tubulars 140 prevents wellbore access with logging tools.

### D. Threaded Connections:

High strength pipe materials and special alloys in oilfield applications may be susceptible to galling, and threaded connections may be beneficially coated so as to reduce friction and increase surface hardness during connection makeup and to enable reuse of pipe and connections without redressing the threads. Seal performance may be improved by enabling higher contact stresses without risk of galling.

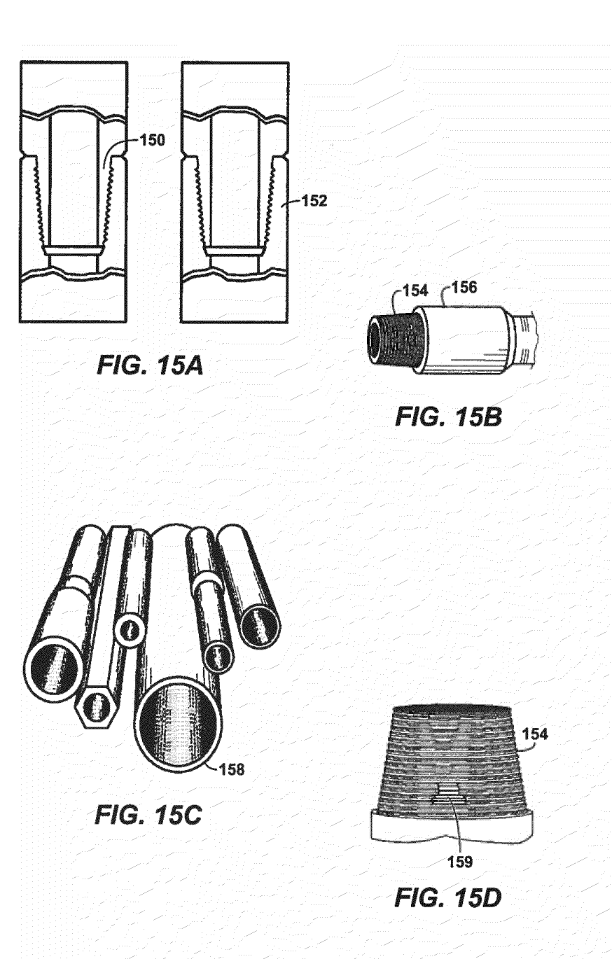

Pin and/or box threads of casing, tubing, drill pipe, drill collars, work strings, surface flowlines, stimulation treatment lines, threads used to connect downhole tools, marine risers, and other threaded connections involved in production operations may be beneficially coated with the low-friction coatings disclosed herein. Threads may be coated separately or in combination with current technology for improved connection makeup and galling resistance, including shot-peening and cold-rolling, and possibly but less likely, chemical treatment or laser shock peening of the threads. (See FIG. 15.) Referring to FIG. 15A, the pin 150 and/or box 152 may be coated with the coatings disclosed herein. Referring to FIG. 15B, the threads 154 and/or shoulder 156 may be coated with the coatings disclosed herein. In FIG. 15C, the threaded connections (not shown) of threaded tubulars 158 may be coated with the coatings disclosed herein. In FIG. 15D, galling 159 of the threads 154 may be prevented by use of the coatings disclosed herein. Coatings in this instance could be applied to one or both sets of threads of a threaded connection.

### E. Mining Equipment:

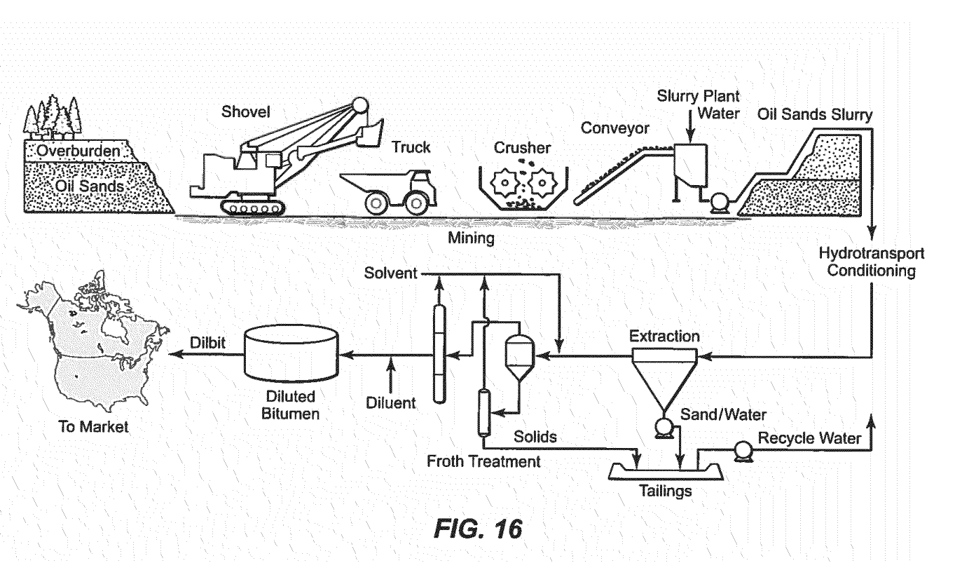

Large pieces of mining equipment are used to develop and produce shallow oil sands found in Alberta, Canada. FIG. 16 illustrates the excavation of oils sands by a shovel, transport via truck to a crushing facility, conveyor belt transfer to a slurry plant, transportation of the slurry via pipeline, extraction of the bitumen and separation of the sand/water with a water recycling loop, further separation of bitumen using a solvent, addition of diluent, and finally transport of diluted bitumen.

These sands can be very abrasive, resulting in erosion and wear of oil sand handling, transport, and processing equipment: shovels, conveyors and conveyor belts, augers, slurry lines and handling equipment, vessels, tanks, and crushing equipment, tailings pond transport lines. Key components may be beneficially coated to combat wear and prolong their operational lifetime between service intervals.

### Related Applications

U.S. Pat. No. 8,220,563, herein incorporated by reference in its entirety, discloses the use of low friction coatings on drill stem assemblies used in gas and oil drilling applications. Other oil and gas well production devices may benefit from the use of the coatings disclosed herein. A drill stem assembly is one example of a production device that may benefit from the use of coatings. The geometry of an operating drill stem assembly is one example of a class of applications comprising a cylindrical body. In the case of the drill stem, the actual drill stem assembly is an inner cylinder that is in sliding contact with the casing or open hole, an outer cylinder. These devices may have varying radii and alternatively may be described as comprising multiple contiguous cylinders of varying radii. As described below, there are several other instances of cylindrical bodies in oil and gas well production operations, either in sliding contact due to relative motion or stationary subject to contact by fluid flowstreams. The inventive coatings may be used advantageously for each of these applications by considering the relevant problem to be addressed, by evaluating the contact or flow problem to be solved to mitigate friction, wear, corrosion, erosion, or deposits, and by judicious consideration of how to apply such coatings to the specific devices for maximum utility and benefit.

U.S. Pat. No. 8,261,841, herein incorporated by reference in its entirety, discloses the use of low friction coatings on oil and gas well production devices and methods of making and using such coated devices. In one form, the coated oil and gas well production device includes an oil and gas well production device including one or more bodies, and a coating on at least a portion of the one or more bodies, wherein the coating is chosen from an amorphous alloy, a heat-treated electroless or electro plated based nickel-phosphorous composite with a phosphorous content greater than 12 wt %, graphite, MoS₂, WS₂, a fullerene based composite, a boride based cermet, a quasicrystalline material, a diamond based material, diamond-like-carbon (DLC), boron nitride, and combinations thereof. The coated oil and gas well production devices may provide for reduced friction, wear, corrosion, erosion, and deposits for well construction, completion and production of oil and gas.

U.S. Pat. No. 8,286,715, herein incorporated by reference in its entirety, discloses the use of low friction coatings on sleeved oil and gas well production devices and methods of making and using such coated devices. In one form, the coated sleeved oil and gas well production device includes an oil and gas well production device including one or more bodies and one or more sleeves proximal to the outer or inner surface of the one or more bodies, and a coating on at least a portion of the inner sleeve surface, outer sleeve surface, or a combination thereof, wherein the coating is chosen from an amorphous alloy, a heat-treated electroless or electro plated based nickel-phosphorous composite with a phosphorous content greater than 12 wt %, graphite, MoS2, WS2, a fullerene based composite, a boride based cermet, a quasicrystalline material, a diamond based material, diamond-like-carbon (DLC), boron nitride, and combinations thereof. The coated sleeved oil and gas well production devices may provide for reduced friction, wear, erosion, corrosion, and deposits for well construction, completion and production of oil and gas.

U.S. Pat. No. 8,561,707, herein incorporated by reference in its entirety, discloses drill stem assemblies with low friction coatings for subterraneous drilling operations. In one form, the coated drill stem assemblies for subterraneous rotary drilling operations include a body assembly with an exposed outer surface including a drill string coupled to a bottom hole assembly, a coiled tubing coupled to a bottom hole assembly, or a casing string coupled to a bottom hole assembly and an low friction coating on at least a portion of the exposed outer surface of the body assembly, hardbanding on at least a portion of the exposed outer surface of the body assembly, an low friction coating on at least a portion of the hardbanding, wherein the low friction coating comprises one or more low friction layers, and one or more buttering layers interposed between the hardbanding and the low friction coating. The coated drill stem assemblies provide for reduced friction, vibration (stick-slip and torsional), abrasion, and wear during straight hole or directional drilling to allow for improved rates of penetration and enable ultra-extended reach drilling with existing top drives.

U.S. Pat. No. 8,602,113, herein incorporated by reference in its entirety, discloses coated oil and gas well production devices and methods of making and using such coated devices. In one form, the coated device includes one or more cylindrical bodies, hardbanding on at least a portion of the exposed outer surface, exposed inner surface, or a combination of both exposed outer or inner surface of the one or more cylindrical bodies, and a coating on at least a portion of the inner surface, the outer surface, or a combination thereof of the one or more cylindrical bodies. The coating includes one or more low friction layers, and one or more buttering layers interposed between the hardbanding and the low friction coating. The coated oil and gas well production devices may provide for reduced friction, wear, erosion, corrosion, and deposits for well construction, completion and production of oil and gas.

U.S. Pat. No. 8,590,627, herein incorporated by reference in its entirety, discloses coated sleeved oil and gas well production devices and methods of making and using such coated sleeved devices. In one form, the coated sleeved oil and gas well production device includes one or more cylindrical bodies, one or more sleeves proximal to the outer diameter or inner diameter of the one or more cylindrical bodies, hardbanding on at least a portion of the exposed outer surface, exposed inner surface, or a combination of both exposed outer or inner surface of the one or more sleeves, and a coating on at least a portion of the inner sleeve surface, the outer sleeve surface, or a combination thereof of the one or more sleeves. The coating includes one or more low friction layers, and one or more buttering layers interposed between the hardbanding and the low friction coating. The coated sleeved oil and gas well production devices may provide for reduced friction, wear, erosion, corrosion, and deposits for well construction, completion and production of oil and gas.

U.S. Patent Publication No. 2011-0162751A1, herein incorporated by reference in its entirety, discloses coated petrochemical and chemical industry devices and methods of making and using such coated devices. In one form, the coated petrochemical and chemical industry device includes a petrochemical and chemical industry device including one or more bodies, and a coating on at least a portion of the one or more bodies, wherein the coating is chosen from an amorphous alloy, a heat-treated electroless or electro plated based nickel-phosphorous composite with a phosphorous content greater than 12 wt %, graphite, MoS₂, WS₂, a fullerene based composite, a boride based cermet, a quasicrystalline material, a diamond based material, diamond-like-carbon (DLC), boron nitride, and combinations thereof. The coated petrochemical and chemical industry devices may provide for reduced friction, wear, corrosion and other properties required for superior performance.

U.S. Provisional Patent Application No. 61/542,501 filed on Oct. 3, 2011, herein incorporated by reference in its entirety, discloses methods and systems for vacuum coating the outside surface of tubular devices for use in oil and gas exploration, drilling, completions, and production operations for friction reduction, erosion reduction and corrosion protection. These methods include embodiments for sealing tubular devices within a vacuum chamber such that the entire device is not contained within the chamber. These methods also include embodiments for surface treating of tubular devices prior to coating. In addition, these methods include embodiments for vacuum coating of tubular devices using a multitude of devices, a multitude of vacuum chambers and various coating source configurations.

U.S. patent application Ser. No. 13/724,403 filed on Dec. 21, 2012, herein incorporated by reference in its entirety, discloses low friction coatings with improved abrasion, wear resistance and methods of making such coatings. In one form, the coating includes: i) an under layer selected from the group consisting of CrN, TiN, TiAlN, TiAlVN, TiAlVCN, TiSiN, TiSiCN, TiAlSiN and combinations thereof, wherein the under layer ranges in thickness from 0.1 to 100 μm, ii) an adhesion promoting layer selected from the group consisting of Cr, Ti, Si, W, CrC, TiC, SiC, WC, and combinations thereof, wherein the adhesion promoting layer ranges in thickness from 0.1 to 50 μm and is contiguous with a surface of the under layer, and iii) a functional layer selected from the group consisting of a fullerene based composite, a diamond based material, diamond-like-carbon and combinations thereof, wherein the functional layer ranges from 0.1 to 50 μm and is contiguous with a surface of the adhesion promoting layer.

U.S. patent application Ser. No. 14/133,902 filed on Dec. 19, 2013, herein incorporated by reference in its entirety, discloses methods of making a drilling tool with low friction coatings to reduce balling and friction. Placing a diamond-like carbon coating on a drilling tool, including along the fluid courses (and including the “junk slots”), will increase the overall hydrophobicity of the tool and decrease the effective coefficient of friction of the tool surface area, minimizing cuttings accumulation and balling potential.

### Exemplary Multi-Layer Low Friction Coating Embodiments

The Applicants have discovered multi-layer low friction coatings that yield improved coating durability in severe abrasive/loading conditions. In a preferred form, these low friction coatings include a diamond-like-carbon (DLC) as one of the layers in the coating.

DLC coatings offer an attractive option to mitigate the negative effects discussed above, as (a) very low COF values can be realized (<0.15, and even <0.1), (b) the COF remains largely stable as a function of temperature, and (c) abrasive wear issues caused by hard particles such as carbides are greatly reduced. The typical structure of DLC coatings requires a layer of very hard amorphous carbon in varying forms of hybridization (i.e. sp2 or sp3-like character). Typically, with increasing sp3 content, the DLC layer becomes harder, but may also develop more residual compressive stress. The hardness and residual stress can be controlled by varying the sp2/sp3 ratio. Increasing sp2 content (i.e. graphite-like nature) typically reduces the hardness and the compressive strength. The sp2/sp3 ratio and overall chemistry can be varied by controlling various parameters during the deposition process (e.g. PVD, CVD or PACVD), such as substrate bias, gas mixture ratio, laser fluence (if applicable), substrate, deposition temperature, hydrogenation level, use of dopants in the DLC layer (metallic and/or non-metallic) etc. However, the reduction of residual stress in the DLC layer is generally accompanied by a reduction in hardness of the DLC (and reduction in sp3 content). While highly sp3-like DLC coatings can reach very high hardness values (˜4500-6000 Hv), these coatings exhibit compressive stresses >>1 GPa, detrimental to durability in applications describe above.

Hence, there is a need for novel DLC compositions with varying sp2/sp3 ratios, aimed at providing higher hardness values (in the range of 1700-5500 Hv) for use in extended reach rotary drilling devices, coated oil and gas well production devices (sleeved and unsleeved) and petrochemical and chemical industry equipment and devices. Hardness values lower than ˜1500 Hv are considered unsuitable for the envisioned application space, as the abrasive nature of relatively hard particles (e.g. sand, components of oil-based drilling mud etc.) is expected to quickly wear out the DLC coating.

While typical DLC coatings do offer improved hardness (in the range of 2500 Hv), there is a need to consider harder versions (Hv>3000) while managing residual stress for optimal coating thickness buildup. In addition, there is a need to minimize the plastic deformation of underlying substrate in the presence of abrasive, 3-body contact scenarios.

Durability of Diamond-like Carbon (DLC) coatings under three-body contact scenarios (i.e., in the presence of abrasive particles) is limited by overall abrasion resistance of the coating and spallation/delamination of coating that can be instigated by plastic deformation of underneath substrate due to creation of high local stresses. For DLC coatings to have enhanced durability in severe loading/abrasive environments, techniques to suppress existing failure modes to improve overall durability are needed.

In one form, a multi-layer low friction coating of the present disclosure includes an under layer that would be contiguous with a surface of a substrate for coating, an adhesion promoting and toughness enhancing layer contiguous with a surface of the under layer, and a functional layer contiguous with a surface of the adhesion promoting layer. Hence, the adhesion promoting layer is interposed between the under layer and the functional layer. The functional layer is the outermost exposed layer of the multi-layer low friction coating.

The surface of the substrate for coating may be made from a variety of different materials. Non-limiting exemplary substrates for coating include steel, stainless steel, hardbanding, an iron alloy, an aluminum based alloy, a titanium based alloy, ceramics and a nickel based alloy. Non-limiting exemplary hardbanding materials include cermet based materials, metal matrix composites, nanocrystalline metallic alloys, amorphous alloys and hard metallic alloys. Other non-limiting exemplary types of hardbanding include carbides, nitrides, borides, and oxides of elemental tungsten, titanium, niobium, molybdenum, iron, chromium, and silicon dispersed within a metallic alloy matrix. Such hardbanding may be deposited by weld overlay, thermal spraying or laser/electron beam cladding. The thickness of hardbanding layer may range from several orders of magnitude times that of or equal to the thickness of the outer coating layer. Non-limiting exemplary hardbanding thicknesses are 1 mm, 2 mm, and 3 mm proud above the surface of the drill stem assembly. The hardbanding surface may have a patterned design to reduce entrainment of abrasive particles that contribute to wear. The multi-layer low friction coatings disclosed herein may be deposited on top of the hardbanding pattern. The hardbanding pattern may include both recessed and raised regions and the thickness variation in the hardbanding can be as much as its total thickness.

The multi-layer low friction coatings of the present disclosure may be applied to a portion of the surface of a device chosen from the following exemplary non-limiting types: a drill bit or a drilling tool for subterraneous rotary drilling, a drill stem assembly for subterraneous rotary drilling, and stabilizers and centralizers. In addition, the multi-layer low friction coatings of the present disclosure may be applied to a portion of the surface of devices described in the definition section of the present disclosure.

The under layer of the low friction coating disclosed herein may be made from a variety of different materials, including, but not limited to, CrN, TiN, TiAlN, TiAlVN, TiAlVCN, TiSiN, TiSiCN, TiAlSiN and combinations thereof. The thickness of the under layer may range from 0.1 to 100 μm, or 1 to 75 μm, or 2 to 50 μm, or 3 to 35 μm, or 5 to 25 μm. The under layer may have a hardness that ranges from 800 to 4000 VHN, or 1000 to 3500 VHN, or 1200 to 3000 VHN, or 1500 to 2500 VHN, or 1800 to 2200 VHN.

The adhesion promoting layer of the low friction coating disclosed herein not only improves the adhesion between the under layer and the functional layer, but also enhances the overall toughness of the coating. For this reason, it may also be referred to herein as a toughness enhancing layer. The adhesion promoting layer of the low friction coating disclosed herein may be made from a variety of different materials, including, but not limited to, Cr, Ti, Si, W, CrC, TiC, SiC, WC, and combinations thereof. The thickness of the adhesion promoting layer may range from 0 to 60 μm, or 0.01 to 50 μm, or 0.1 to 25 μm, or 0.2 to 20 μm, or 0.3 to 15 μm, or 0.5 to 10 μm. The adhesion promoting layer may have a hardness that ranges from 200 to 2500 VHN, or 500 to 2000 VHN, or 800 to 1700 VHN, or 1000 to 1500 VHN. There is also generally a compositional gradient or transition at the interface of the under layer and the adhesion promoting layer, which may range in thickness from 0.01 to 10 μm, or 0.05 to 9 μm, or 0.1 to 8 μm, or 0.5 to 5 μm.

The functional layer of the low friction coating disclosed herein may be made from a variety of different materials, including, but not limited to, a fullerene based composite, graphene, a diamond based material, diamond-like-carbon (DLC) and combinations thereof. Non-limiting exemplary diamond based materials include chemical vapor deposited (CVD) diamond or polycrystalline diamond compact (PDC). The functional layer of the low friction coating disclosed herein is advantageously diamond-like-carbon (DLC) coating, and more particularly the DLC coating may be chosen from tetrahedral amorphous carbon (ta-C), tetrahedral amorphous hydrogenated carbon (ta-C:H), diamond-like hydrogenated carbon (DLCH), polymer-like hydrogenated carbon (PLCH), graphite-like hydrogenated carbon (GLCH), silicon containing diamond-like-carbon (Si-DLC), titanium containing diamond-like-carbon (Ti-DLC), chromium containing diamond-like-carbon (Cr-DLC), metal containing diamond-like-carbon (Me-DLC), oxygen containing diamond-like-carbon (O-DLC), nitrogen containing diamond-like-carbon (N-DLC), boron containing diamond-like-carbon (B-DLC), fluorinated diamond-like-carbon (F-DLC), sulfur-containing diamond-like carbon (S-DLC), and combinations thereof. The functional layer may be graded for improved durability, friction reduction, adhesion, and mechanical performance. The thickness of the functional layer may range from 0.1 to 50 μm, or 0.2 to 40 μm, or 0.5 to 25 μm, or 1 to 20 μm, or 2 to 15 μm, or 5 to 10 μm. The functional layer may have a Vickers hardness that ranges from 1000 to 7500 VHN, or 1500 to 7000 VHN, or 2000 to 6500 VHN, or 2200 to 6000 VHN, or 2500 to 5500 VHN, or 3000 to 5000 VHN. The functional layer may have a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. There is also generally a compositional gradient or transition at the interface of the adhesion promoting layer and the functional layer, which may range in thickness from 0.01 to 10 μm, or 0.05 to 9 μm, or 0.1 to 8 μm, or 0.5 to 5 μm.

In another form of the present disclosure, the multi-layer low friction coating including an under layer contiguous with a surface of a substrate for coating, an adhesion promoting layer contiguous with a surface of the under layer, and a functional layer contiguous with a surface of the adhesion promoting layer may further include a second adhesion promoting layer that is contiguous with a surface of the functional layer, and a second functional layer that is contiguous with a surface of the second adhesion promoting layer. Hence, the second adhesion promoting layer is interposed between the functional layer described above and a second functional layer. The second functional layer is the outermost exposed layer of the multi-layer low friction coating.

The second adhesion promoting layer may be made from the following non-limiting exemplary materials: Cr, Ti, Si, W, CrC, TiC, SiC, WC, and combinations thereof. The thickness of the second adhesion promoting layer may range from 0 to 60 μm, or 0.1 to 50 μm, or 1 to 25 μm, or 2 to 20 μm, or 3 to 15 μm, or 5 to 10 μm. The second adhesion promoting layer may have a Vickers hardness that ranges from 200 to 2500 VHN, or 500 to 2000 VHN, or 800 to 1700 VHN, or 1000 to 1500 VHN. There is also generally a compositional gradient or transition at the interface of the functional layer and the second adhesion promoting layer, which may range in thickness from 0.01 to 10 μm, or 0.05 to 9 μm, or 0.1 to 8 μm, or 0.5 to 5 μm.

The second functional layer may also be made from a variety of different materials, including, but not limited to, a fullerene based composite, graphene, a diamond based material, diamond-like-carbon (DLC) and combinations thereof. Non-limiting exemplary diamond based materials include chemical vapor deposited (CVD) diamond or polycrystalline diamond compact (PDC). Non-limiting exemplary diamond-like-carbon include ta-C, ta-C:H, DLCH, PLCH, GLCH, Si-DLC, N-DLC, O-DLC, B-DLC, Me-DLC, F-DLC and combinations thereof. The thickness of the second functional layer may range from 0.1 to 50 μm, or 0.2 to 40 μm, or 0.5 to 25 μm, or 1 to 20 μm, or 2 to 15 μm, or 5 to 10 μm. The second functional layer may have a hardness that ranges from 1000 to 7500 VHN, or 1500 to 7000 VHN, or 2000 to 6500 VHN, or 2500 to 6000 VHN, or 3000 to 5500 VHN, or 3500 to 5000 VHN. The second functional layer may have a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. There is also generally a compositional gradient or transition at the interface of the second adhesion promoting layer and the second functional layer, which may range in thickness from 0.01 to 10 μm, or 0.05 to 9 μm, or 0.1 to 8 μm, or 0.5 to 5.

The multi-layer low friction coating including a second adhesion promoting layer and a second functional layer may also optionally include a second under layer interposed between the functional layer and the second adhesion promoting layer. The second under layer of the low friction coating disclosed herein may be made from a variety of different materials, including, but not limited to, CrN, TiN, TiAlN, TiAlVN, TiAlVCN, TiSiN, TiSiCN, TiAlSiN and combinations thereof. The thickness of the second under layer may range from 0.1 to 100 μm, or 2 to 75 μm, or 2 to 75 μm, or 3 to 50 μm, or 5 to 35 μm, or 10 to 25 μm. The second under layer may have a hardness that ranges from 800 to 3500 VHN, or 1000 to 3300 VHN, or 1200 to 3000 VHN, or 1500 to 2500 VHN, or 1800 to 2200 VHN.

In yet another form of the present disclosure, the multi-layer low friction coating including an under layer contiguous with a surface of a substrate for coating, an adhesion promoting layer contiguous with a surface of the under layer, and a functional layer contiguous with a surface of the adhesion promoting layer may further include from 1 to 100 series of incremental coating layers, wherein each series of incremental coating layers includes a combination of an incremental adhesion promoting layer, an incremental functional layer and an optional incremental under layer, wherein the each series of incremental coating layers is configured as follows: A) the optional incremental under layer contiguous with a surface of the functional layer and the incremental adhesion promoting layer; wherein the optional incremental under layer is interposed between the functional layer and the incremental adhesion promoting layer; B) the incremental adhesion promoting layer contiguous with a surface of the functional layer or optional incremental under layer, and the incremental functional layer; and the incremental adhesion promoting layer is interposed between the functional layer and the incremental functional layer or between the optional incremental under layer and the incremental functional layer; and C) the incremental functional layer is contiguous with a surface of the incremental adhesion promoting layer.

The optional incremental under layer of the low friction coating disclosed herein may be made from a variety of different materials, including, but not limited to, CrN, TiN, TiAlN, TiAlVN, TiAlVCN, TiSiN, TiSiCN, TiAlSiN and combinations thereof. The thickness of the optional incremental under layer may range from 0.1 to 100 μm, or 2 to 75 μm, or 2 to 75 μm, or 3 to 50 μm, or 5 to 35 μm, or 10 to 25 μm. The optional incremental under layer may have a hardness that ranges from 800 to 3500 VHN, or 1000 to 3300 VHN, or 1200 to 3000 VHN, or 1500 to 2500 VHN, or 1800 to 2200 VHN.

The incremental adhesion promoting layer may be made from the following non-limiting exemplary materials: Cr, Ti, Si, W, CrC, TiC, SiC, WC, and combinations thereof. The thickness of the incremental adhesion promoting layer may range from 0 to 60 μm, or 0.1 to 50 μm, or 1 to 25 μm, or 2 to 20 μm, or 3 to 15 μm, or 5 to 10 μm. The incremental adhesion promoting layer may have a hardness that ranges from 200 to 2500 VHN, or 500 to 2000 VHN, or 800 to 1700 VHN, or 1000 to 1500 VHN. There is also generally a compositional gradient or transition at the interface of the optional incremental under layer and the incremental adhesion promoting layer, which may range in thickness from 0.01 to 10 μm, or 0.05 to 9 μm, or 0.1 to 8 μm, or 0.5 to 5 μm.

The incremental functional layer may be made from a variety of different materials, including, but not limited to, a fullerene based composite, graphene, a diamond based material, diamond-like-carbon (DLC) and combinations thereof. Non-limiting exemplary diamond based materials include chemical vapor deposited (CVD) diamond or polycrystalline diamond compact (PDC). Non-limiting exemplary diamond-like-carbon include ta-C, ta-C:H, DLCH, PLCH, GLCH, Si-DLC, N-DLC, O-DLC, B-DLC, Me-DLC, F-DLC and combinations thereof. The thickness of the incremental functional layer may range from 0.1 to 50 μm, or 0.2 to 40 μm, or 0.5 to 25 μm, or 1 to 20 μm, or 2 to 15 μm, or 5 to 10 μm. The incremental functional layer may have a hardness that ranges from 1000 to 7500 VHN, or 1500 to 7000 VHN, or 2000 to 6500 VHN, or 2200 to 6000 VHN, or 2500 to 5500 VHN, or 3000 to 5000 VHN. The incremental functional layer may have a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. There is also generally a compositional gradient or transition at the interface of the incremental adhesion promoting layer and the incremental functional layer, which may range in thickness from 0.01 to 10 μm, or 0.05 to 9 μm, or 0.1 to 8 μm, or 0.5 to 5 μm.

The final layer of coating is the “terminal layer” which is the coating that will be directly exposed on first application. As long as the terminal layer survives intact, its properties will govern the observed behavior of the coating. For this reason, it is a vital part of the coating architecture.

The total thickness of the multi-layered low friction coatings of the present disclosure may range from 0.5 to 5000 microns. The lower limit of the total multi-layered coating thickness may be 0.5, 0.7, 1.0, 3.0, 5.0, 7.0, 10.0, 15.0, or 20.0 microns in thickness. The upper limit of the total multi-layered coating thickness may be 25, 50, 75, 100, 200, 500, 1000, 3000, 5000 microns in thickness.

The multi-layer low friction coatings of the present disclosure yield a coefficient of friction of the functional layer of the low friction coating as measured by the block on ring friction test is less than or equal to 0.15, or less than or equal to 0.12, or less than or equal to 0.10, or less than or equal to 0.08. The friction force may be calculated as follows: Friction Force=Normal Force x Coefficient of Friction. The multi-layer low friction coating of the present disclosure yields a counterface wear scar depth as measured by the block on ring friction test of less than or equal to 500 μm, or less than or equal to 300 μm, or less than or equal to 100 μm, or less than or equal to 50 μm.

The multi-layer low friction coatings of the present disclosure also yield an unexpected improvement in abrasion resistance. The modified ASTM G105 abrasion test may be used to measure the abrasion resistance. In particular, the multi-layer low friction coatings of the present disclosure yield an abrasion resistance as measured by the modified ASTM G105 abrasion test for wear scar depth and weight loss that is at least 5 times lower, or at least 4 times lower, or at least 2 times lower than a single layer coating of the same functional layer. The multi-layer low friction coatings of the present disclosure yield a wear scar depth via the modified ASTM G105 abrasion test of less than or equal to 20 μm, or less than or equal to 15 μm, or less than or equal to 10 μm, or less than or equal to 5 μm, or less than or equal to 2 μm. The multi-layer low friction coatings of the present disclosure yield a weight loss via the modified ASTM G105 abrasion test of less than or equal to 0.03 grams, or less than or equal to 0.02 grams, or less than or equal to 0.01 grams, or less than or equal to 0.005 grams, or less than or equal to 0.004 grams, or less than or equal to 0.001 grams.

The coating may be polished before or after application of the terminal layer to achieve a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. Avoiding surface asperities is important for coating longevity as the structure of the coating is thereby more resistant to fracturing and delamination. Surface polishing may occur at any point in the process of coating a device but is most often accomplished prior to application of the under layer and optionally at one or more additional step(s) in the coating process, including after deposition of the terminal layer.

### Exemplary Method of Making Multi-Layer Low Friction Coatings Embodiments

The multi-layer low friction coatings of the present disclosure may be made by a variety of process techniques. In one exemplary form, a method of making a low friction coating includes the following steps: i) providing a substrate for coating, ii) depositing on a surface of the substrate an under layer, iii) depositing on the surface of the under layer an adhesion promoting layer is contiguous with a surface of the under layer, iv) depositing on the surface of the adhesion promoting layer a functional layer that is contiguous with a surface of the adhesion promoting layer.

The under layer of the method of making a low friction coating disclosed herein may be made from a variety of different materials, including, but not limited to, CrN, TiN, TiAlN, TiAlVN, TiAlVCN, TiSiN, TiSiCN, TiAlSiN and combinations thereof. The thickness of the under layer may range from 0.1 to 100 μm, or 2 to 75 μm, or 2 to 75 μm, or 3 to 50 μm, or 5 to 35 μm, or 10 to 25 μm. The under layer may have a hardness that ranges from 800 to 3500 VHN, or 1000 to 3300 VHN, or 1200 to 3000 VHN, or 1500 to 2500 VHN, or 1800 to 2200 VHN.

The adhesion promoting layer of the method of making a low friction coating disclosed herein not only improves the adhesion between the under layer and the functional layer, but also improves the toughness of the coating. For this reason, it may also be referred to herein as a toughness enhancing layer. The adhesion promoting layer of the low friction coating disclosed herein may be made from a variety of different materials, including, but not limited to, Cr, Ti, Si, W, CrC, TiC, SiC, WC, and combinations thereof. The thickness of the adhesion promoting layer may range from 0 to 60 μm, or 0.1 to 50 μm, or 1 to 25 μm, or 2 to 20 μm, or 3 to 15 μm, or 5 to 10 μm. The adhesion promoting layer may have a hardness that ranges from 200 to 2500 VHN, or 500 to 2000 VHN, or 800 to 1700 VHN, or 1000 to 1500 VHN. There is also generally a compositional gradient or transition at the interface of the under layer and the adhesion promoting layer, which may range in thickness from 0.01 to 10 μm, or 0.05 to 9 μm, or 0.1 to 8 μm, or 0.5 to 5 μm.

The functional layer of the method of making a low friction coating disclosed herein may be made from a variety of different materials, including, but not limited to, a fullerene based composite, graphene, a diamond based material, diamond-like-carbon (DLC) and combinations thereof. Non-limiting exemplary diamond based materials include chemical vapor deposited (CVD) diamond or polycrystalline diamond compact (PDC). Non-limiting exemplary diamond-like-carbon include ta-C, ta-C:H, DLCH, PLCH, GLCH, Si-DLC, N-DLC, O-DLC, B-DLC, Me-DLC, F-DLC and combinations thereof. The thickness of the functional layer may range from 0.1 to 50 μm, or 0.2 to 40 μm, or 0.5 to 25 μm, or 1 to 20 μm, or 2 to 15 μm, or 5 to 10 μm. The functional layer may have a hardness that ranges from 1000 to 7500 VHN, or 1500 to 7000 VHN, or 2000 to 6500 VHN, or 2200 to 6000 VHN, or 2500 to 5500 VHN, or 3000 to 5000 VHN. The functional layer may have a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. There is also generally a compositional gradient or transition at the interface of the adhesion promoting layer and the functional layer, which may range in thickness from 0.01 to 10 μm, or 0.05 to 9 μm, or 0.1 to 8 μm, or 0.5 to 5 μm.

The method of making a low friction coating described above may further include depositing additional layers of adhesion promoting layer(s), functional layer(s) and optional under layer(s) (between functional layer(s) and adhesion promoting layer(s)) to further enhance the abrasion resistance, coefficient of friction and other properties of the multi-layer low friction coating. In another exemplary form, the method of making a low friction coating including an under layer contiguous with a surface of a substrate for coating, an adhesion promoting layer contiguous with a surface of the under layer, and a functional layer contiguous with a surface of the adhesion promoting layer may further include the step of depositing from 1 to 100 series of incremental coating layers, wherein each series of incremental coating layers includes a combination of an incremental adhesion promoting layer, an incremental functional layer and an optional incremental under layer, wherein the each series of incremental coating layers is configured as follows: A) the optional incremental under layer contiguous with a surface of the functional layer and the incremental adhesion promoting layer; wherein the optional incremental under layer is interposed between the functional layer and the incremental adhesion promoting layer; B) the incremental adhesion promoting layer contiguous with a surface of the functional layer or optional incremental under layer, and the incremental functional layer; and the incremental adhesion promoting layer is interposed between the functional layer and the incremental functional layer or between the optional incremental under layer and the incremental functional layer; and C) the incremental functional layer is contiguous with a surface of the incremental adhesion promoting layer.

The optional incremental under layer of the method of making a low friction coating disclosed herein may be made from a variety of different materials, including, but not limited to, CrN, TiN, TiAlN, TiAlVN, TiAlVCN, TiSiN, TiSiCN, TiAlSiN and combinations thereof. The thickness of the optional incremental under layer may range from 0.1 to 100 μm, or 2 to 75 μm, or 2 to 75 μm, or 3 to 50 μm, or 5 to 35 μm, or 10 to 25 μm. The optional incremental under layer may have a hardness that ranges from 800 to 3500 VHN, or 1000 to 3300 VHN, or 1200 to 3000 VHN, or 1500 to 2500 VHN, or 1800 to 2200 VHN.

The incremental adhesion promoting layer of the method of making a low friction coating disclosed herein may be made from the following non-limiting exemplary materials: Cr, Ti, Si, W, CrC, TiC, SiC, WC, and combinations thereof. The thickness of the incremental adhesion promoting layer may range from 0 to 60 μm, or 0.1 to 50 μm, or 1 to 25 μm, or 2 to 20 μm, or 3 to 15 μm, or 5 to 10 μm. The incremental adhesion promoting layer may have a hardness that ranges from 200 to 2500 VHN, or 500 to 2000 VHN, or 800 to 1700 VHN, or 1000 to 1500 VHN. There is also generally a compositional gradient or transition at the interface of the optional incremental under layer and the incremental adhesion promoting layer, which may range in thickness from 0.01 to 10 μm, or 0.05 to 9 μm, or 0.1 to 8 μm, or 0.5 to 5 μm.

The incremental functional layer of the method of making a low friction coating disclosed herein may be made from a variety of different materials, including, but not limited to, a fullerene based composite, graphene, a diamond based material, diamond-like-carbon (DLC) and combinations thereof. Non-limiting exemplary diamond based materials include chemical vapor deposited (CVD) diamond or polycrystalline diamond compact (PDC). Non-limiting exemplary diamond-like-carbon include ta-C, ta-C:H, DLCH, PLCH, GLCH, Si-DLC, N-DLC, O-DLC, B-DLC, Me-DLC, F-DLC and combinations thereof. The thickness of the incremental functional layer may range from 0.1 to 50 μm, or 0.2 to 40 μm, or 0.5 to 25 μm, or 1 to 20 μm, or 2 to 15 μm, or 5 to 10 μm. The incremental functional layer may have a hardness that ranges from 1000 to 7500 VHN, or 1500 to 7000 VHN, or 2000 to 6500 VHN, or 2200 to 6000 VHN, or 2500 to 5500 VHN, or 3000 to 5000 VHN. The incremental functional layer may have a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. There is also generally a compositional gradient or transition at the interface of the incremental adhesion promoting layer and the incremental functional layer, which may range in thickness from 0.01 to 10 μm, or 0.05 to 9 μm, or 0.1 to 8 μm, or 0.5 to 5 μm.

The method of making multi-layer low friction coatings of the present disclosure yield a coefficient of friction of the functional layer of the low friction coating as measured by the block on ring friction test is less than or equal to 0.15, or less than or equal to 0.12, or less than or equal to 0.10, or less than or equal to 0.08. The multi-layer low friction coating of the present disclosure yields a counterface wear scar depth as measured by the block on ring friction test of less than or equal to 500 μm, or less than or equal to 300 μm, or less than or equal to 100 μm, or less than or equal to 50 μm.

The method of making low friction coatings of the present disclosure also yields an unexpected improvement in abrasion resistance. The modified ASTM G105 abrasion test may be used to measure the abrasion resistance. In particular, the multi-layer low friction coatings of the present disclosure yield an abrasion resistance as measured by the modified ASTM G105 abrasion test for wear scar depth and weight loss that is at least 5 times lower, or at least 4 times lower, or at least 2 times lower than a single layer coating of the same functional layer. The multi-layer low friction coatings of the present disclosure yield a wear scar depth via the modified ASTM G105 abrasion test of less than or equal to 20 μm, or less than or equal to 15 μm, or less than or equal to 10 μm, or less than or equal to 5 μm, or less than or equal to 2 μm. The multi-layer low friction coatings of the present disclosure yield a weight loss via the modified ASTM G105 abrasion test of less than or equal to 0.03 grams, or less than or equal to 0.02 grams, or less than or equal to 0.01 grams, or less than or equal to 0.005 grams, or less than or equal to 0.004 grams, or less than or equal to 0.001 grams.

For the method of making low friction coatings of the present disclosure, the steps of depositing the under layer(s), the adhesion promoting layer(s) and/or the functional layer(s) may be chosen from the following non-limiting exemplary methods: physical vapor deposition, plasma assisted chemical vapor deposition, and chemical vapor deposition. Non-limiting exemplary physical vapor deposition coating methods are magnetron sputtering, ion beam assisted deposition, cathodic arc deposition and pulsed laser deposition.

The method of making low friction coatings of the present disclosure may further include the step of polishing the layers of the coating to achieve a surface roughness between 0.01 to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. Non-limiting exemplary post-processing steps may include mechanical polishing, chemical polishing, depositing of smoothening layers, an ultra-fine superpolishing process, a tribochemical polishing process, an electrochemical polishing process, and combinations thereof.

The method of making low friction coatings of the present disclosure may be applied to the surface of various substrates for coating. Non-limiting exemplary substrates for the coating methods disclosed include steel, stainless steel, hardbanding, an iron alloy, an aluminum based alloy, a titanium based alloy, ceramics and a nickel based alloy. Non-limiting exemplary hardbanding materials include cermet based materials, metal matrix composites, nanocrystalline metallic alloys, amorphous alloys and hard metallic alloys. Other non-limiting exemplary types of hardbanding include carbides, nitrides, borides, and oxides of elemental tungsten, titanium, niobium, molybdenum, iron, chromium, and silicon dispersed within a metallic alloy matrix. Such hardbanding may be deposited by weld overlay, thermal spraying or laser/electron beam cladding. The thickness of hardbanding layer may range from several orders of magnitude times that of or equal to the thickness of the outer coating layer. Non-limiting exemplary hardbanding thicknesses are 1 mm, 2 mm, and 3 mm proud above the surface of the drill stem assembly. The hardbanding surface may have a patterned design to reduce entrainment of abrasive particles that contribute to wear. The multi-layer low friction coatings disclosed herein may be deposited on top of the hardbanding pattern. The hardbanding pattern may include both recessed and raised regions and the thickness variation in the hardbanding can be as much as its total thickness.

The method of making low friction coatings of the present disclosure may further include a cleaning step, wherein cleaning of the device to be coated occurs prior to one or more PVD, PACVD, and CVD coating process steps and wherein the cleaning step includes: ultrasonication, chemical solvent bath (acidic or basic in nature), water bath, organic solvent, surfactant, detergent, forced air, mechanical wiping, etching, argon etching, plasma etching, ion etching, with argon, oxygen, hydrogen, or combinations, nitrogen, neon, inert gas ions, baking or extended temperature annealing to remove organic volatiles and grease.

The optional processing steps of cleaning and polishing may occur beneficially at any step in the coating operation. Typically, it is beneficial to polish the device as one step after the device has been manufactured, followed by a cleaning step prior to coating of the device. Some coating processes may warrant post-coating polishing, depending on the process used and the intended application for the device. This non-limiting sequence of operations may provide acceptable results for some applications.

### Exemplary Method of Using Multi-Layer Low Friction Coatings Embodiments

The multi-layer low friction coatings disclosed herein may be applied to at least a portion of the surface of a device provided above.

More particularly, the multi-layer low friction coatings disclosed herein may be used to improve the performance of drilling tools, particularly a drilling head for drilling in formations containing clay and similar substances. The present disclosure utilizes the low surface energy novel materials or coating systems to provide thermodynamically low energy surfaces, e.g., non-water wetting surface for bottom hole components. The multi-layer low friction coatings disclosed herein are suitable for oil and gas drilling in gumbo-prone areas, such as in deep shale drilling with high clay contents using water-based muds (abbreviated herein as WBM) to prevent drill bit and bottom hole assembly component balling. This feature will also pertain to any other devices in contact with such formation materials.

Furthermore, the multi-layer low friction coatings disclosed herein when applied to the drill string assembly can simultaneously reduce contact friction, bit balling and reduce wear while not compromising the durability and mechanical integrity of casing in the cased hole situation. Thus, the multi-layer low friction coatings disclosed herein are “casing friendly” in that they do not degrade the life or functionality of the casing. The multi-layer low friction coatings disclosed herein are also characterized by low or no sensitivity to velocity weakening friction behavior. Thus, the drill stem assemblies provided with the multi-layer low friction coatings disclosed herein provide low friction surfaces with advantages in both mitigating stick-slip vibrations and reducing parasitic torque to further enable ultra-extended reach drilling.

In an artificial lift application, multi-layer low friction coatings applied to sucker rod couplings and plunger lifts provide benefit from reduced wear of the counterface material, which in this case is the tubing installed in the well. Coated devices require fewer workover interventions and can reduce production operating costs.

The multi-layer low friction coatings disclosed herein for drill stem assemblies thus provide for the following exemplary non-limiting advantages: i) mitigating stick-slip vibrations, ii) reducing torque and drag for extending the reach of extended reach wells, and iii) mitigating drill bit and other bottom hole component balling. These three advantages together with minimizing the parasitic torque may lead to significant improvements in drilling rate of penetration as well as durability of downhole drilling equipment, thereby also contributing to reduced non-productive time (abbreviated herein as NPT). The multi-layer low friction coatings disclosed herein not only reduce friction, but also withstand the aggressive downhole drilling environments requiring chemical stability, corrosion resistance, impact resistance, durability against wear, erosion and mechanical integrity (coating-substrate interface strength). The multi-layer low friction coatings disclosed herein are also amenable for application to complex shapes without damaging the substrate properties. Moreover, the multi-layer low friction coatings disclosed herein also provide low energy surfaces necessary to provide resistance to balling of bottom hole assembly components.

The body assembly of the coated device may include hardbanding or spraymetal alloy on at least a portion of the exposed outer surface to provide enhanced wear resistance and durability. Drill stem assemblies experience significant wear at the hardbanded regions since these are primary contact points between drill stem and casing or open borehole. The wear can be exacerbated by abrasive sand and rock particles becoming entrained in the interface and abrading the surfaces. The coatings on the coated drill stem assembly disclosed herein show high hardness properties to help mitigate abrasive wear. Using hardbanding that has a surface with a patterned design may promote the flow of abrasive particles past the coated hardbanded region and reduce the amount of wear and damage to the coating and hardbanded portion of the component. Spraymetal couplings are similarly used to prevent premature wear of the coupling material, possibly at a cost to the life of the tubing of the well. Using coatings in conjunction with patterned hardbanding or spraymetal material may further reduce wear due to abrasive particles.

Therefore, another aspect of the disclosure is the use of multi-layer low friction coatings on a hardbanding or spraymetal material on at least a portion of the exposed outer surface of the body assembly, where the surface has a patterned design that reduces entrainment of abrasive particles that contribute to wear. Abrasive sand and other rock particles suspended in the flow can travel into the interface between the body assembly and casing, tubing, or open borehole. It is therefore advantageous to use hardbanding or spraymetal material with multi-layer low friction coatings to provide for wear protection and low friction. It may be further advantageous to apply hardbanding or spraymetal material in a patterned design wherein grooves allow for the flow of particles without becoming entrained and abrading the interface. The multi-layer low friction coatings could be applied in any arrangement, but preferably it would be applied to the entire area of the pattern since to allow material to pass through the passageways of the pattern.

An aspect of the present disclosure relates to an advantageous coated device for subterraneous rotary drilling operations comprising: a body assembly with an exposed outer surface including a drill string coupled to a bottom hole assembly, a coiled tubing coupled to a bottom hole assembly, or a casing string coupled to a bottom hole assembly, hardbanding or spraymetal material on at least a portion of the exposed outer surface of the body assembly, where the surface may or may not have a patterned design, a multi-layer low friction coating on at least a portion of the hard material, and one or more buttering layers interposed between the hard material and the multi-layer low friction coating.

A further aspect of the present disclosure relates to an advantageous method for reducing friction in a coated device during subterraneous rotary drilling operations comprising: providing a drill stem assembly comprising a body assembly with an exposed outer surface including a drill string coupled to a bottom hole assembly, a coiled tubing coupled to a bottom hole assembly, or a casing string coupled to a bottom hole assembly, hardbanding or spraymetal material on at least a portion of the exposed outer surface of the body assembly, where the hard material surface may or may not have a patterned design, a multi-layer low friction coating on at least a portion of the hard material, and one or more buttering layers interposed between the hard material and the multi-layer low friction coating, and utilizing the coated device in subterraneous rotary drilling operations.

A further aspect of the present disclosure relates to the interposition of one or more buttering layer(s) between the outer surface of the body assembly, hardbanding, or spraymetal material and the multi-layer low friction coating. The buttering layer may be created or deposited as a result of one or more techniques including electrochemical or electroless plating methods, Plasma Vapor Deposition (PVD) or Plasma Assisted Chemical Vapor Deposition (PACVD) methods, carburizing, nitriding or boriding methods, or ultra-fine superpolishing methods. The buttering layer may be graded, and may serve several functional purposes, including but not limited to: decreased surface roughness, enhanced adhesion with other layer(s), enhanced mechanical integrity and performance.

A still further aspect of the present disclosure relates to the advantageous method of forming one or more buttering layer(s) interposed between the outer surface of the body assembly, hardbanding, or spraymetal material, and the multi-layer low friction coating. The buttering layer may be created or deposited as a result of one or more techniques including electrochemical or electroless plating methods, Plasma Vapor Deposition (PVD) or Plasma Assisted Chemical Vapor Deposition (PACVD) methods, carburizing, nitriding or boriding methods, or ultra-fine superpolishing methods. The buttering layer may be graded, and may serve several functional purposes, including but not limited to: decreased surface roughness, enhanced adhesion with other layer(s), enhanced mechanical integrity and performance.

In another embodiment, the buttering layer may be used in conjunction with hardbanding or spraymetal material, where the latter is on at least a portion of the exposed outer or inner surface to provide enhanced wear resistance and durability to the coated drill stem assembly, where the surface may have a patterned design that reduces entrainment of abrasive particles that contribute to wear. In addition, the multi-layer low friction coating may be deposited on top of the buttering layer.

### Further Details Regarding Individual Layers and Interfaces

Further details regarding the functional layers for use in the multi-layer low friction coatings disclosed herein are as follows:

### Fullerene Based Composites

Fullerene based composite coating layers which include fullerene-like nanoparticles may also be used as the functional layer(s). Fullerene-like nanoparticles have advantageous tribological properties in comparison to typical metals while alleviating the shortcomings of conventional layered materials (e.g., graphite, MoS₂). Nearly spherical fullerenes may also behave as nanoscale ball bearings. The main favorable benefit of the hollow fullerene-like nanoparticles may be attributed to the following three effects, (a) rolling friction, (b) the fullerene nanoparticles function as spacers, which eliminate metal to metal contact between the asperities of the two mating metal surfaces, and (c) three body material transfer. Sliding/rolling of the fullerene-like nanoparticles in the interface between rubbing surfaces may be the main friction mechanism at low loads, when the shape of nanoparticle is preserved. The beneficial effect of fullerene-like nanoparticles increases with the load. Exfoliation of external sheets of fullerene-like nanoparticles was found to occur at high contact loads (˜1 GPa). The transfer of delaminated fullerene-like nanoparticles appears to be the dominant friction mechanism at severe contact conditions. The mechanical and tribological properties of fullerene-like nanoparticles can be exploited by the incorporation of these particles in binder phases of coating layers. In addition, composite coatings incorporating fullerene-like nanoparticles in a metal binder phase (e.g., Ni—P electroless plating) can provide a film with self-lubricating and excellent anti-sticking characteristics suitable for the functional layer of the multi-layer low friction coatings disclosed herein.

### Super-Hard Materials (Diamond, Diamond-Like-Carbon)

Super-hard materials such as diamond, and diamond-like-carbon (DLC) may be used as the functional layer of the multi-layer low friction coatings disclosed herein. Diamond is the hardest material known to man and under certain conditions may yield low coefficient of friction when deposited by chemical vapor deposition (abbreviated herein as CVD).

In one advantageous embodiment, diamond-like-carbon (DLC) may be used as the functional layer of the multi-layer low friction coatings disclosed herein. DLC refers to amorphous carbon material that display some of the unique properties similar to that of natural diamond. Suitable diamond-like-carbon (DLC) layers or coatings may be chosen from ta-C, ta-C:H, DLCH, PLCH, GLCH, Si-DLC, titanium containing diamond-like-carbon (Ti-DLC), chromium containing diamond-like-carbon (Cr-DLC), Me-DLC, F-DLC, S-DLC, other DLC layer types, and combinations thereof. DLC coatings include significant amounts of sp³ hybridized carbon atoms. These sp³ bonds may occur not only with crystals—in other words, in solids with long-range order—but also in amorphous solids where the atoms are in a random arrangement. In this case there will be bonding only between a few individual atoms, that is short-range order, and not in a long-range order extending over a large number of atoms. The bond types have a considerable influence on the material properties of amorphous carbon films. If the sp² type is predominant the DLC film may be softer, whereas if the sp³ type is predominant, the DLC film may be harder.

DLC coatings may be fabricated as amorphous, flexible, and yet primarily sp³ bonded “diamond”. The hardest is such a mixture known as tetrahedral amorphous carbon, or ta-C. Such ta-C includes a high volume fraction (˜80%) of sp³ bonded carbon atoms. Optional fillers for the DLC coatings, include, but are not limited to, hydrogen, graphitic sp² carbon, and metals, and may be used in other forms to achieve a desired combination of properties depending on the particular application. The various forms of DLC coatings may be applied to a variety of substrates that are compatible with a vacuum environment and that are also electrically conductive. DLC coating quality is also dependent on the fractional content of alloying and/or doping elements such as hydrogen. Some DLC coating methods require hydrogen or methane as a precursor gas, and hence a considerable percentage of hydrogen may remain in the finished DLC material. In order to further improve their tribological and mechanical properties, DLC films are often modified by incorporating other alloying and/or doping elements. For instance, the addition of fluorine (F), and silicon (Si) to the DLC films lowers the surface energy and wettability. The reduction of surface energy in fluorinated DLC (F-DLC) is attributed to the presence of —CF2 and —CF3 groups in the film. However, higher F contents may lead to a lower hardness. The addition of Si may reduce surface energy by decreasing the dispersive component of surface energy. Si addition may also increase the hardness of the DLC films by promoting sp³ hybridization in DLC films. Addition of metallic elements (e.g., W, Ta, Cr, Ti, Mo) to the film can reduce the compressive residual stresses resulting in better mechanical integrity of the film upon compressive loading.

The diamond-like phase or sp³ bonded carbon of DLC is a thermodynamically metastable phase while graphite with sp² bonding is a thermodynamically stable phase. Thus the formation of DLC coating films requires non-equilibrium processing to obtain metastable sp³ bonded carbon. Equilibrium processing methods such as evaporation of graphitic carbon, where the average energy of the evaporated species is low (close to kT where k is Boltzman's constant and T is temperature in absolute temperature scale), lead to the formation of 100% sp² bonded carbons. The methods disclosed herein for producing DLC coatings require that the carbon in the sp³ bond length be significantly less than the length of the sp² bond. Hence, the application of pressure, impact, catalysis, or some combination of these at the atomic scale may force sp² bonded carbon atoms closer together into sp³ bonding. This may be done vigorously enough such that the atoms cannot simply spring back apart into separations characteristic of sp² bonds. Typical techniques either combine such a compression with a push of the new cluster of sp³ bonded carbon deeper into the coating so that there is no room for expansion back to separations needed for sp² bonding; or the new cluster is buried by the arrival of new carbon destined for the next cycle of impacts.

The DLC coatings disclosed herein may be deposited by physical vapor deposition, chemical vapor deposition, or plasma assisted chemical vapor deposition coating techniques. The physical vapor deposition coating methods include RF-DC plasma reactive magnetron sputtering, ion beam assisted deposition, cathodic arc deposition and pulsed laser deposition (PLD). The chemical vapor deposition coating methods include ion beam assisted CVD deposition, plasma enhanced deposition using a glow discharge from hydrocarbon gas, using a radio frequency (r.f.) glow discharge from a hydrocarbon gas, plasma immersed ion processing and microwave discharge. Plasma enhanced chemical vapor deposition (PECVD) is one advantageous method for depositing DLC coatings on large areas at high deposition rates. Plasma-based CVD coating process is a non-line-of-sight technique, i.e. the plasma conformally covers the part to be coated and the entire exposed surface of the part is coated with uniform thickness. The surface finish of the part may be retained after the DLC coating application. One advantage of PECVD is that the temperature of the substrate part does not generally increase above about 150° C. during the coating operation. The fluorine-containing DLC (F-DLC) and silicon-containing DLC (Si-DLC) films can be synthesized using plasma deposition technique using a process gas of acetylene (C₂H₂) mixed with fluorine-containing and silicon-containing precursor gases respectively (e.g., tetra-fluoro-ethane and hexa-methyl-disiloxane).

The DLC coatings disclosed herein may exhibit coefficients of friction within the ranges earlier described. The low COF may be based on the formation of a thin graphite film in the actual contact areas. As sp³ bonding is a thermodynamically unstable phase of carbon at elevated temperatures of 600 to 1500° C., depending on the environmental conditions, it may transform to graphite which may function as a solid lubricant. These high temperatures may occur as very short flash (referred to as the incipient temperature) temperatures in the asperity collisions or contacts. An alternative theory for the low COF of DLC coatings is the presence of hydrocarbon-based slippery film. The tetrahedral structure of a sp³ bonded carbon may result in a situation at the surface where there may be one vacant electron coming out from the surface, that has no carbon atom to attach to, which is referred to as a “dangling bond” orbital. If one hydrogen atom with its own electron is put on such carbon atom, it may bond with the dangling bond orbital to form a two-electron covalent bond. When two such smooth surfaces with an outer layer of single hydrogen atoms slide over each other, shear will take place between the hydrogen atoms. There is no chemical bonding between the surfaces, only very weak van der Waals forces, and the surfaces exhibit the properties of a heavy hydrocarbon wax. Carbon atoms at the surface may make three strong bonds leaving one electron in the dangling bond orbital pointing out from the surface. Hydrogen atoms attach to such surface which becomes hydrophobic and exhibits low friction.

The DLC coatings for the functional layer of the multi-layer low friction coatings disclosed herein also prevent wear due to their tribological properties. In particular, the DLC coatings disclosed herein demonstrate enhanced resistance to wear and abrasion making them suitable for use in applications that experience extreme contact pressure and severe abrasive environments.

### Buttering Layers

In yet another embodiment of the multi-layer low friction coatings herein, the device may further include one or more buttering layers interposed between the outer surface of the body assembly or hardbanding layer and the layers comprising the multi-layer low friction coating on at least a portion of the exposed outer surface.

In one embodiment of the nickel based alloy used as a buttering layer, the layer may be formed by electroplating. Electro-plated nickel may be deposited as a buttering layer with tailored hardness ranging from 150-1100, or 200 to 1000, or 250 to 900, or 300 to 700 Hv. Nickel is a silver-white metal, and therefore the appearance of the nickel based alloy buttering layer may range from a dull gray to an almost white, bright finish. In one form of the nickel alloy buttering layers disclosed herein, sulfamate nickel may be deposited from a nickel sulfamate bath using electoplating. In another form of the nickel alloy buttering layers disclosed herein, watts nickel may be deposited from a nickel sulfate bath. Watts nickel normally yields a brighter finish than does sulfamate nickel since even the dull watts bath contains a grain refiner to improve the deposit. Watts nickel may also be deposited as a semi-bright finish. Semi-bright watts nickel achieves a brighter deposit because the bath contains organic and/or metallic brighteners. The brighteners in a watts bath level the deposit, yielding a smoother surface than the underlying part. The semi-bright watts deposit can be easily polished to an ultra smooth surface with high luster. A bright nickel bath contains a higher concentration of organic brighteners that have a leveling effect on the deposit. Sulfur-based brighteners are normally used to achieve leveling in the early deposits, and a sulfur-free organic, such as formaldehyde, is used to achieve a fully bright deposit as the plating layer thickens. In another form, the nickel alloy used for the buttering layer may be formed from black nickel, which is often applied over an under plating of electrolytic or electroless nickel. Among the advantageous properties afforded by a nickel based buttering layer, include, but are not limited to, corrosion prevention, magnetic properties, smooth surface finish, appearance, lubricity, hardness, reflectivity, and emissivity.

In another embodiment, the nickel based alloy used as a buttering layer may be formed as an electroless nickel plating. In this form, the electroless nickel plating is an autocatalytic process and does not use externally applied electrical current to produce the deposit. The electroless process deposits a uniform coating of metal, regardless of the shape of the part or its surface irregularities; therefore, it overcomes one of the major drawbacks of electroplating, the variation in plating thickness that results from the variation in current density caused by the geometry of the plated part and its relationship to the plating anode. An electroless plating solution produces a deposit wherever it contacts a properly prepared surface, without the need for conforming anodes and complicated fixtures. Since the chemical bath maintains a uniform deposition rate, the plater can precisely control deposit thickness simply by controlling immersion time. Low-phosphorus electroless nickel used as a buttering layer may yield the brightest and hardest deposits. Hardness ranges from 60-70 R_{C} (or 697 Hv˜1076 Hv). In another form, medium-phosphorus or mid-phos may be used as a buttering layer, which has a hardness of approximately 40-42 R_{C} (or 392 Hv˜412 Hv). Hardness may be improved by heat-treating into the 60-62 R_{C} (or 697 H18 746 Hv) range. Porosity is lower, and conversely corrosion resistance is higher than low-phosphorous electroless nickel. High-phosphorous electroless nickel is dense and dull in comparison to the mid and low-phosphorus deposits. High-phosphorus exhibits the best corrosion resistance of the electroless nickel family; however, the deposit is not as hard as the lower phosphorus content form. High-phosphorus electroless nickel is a virtually non-magnetic coating. For the nickel alloy buttering layers disclosed herein, nickel boron may be used as an underplate for metals that require firing for adhesion. The NiP amorphous matrix may also include a dispersed second phase. Non-limiting exemplary dispersed second phases include: i) electroless NiP matrix incorporated fine nano size second phase particles of diamond, ii) electroless NiP matrix with hexagonal boron nitride particles dispersed within the matrix, and iii) electroless NiP matrix with submicron PTFE particles (e.g. 20-25% by volume Teflon) uniformly dispersed throughout coating.

In yet another embodiment, the buttering layer may be formed of an electroplated chrome layer to produce a smooth and reflective surface finish. Hard chromium or functional chromium plating buttering layers provide high hardness that is in the range of 700 to 1,000, or 750 to 950, or 800 to 900 Hᵥ, have a bright and smooth surface finish, and are resistant to corrosion with thicknesses ranging from 20 μm to 250, or 50 to 200, or 100 to 150 μm. Chromium plating buttering layers may be easily applied at low cost. In another form of this embodiment, a decorative chromium plating may be used as a buttering layer to provide a durable coating with smooth surface finish. The decorative chrome buttering layer may be deposited in a thickness range of 0.1 μm to 0.5 μm, or 0.15 μm to 0.45 μm, or 0.2 μm to 0.4 μm, or 0.25 μm to 0.35 μm. The decorative chrome buttering layer may also be applied over a bright nickel plating.

In still yet another embodiment, the buttering layer may be formed on the body assembly or hardbanding from a super-polishing process, which removes machining/grinding grooves and provides for a surface finish below 0.25 μm average surface roughness (Ra).

In still yet another embodiment, the buttering layer may be formed on the body assembly or hardbanding by one or more of the following non-limiting exemplary processes: PVD, PACVD, CVD, ion implantation, carburizing, nitriding, boronizing, sulfiding, siliciding, oxidizing, an electrochemical process, an electroless plating process, a thermal spray process, a kinetic spray process, a laser-based process, a friction-stir process, a shot peening process, a laser shock peening process, a welding process, a brazing process, an ultra-fine superpolishing process, a tribochemical polishing process, an electrochemical polishing process, and combinations thereof.

### Interfaces

The interfaces between various layers in the coating may have a substantial impact on the performance and durability of the coating. In particular, non-graded interfaces may create sources of weaknesses including one or more of the following: stress concentrations, voids, residual stresses, spallation, delamination, fatigue cracking, poor adhesion, chemical incompatibility, mechanical incompatibility. One non-limiting exemplary way to improve the performance of the coating is to use graded interfaces.

Graded interfaces allow for a gradual change in the material and physical properties between layers, which reduces the concentration of sources of weakness. One non-limiting exemplary way to create a graded interface during a manufacturing process is to gradually stop the processing of a first layer while simultaneously gradually commencing the processing of a second layer. The thickness of the graded interface can be optimized by varying the rate of change of processing conditions. The thickness of the graded interface may range from 0.01 to 10 μm, or 0.05 to 9 μm, or 0.1 to 8 μm, or 0.5 to 5 μm. Alternatively the thickness of the graded interface may range from 5% to 95% of the thickness of the thinnest adjacent layer.

### Terminal Layers

In some applications, it may be advantageous to use a particular coating from those provided above for the terminal layer. For example, in a bit-balling application for which the coating durability may be expected to be quite long, the hydrophobicity of the terminal layer will govern the ultimate resistance of the coated bit to balling. The structure of the coating layers provides sufficient support for a high integrity, hydrophobic layer to be applied in the expectation that it will remain intact for a significant duration.

Polishing is an important step to manage the stress state within the coating and to prevent fracturing of the coating layers, which may have high internal stresses. The coating may be polished before or after application of the terminal layer to achieve a surface roughness that ranges from 0.01 μm to 1.0 μm Ra, or 0.03 μm to 0.8 μm Ra, or 0.05 μm to 0.5 μm Ra, or 0.07 μm to 0.3 μm Ra, or 0.1 μm to 0.2 μm Ra. Surface polishing may occur at any point in the process of coating a device but is most often accomplished prior to application of the under layer and optionally at one or more additional step(s) in the coating process. Additionally, for some applications, it may be appropriate to polish the terminal layer to these specifications.

### Test Methods

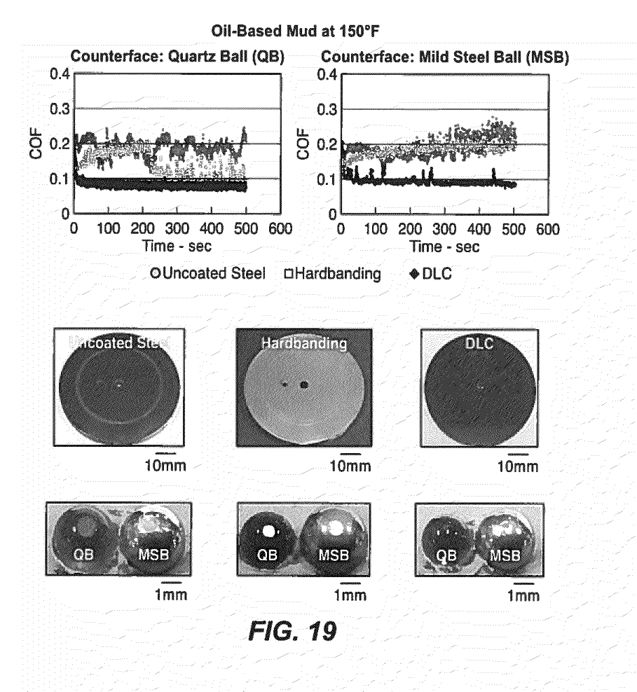

Coefficient of friction was measured using a ball-on-disk tester according to ASTM G99 test method. The test method requires two specimens—a flat disk specimen and a spherically ended ball specimen. A ball specimen, rigidly held by using a holder, is positioned perpendicular to the flat disk. The flat disk specimen slides against the ball specimen by revolving the flat disk of 2.7 inches diameter in a circular path. The normal load is applied vertically downward through the ball so the ball is pressed against the disk. The specific normal load can be applied by means of attached weights, hydraulic or pneumatic loading mechanisms. During the testing, the frictional forces are measured using a tension-compression load cell or similar force-sensitive devices attached to the ball holder. The friction coefficient can be calculated from the measured frictional forces divided by normal loads. The test was done at room temperature and 150° F. under various testing condition sliding speeds. Quartz or mild steel ball, 4 mm˜5 mm diameter, was utilized as a counterface material, and the coating material to be tested was applied to the disk component. The environment for reference conditions is oil-based drilling fluid at a sliding velocity of 0.6 m/s, with a 300 g load at 150° F. (see FIG. 19).

Velocity strengthening or weakening effects were evaluated by measuring the friction coefficient at various sliding velocities using the ball-on-disk friction test apparatus by ASTM G99 test method described above.

Hardness was measured according to ASTM C1327 Vickers hardness test method. The Vickers hardness test method consists of indenting the test material with a diamond indenter, in the form of a right pyramid with a square base and an angle of 136 degrees between opposite faces subjected to a load of 1 to 100 kgf. The full load is normally applied for 10 to 15 seconds. The two diagonals of the indentation left in the surface of the material after removal of the load are measured using a microscope and their average is calculated. The area of the sloping surface of the indentation is calculated. The Vickers hardness is the quotient obtained by dividing the kgf load by the square mm area of indentation. The advantages of the Vickers hardness test are that extremely accurate readings can be taken, and just one type of indenter is used for all types of metals and surface treatments. The hardness of thin coating layer (e.g., less than 100 μm) has been evaluated by nanoindentation wherein the normal load (P) is applied to a coating surface by an indenter with well known pyramidal geometry (e.g., Berkovich tip, which has a three-sided pyramid geometry). In nanoindentation, small loads and tip sizes are used to eliminate or reduce the effect from the substrate, so the indentation area may only be a few square micrometers or even nanometers. During the course of the nanoindentation process, a record of the depth of penetration is made, and then the area of the indent is determined using the known geometry of the indentation tip. The hardness can be obtained by dividing the load (kgf) by the area of indentation (square mm).

Wear performance was measured by the ball on disk geometry according to ASTM G99 test method. The amount of wear, or wear volume loss of the disk and ball, is determined by measuring the dimensions of both specimens before and after the test. The depth or shape change of the disk wear track was determined by laser surface profilometry and atomic force microscopy. The amount of wear, or wear volume loss, of the ball was determined by measuring the dimensions of specimens before and after the test. The wear volume of the ball was calculated from the known geometry and size of the ball.

Water contact angle was measured according to ASTM D5725 test method. The method referred to as “sessile drop method” uses a liquid contact angle goniometer that is based on an optical system to capture the profile of a pure liquid on a solid substrate. A drop of liquid (e.g., water) was placed (or allowed to fall from a certain distance) onto a solid surface. When the liquid settled (has become sessile), the drop retained its surface tension and became ovate against the solid surface. The angle formed between the liquid/solid interface and the liquid/vapor interface is the contact angle. The contact angle at which the oval of the drop contacts the surface determines the affinity between the two substances. That is, a flat drop indicates a high affinity, in which case the liquid is said to “wet” the substrate. A more rounded drop (by height) on top of the surface indicates lower affinity because the angle at which the drop is attached to the solid surface is more acute. In this case the liquid is said to “not wet” the substrate. The sessile drop systems employ high resolution cameras and software to capture and analyze the contact angle.

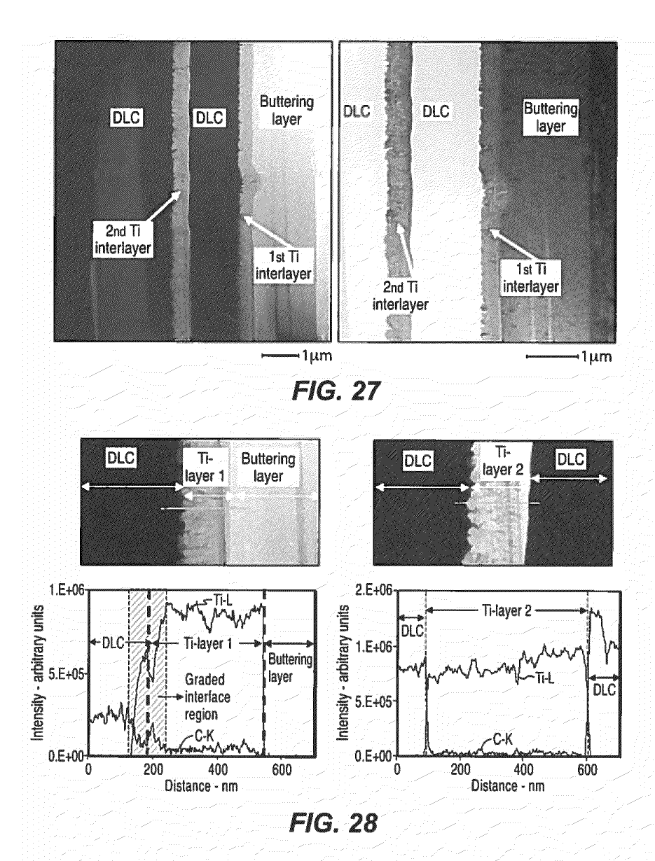

Scanning Electron Microscopy (SEM) studies were performed on a SEM operated at an accelerating voltage of 15-20 kV. Specimens for SEM study were prepared by cross-sectioning of coated substrates, followed by metallographic specimen preparation techniques for observation. Scanning Transmission Electron Microscopy (STEM) studies were performed on a microscope operated at 300 kV, equipped with a High Resolution Electron Energy-Loss Spectrometer (EELS) for compositional analysis. Operation in the STEM mode enabled acquisition of High Angle Annular Dark Field (HAADF) and Bright Field (BF) STEM images of the coating architectures. An example SEM image and HAADF-STEM image of a candidate coating is shown in FIG. 27.

After initial tests using the ball-on-disk method, additional tests were conducted with a different contact geometry. Several combinations of hardbanded substrate materials and coatings were evaluated in the second phase of the laboratory test program. To better simulate drilling conditions, a small block is pushed against a ring of about 2-inches diameter and one-quarter inch width in a “block-on-ring” test. These tests are conducted using an apparatus obtained from the Center for Tribology Research (CETR) that is commonly available.

### High-Sand CETR Block-on-Ring Test

This test was designed to simulate a high load (i.e., high contact pressure) and high abrasion environment. Ring specimens were rotated at various speeds and loads against a 6.36 mm wide steel block (hardness ˜300-350 Hv) at ambient temperature. The steel counterface was translated at a reciprocating speed of 1 mm/s perpendicular to the axis of the rotation of the ring in order to maintain uniformity in wear across the ring. The lubricating medium used for this study consisted of an oil-based slurry (Oil:Water=1:9) where water was used as a continuous phase. A poly-alpha-olefin oil of viscosity 8 cSt at 100° C. was used. This made the emulsion viscosity approximately 0.009 Pa.S at the test temperature which is comparable to the viscosity of a typical oil based mud under similar conditions. The slurry contained 50 wt. % sand (silica) of 150 μm mean diameter. The slurry was introduced into a containing chamber into which the ring was partially immersed for the duration of the test. The sand was fully homogenized in the lubricating medium prior to the test by introducing the slurry (in a sealed container) in a magnetic stirrer for 30 minutes. The rotation of the ring prevented the sedimentation of particles in the reservoir during the test. The friction coefficient values during each wear test were recorded automatically by a computer. The block wear (scar depth) was measured by scanning the wear track in a stylus profilometer while the coating wear was estimated based on the visual inspection. The block wear was used as the measure of counterface friendliness for any given coating. It should be noted that all coatings yielded low coefficient of friction (typically <0.1), as long the DLC remained intact during the CETR-BOR test.

### Modified ASTM G105 Abrasion Test

This is a wet sand/rubber wheel abrasion test designed to simulate a lower load and very severe abrasion environment. The standard ASTM G105 test is run using rubber wheels of four different Shore hardness. However, in order to avoid complexity, the ASTM G105 test was modified for this study where the specimen was tested in contact against a rotating rubber wheel of given shore hardness (A 58-62). Tests were run in a Falex wear tester keeping the rubber wheel partially submerged in a mixture of sand and water. The wheel was rotated at 200 rpm for 30 minutes against a vertically placed flat test specimen (1“X3”) under 30 lbf load. The diameter and width of the wheel was 9″ and 0.5″ respectively. The slurry contained 60% SiO₂ sand (round) and 40% water. At the completion of the tests, specimens have been investigated for coating durability and performance determined by (a) residual coating on plate (visual examination—percent of wear zone covered by top layer coating after test), (b) mass loss, (c) profilometry to measure wear scar depth and (d) microscopy. Reported wear scar depth is the maximum depth of the wear groove measured by scanning the stylus along the length of the wear track created by the rubber wheel through the middle of the wear zone width.

Profilometry was used to measure surface roughness. The roughness of the flat plates was measured with a Veeco Dektak nano-profilometer with a 5 μm tip. The resolution of the instrument is 5 μm in the x and y directions (limited by the tip) and less than 10 μin the z direction. At least three line scans of 1000 μm in length were taken on various sections of the surface. The scan speed was set at a low enough value that it would not result in a degradation of horizontal resolution past the limit of the stylus tip radius. In this case a value of 0.1 μm per data point was used. The raw data was then corrected for curvature and tilt and a high pass Fourier filter was applied to correct for the waviness of the surface (sinusoidal wave associated with the machining marks from previous material removal steps). The average Ra value for a flat hard banded plate was 0.039 μm before filters were applied and 0.02 μm after filtering the data.

Testing of drilling tool-joints was conducted using industry-standard test equipment in a number of configurations of substrate and coating materials. These tests were conducted at MOHR Engineering in Houston, Tex. Several coatings were applied to both steel and hardbanded rings of the same dimensions as a tool-joint. In this test, outer rings of casing material or sandstone are pushed against the coated joint that turns in a lathe fixture. At the same time, the outer ring reciprocates axially, and drilling mud is sprayed at the interface between the two bodies using nozzles and a circulating system.

The data from these test programs has guided the research direction prior to actual field testing of coated components and facilitated the understanding of those combinations of materials and application methods that would most likely be successful in a production environment.

### EXAMPLES

### Illustrative Example 1

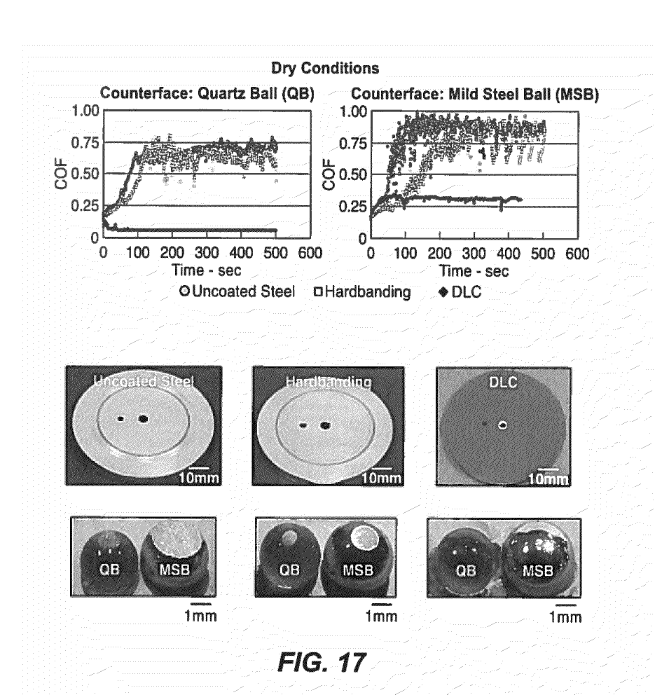

DLC coatings were applied on 4142 steel substrates by vapor deposition technique. DLC coatings had a thickness ranging from 1.5 to 25 micrometers. The hardness was measured to be in the range of 1,300 to 7,500 Vickers Hardness Number. Laboratory tests based on ball-on-disk geometry were conducted to demonstrate the friction and wear performance of the coating. Quartz ball and mild steel ball were used as counterface materials to simulate open hole and cased hole conditions respectively. In one ambient temperature test, uncoated 4142 steel, DLC coating and commercial state-of-the-art hardbanding weld overlay coating were tested in “dry” or ambient air condition against quartz counterface material at 300 g normal load and 0.6 m/sec sliding speed to simulate an open borehole condition. Up to 10 times improvement in friction performance (reduction of friction coefficient) over uncoated 4142 steel and hardbanding could be achieved in DLC coatings as shown in FIG. 17.

In another ambient temperature test, uncoated 4142 steel, DLC coating and commercial state-of-the-art hardbanding weld overlay coating were tested against mild steel counterface material to simulate a cased hole condition. Up to three times improvement in friction performance (reduction of friction coefficient) over uncoated 4142 steel and hardbanding could be achieved in DLC coatings as shown in FIG. 17. The DLC coating polished the quartz ball due to higher hardness of DLC coating than that of counterface materials (i.e., quartz and mild steel). However, the volume loss due to wear was minimal in both quartz ball and mild steel ball. On the other hand, the plain steel and hardbanding caused significant wear in both the quartz and mild steel balls, indicating that these are not very “casing friendly”.

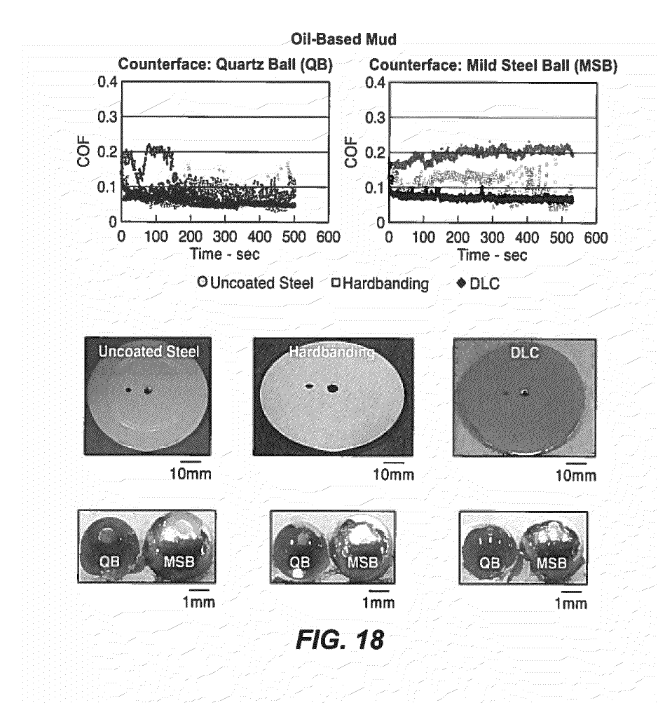

Ball-on-disk wear and friction coefficient were also tested at ambient temperature in oil based mud. Quartz ball and mild steel balls were used as counterface materials to simulate open hole and cased hole respectively. The DLC coating exhibited significant advantages over commercial hardbanding as shown in FIG. 18. Up to 30% improvement in friction performance (reduction of friction coefficient) over uncoated 4142 steel and hardbanding could be achieved with DLC coatings. The DLC coating polished the quartz ball due to its higher hardness than that of quartz. On the other hand, for the case of uncoated steel disk, both the mild steel and quartz balls as well as the steel disc showed significant wear. For a comparable test, the wear behavior of hardbanded disk was intermediate to that of DLC coated disc and the uncoated steel disc.

FIG. 19 depicts the wear and friction performance at elevated temperatures. The tests were carried out in oil based mud heated to 150° F., and again the quartz ball and mild steel ball were used as counterface materials to simulate an open hole and cased hole condition respectively. DLC coatings exhibited up to 50% improvement in friction performance (reduction of friction coefficient) over uncoated 4142 steel and commercial hardbanding. Uncoated steel and hardbanding caused wear damage in the counterface materials of quartz and mild steel balls, whereas, significantly less wear damage was observed in the counterface materials rubbed against the DLC coating.

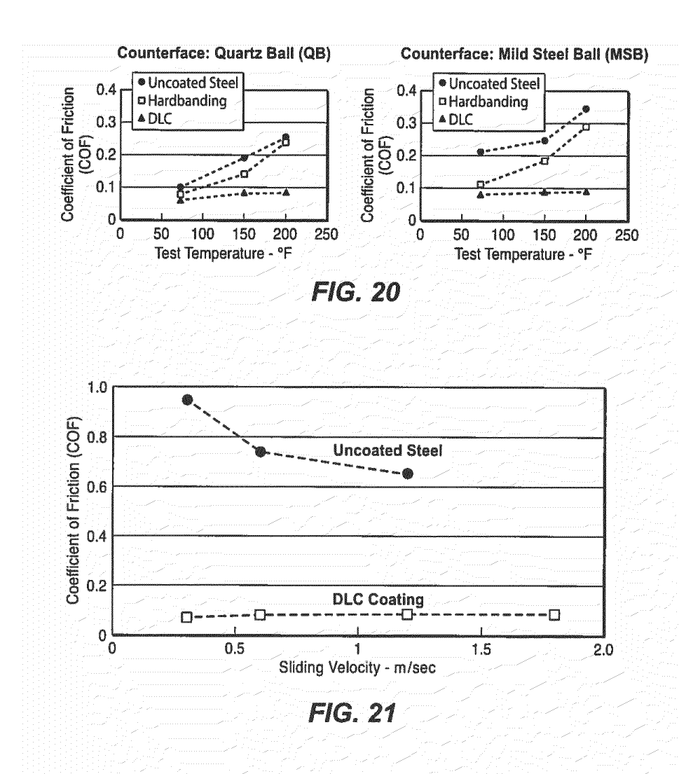

FIG. 20 shows the friction performance of DLC coating at elevated temperature (150° F. and 200° F.) in oil based mud. In this test data, the DLC coatings exhibited low friction coefficient at elevated temperature up to 200° F. However, the friction coefficient of uncoated steel and hardbanding increased significantly with temperature.

### Illustrative Example 2

In the laboratory wear/friction testing, the velocity dependence (velocity weakening or strengthening) of the friction coefficient for a DLC coating and uncoated 4142 steel was measured by monitoring the shear stress required to slide at a range of sliding velocity of 0.3 m/sec˜1.8 m/sec. Quartz ball was used as a counterface material in the dry sliding wear test. The velocity-weakening performance of the DLC coating relative to uncoated steel is depicted in FIG. 21. Uncoated 4142 steel exhibits a decrease of friction coefficient with sliding velocity (i.e. significant velocity weakening), whereas DLC coatings show no velocity weakening and indeed, there seems to be a slight velocity strengthening of COF (i.e. slightly increasing COF with sliding velocity), which may be advantageous for mitigating torsional instability, a precursor to stick-slip vibrations.

### Illustrative Example 3

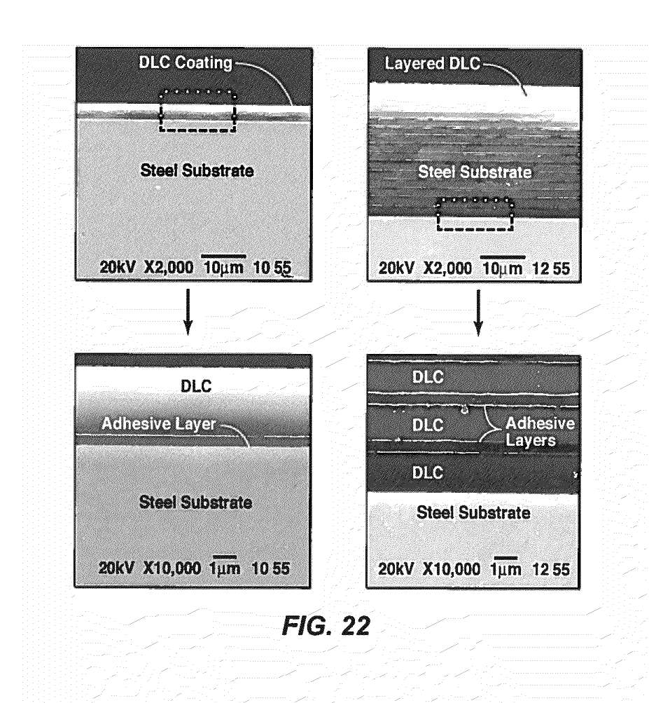

Multi-layered DLC coatings were produced in order to maximize the thickness of the DLC coatings to enhance their durability. In one form, the total thickness of the multi-layered DLC coating varied from 6 μm to 25 μm. FIG. 22 depicts SEM images of both single layer and multilayer DLC coatings for drill stem assemblies produced via PECVD. Adhesion promoting layers, in this case containing silicon, were used with the DLC coatings.

### Illustrative Example 4

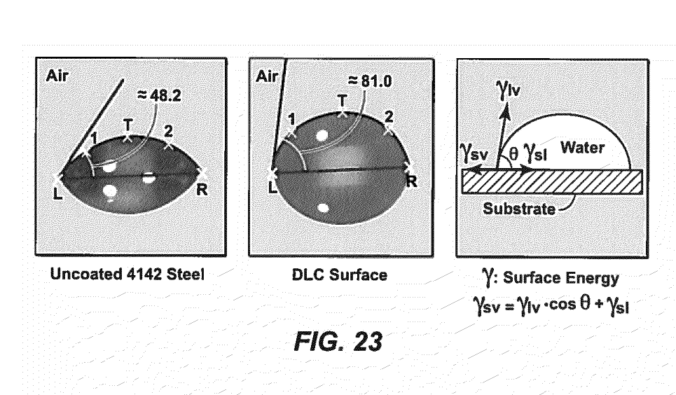

The surface energy of DLC coated substrates in comparison to an uncoated 4142 steel surface was measured via water contact angle. Results are depicted in FIG. 23 and indicate that a DLC coating provides a substantially lower surface energy in comparison to an uncoated steel surface. The lower surface energy may provide lower adherence surfaces for mitigating or reducing bit/stabilizer balling and to prevent formation of deposits of asphaltenes, paraffins, scale, and/or hydrates.

### Illustrative Example 5

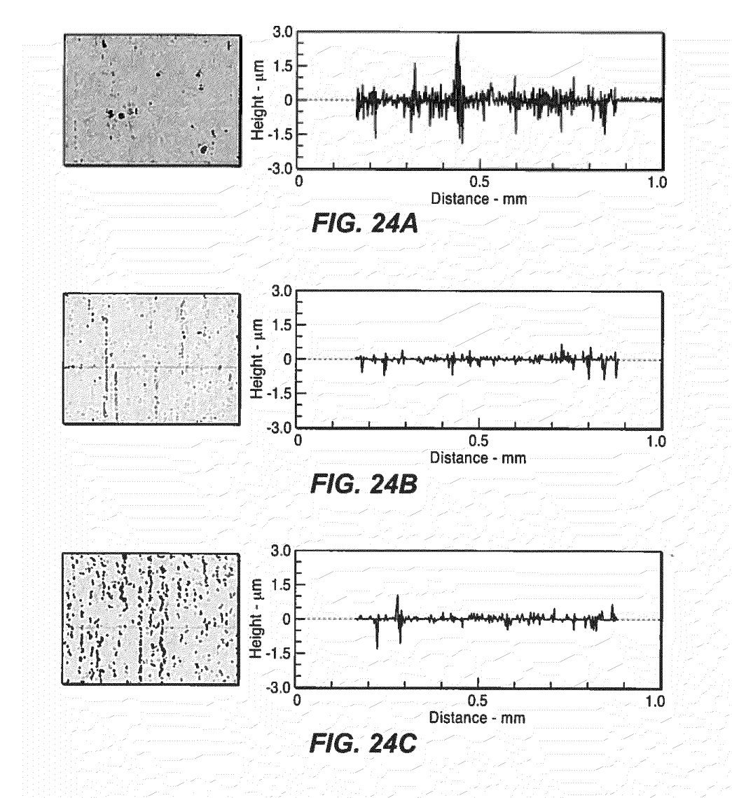

The roughness of unpolished, polished, and Ni—P plated rings are shown in FIG. 24. More particularly, FIG. 24 depicts roughness results obtained using an optical profilometer, which works based on the white light interferometry technique, from: a) unpolished ring; b) super-polished ring; and c) un-polished DLC coated ring with Ni—P buttering layer. Optical images of the scanned area are shown on the left and surface profiles are shown on the right. Scanning was performed three times on each sample in an area of 0.53 mm by 0.71 mm. The roughness of the unpolished ring appeared to be quite high (Rₐ˜0.28 μm). The super-polished ring had almost one order of magnitude lower roughness (Rₐ˜0.06 μm) than the unpolished ring. The electroless Ni—P plating on an unpolished ring provided about the same level of roughness (Rₐ˜0.08 μm) as the super-polished ring. This demonstrates that the deposition of a Ni—P buttering layer on a rough surface can improve the surface smoothness, and hence it may help avoid time consuming super-polishing steps prior to depositing low friction coatings.

### Illustrative Example 6

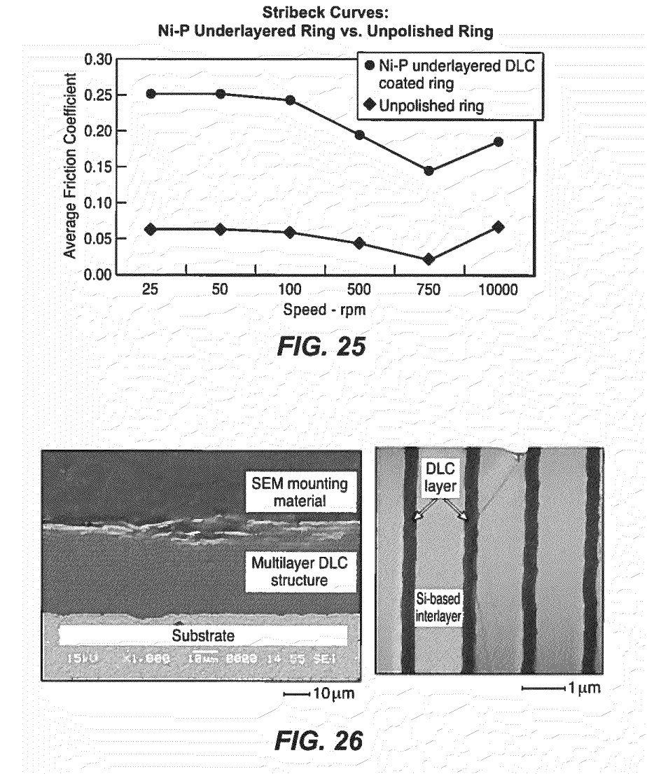

Friction and wear results for a bare unpolished ring versus a Ni—P buttering layer/DLC coated ring are shown in FIG. 25. More specifically, FIG. 25 depicts the average friction coefficient as a function of speed for Ni—P buttering layer/DLC coated ring and bare unpolished ring. Tribological tests were performed in a block-on-ring (BOR) tribometer. An oil based mud with 2% sand was used as a lubricant for the test. Tests were run at room temperature but other conditions (speed and load) were varied for different tests designed to evaluate friction and durability performance of the coated rings. The friction as a function of speed, which is also known as a Stribeck Curve, is shown in FIG. 25. Stribeck curves are typically used to demonstrate the friction response as a function of contact severity under lubricated conditions. In all cases, the Stribeck curve for the Ni—P buttering layer/DLC coated ring showed much lower friction both at low and high speed than the bare unpolished ring. Hence, it is evident that the Ni—P buttering layer that helped reduce surface roughness also provided significant friction benefit compared to the bare unpolished ring of higher roughness.

### Illustrative Example 7

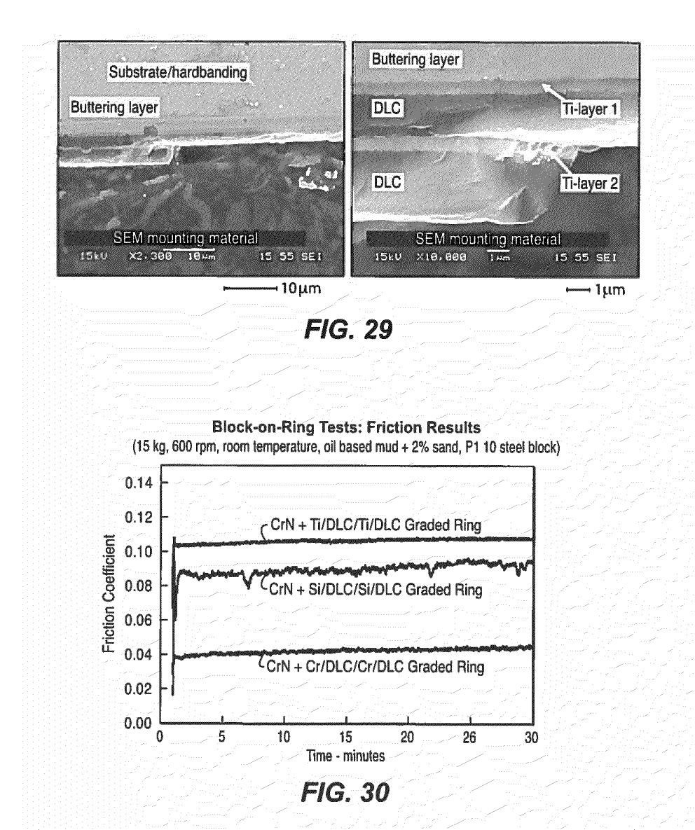

As an example, a 2-period DLC layer structure (with Ti as the adhesion-promoting layer material) was created where the first Ti layer was deposited using a graded interface approach (e.g. between the DLC layer and first Ti layer). The second Ti layer was created with a non-graded interface. The overall multilayer structure is shown in FIG. 27. The graded interface at the first Ti layer/DLC interface, and non-graded interface between the second Ti layer/DLC interface is shown in FIG. 28. More specifically, FIG. 27 shows High Angle Annular Dark Field (HAADF)-Scanning Transmission Electron Microscopy (STEM) image on the left and Bright-Field STEM image on the right disclosing the 2-period Ti-DLC structure. FIG. 28 depicts Electron Energy-Loss Spectroscopy (EELS) composition profiles showing the graded adhesive layer interface between Ti-layer 1 and DLC (left top and bottom) and the non-graded interface between Ti-layer 2 and DLC (right top and bottom). This 2-period DLC structure was coated on ring-shaped samples of appropriate geometry and tested under lab-scale (CETR-BOR) and large-scale (MOHR) testing conditions. Post-mortem analysis of the tested samples showed failure occurring through delamination at the non-graded interface between the 2^{nd} titanium adhesive layer and the DLC layer. This suggests that the creation of graded interfaces allows for improved interfacial adhesion performance. Representative images of the tested sample are shown in FIG. 29. More specifically, FIG. 29 depicts SEM images showing failure occurring through delamination at the non-graded interface between the DLC and the 2^{nd} Titanium adhesive layer. The thicknesses of the interfaces were measured as the length span between the 5% and 95% values of the limiting titanium intensity counts in each layer. The non-graded interfaces had thicknesses less than 20 μm, whereas the graded interfaces had thicknesses greater than 100 μm. An improvement in performance was observed in MOHR tests for the DLC structure with a graded interface, through preservation of the first DLC layer. The above structure successfully withstood side loads of 3500 lbf in large-scale MOHR tests—other coatings not engineered in similar fashion were not able to withstand this level of loading, leading to coating failure.

### Illustrative Example 8

The tribological performance of DLC coatings with various adhesion-promoting layers are discussed below. Durability and wear tests were performed in a block-on-ring (BOR) tribometer. FIG. 30 shows friction coefficient results as a function of time for a given test condition. Results reveal the differences in friction response with the selection of adhesive layer for the same DLC coating. The DLC coating with Ti layer provided the lowest friction. In addition, DLC coatings with Si and Cr adhesion-promoting layers also provided quite low friction (˜0.1 or less) and in all cases friction largely remained stable throughout the test. The block wear for the corresponding ring samples as shown in Table 1 below appeared to be in the same range suggesting that the change in contact pressure was not significant, and hence the block wear had no apparent influence on the friction response.

TABLE 1
Block wear results:

| Rings ran against the block | Wear scar width on the block |
|---|---|
| CrN + Ti/DLC/Ti/DLC Graded Ring | 3.1 mm |
| CrN + Si/DLC/Si/DLC Graded Ring | 2.1 mm |
| CrN + Cr/DLC/Cr/DLC Graded Ring | 3.7 mm |

### Illustrative Example 9

The two steps as outlined below were used to improve coating durability in severe abrasive/loading conditions.

### Step 1: Thick/Superthick Underlayer Structures:

Deposition of the DLC and adhesion promoting layers can be done through a process such as PACVD, where a source and/or target is used to deposit the DLC layer and the underlayer (e.g., CrₓN, TiₓN etc.). In some cases, the DLC layer (usually 1-5 μm) is deposited directly onto a substrate without any underlayer. In other cases, an underlayer (typically 2-5 μm) is deposited onto the substrate before DLC deposition (on the underlayer). The underlayer provides some mechanical integrity and toughness through load shielding while also providing some adhesion enhancement with the substrate. Generally, lower underlayer thicknesses help to improve overall coating performance in less severe conditions (e.g., low abrasion/load), the coating durability remains very poor under conditions where high abrasion/loads are encountered, mainly due to the plastic deformation of the substrate and abrasive wear of the DLC itself.

Finite Element Analysis (FEA) indicates that the transmission of loads through sand grains can initiate significant deformation of the underlying substrate at indentation depths of <1 μm, which is possible under high-load operating conditions. In fact, with larger sand grains (˜25-50 μm), the level of substrate plastic deformation (locally) can be quite high (>10%), leading to delamination and cracking of coating near the underlayer/substrate interface. Furthermore, the plastic deformation in the substrate can change the stress state in the underlayer/DLC interface, further reducing the load-bearing capacity of the DLC coating. The delamination/cracking of the coating is accelerated by the high compressive residual stress within the DLC coating which creates a complex local stress state conducive to coating removal (debonding).

By systematically increasing the underlayer thickness (to ≧10-15 μm), a more effective load-shielding layer can be created, thus significantly minimizing plastic deformation of the substrate. Experiments and abrasion test results (discussed below) illustrate the beneficial effect on coating durability as a function of increasing underlayer (CrN) thickness. The deposition of such thick underlayers is a technically challenging process, and may require a good control of stoichiometry (e.g., alternating CrN and Cr₂N layers to manage residual stress) and longer deposition times (typical deposition rates for CrN: 1 μm per 40-50 minutes).

Step 2: Thick/Superthick, Superhard and/or Composite DLC Structures:

While Step 1 (above) helps minimize plastic deformation of the substrate, it does not directly address the issue of DLC performance (i.e., durability) in severe abrasive conditions.

In wear involving an abrading medium (i.e., sand), the ratio of the hardness of the abrading medium and coating (i.e. surface being abraded) determines overall abrasion rate (according to the open literature). Under this premise, increasing coating hardness can help reduce abrasive wear. However, increased hardness of DLC coatings comes at the expense of increasing residual stress, which causes issues with coating cracking/ delamination/ spalling. Thus, this aspect leads to a focus on “optimal” hardness as opposed to “extreme” hardness. Our experiments indicate that hardness values of 2500-5500 (Hv) can be targeted, in combination with effective underlayer thicknesses, while not compromising coating durability (through cracking/spalling) severely for the thicker coating architectures.

Given a coating hardness, which in turn determines abrasion rate (assuming a gradual abrasion mechanism dominates as opposed to coating cracking/spalling), the overall durability of the coating depends on the coating thickness. By systematically increasing the thickness of the DLC layer (to values >15 μm), it has been shown that the coating durability can be improved in severe abrasive/loading conditions (discussed below). The deposition of such DLC layers is a technically challenging process requiring good control over interlayer adhesion (where applicable) and chemistry, management of residual stress, and process control to avoid chamber contamination, while requiring long deposition times (typical DLC deposition rates: 1 μm for every 80-100 minutes). In some cases, the beneficial effects of using harder functional layers such as ta-C, in combination with thicker underlayers and adhesion promoting layers, can also be realized.

The intrinsic abrasion resistance of the DLC depends upon the coating chemistry. A multilayer of a-C:H alternating with CrC can be created to enhance overall intrinsic toughness and abrasion resistance of the multilayer. The a-C:H phase is essential to provide the low friction properties, while the CrC phase provides toughness and higher resistance to abrasion. Results indicating superior abrasion resistance of such a multilayer are also presented (below). Alternatively, a combination of a harder functional layer (e.g., ta-C) with a targeted thickness of underlayer (such as CrN), may also yield superior abrasion resistance along with improved toughness and durability of the coating.

### Results Summarizing the Combined Benefits of Step 1 and Step 2:

Table 2 below shows a summary of nine different coating architectures tested to evaluate the effect of the approaches/steps outlined above (in some cases, values of adhesion promoting layer thicknesses are not explicitly reported). Two types of tests/experiments were designed and conducted to evaluate coating durability: CETR block on ring (high sand) test, and modified ASTM G105 test. These tests, and associated measurements from each are described above.

TABLE 2
Summary of coating architectures and test results

| | | | CETR Block | Residual coating | ASTM G105 | ASTM G105 | ASTM G105 % |
|---|---|---|---|---|---|---|---|
| | | | wear scar | after CETR | weight | max. scar | DLC intact |
| # | Coating | Description | depth (μm) | test (%) | loss (g) | depth (μm)* | after test |
| A | Thin coating | 2 μm CrN + | ~450 | <15 | 0.0516 | 27 | 0 |
| | | 1 μm DLC | | | | | |
| B | Moderate DLC | 2 μm CrN + | ~50 | ~50 | 0.0406 | 25 | 0 |
| | thickness | 5 μm DLC | | | | | |
| | | 5 μm CrN + | ~60 | >70 | 0.0083 | ~6-8 | 30 |
| | | 5 μm DLC | | | | | |
| C | Thick underlayer | 10 μm CrN + | ~150 | >80 | 0.0058 | ~8 | 0 |
| | | 5 μm DLC | | | | | |
| D | Thick underlayer + | 15 μm CrN + | ~200 | >90 | 0.0041 | ~10 | 40 |
| | thick DLC | 10 μm DLC | | | | | |
| E | Thick underlayer + | 15 μm CrN + | ~100 | >95 | 0.0028 | ~9 | 60 |
| | Thick | 10 μm | | | | | |
| | multilayer DLC) | Multilayer | | | | | |
| | | (CrC/DLC) | | | | | |
| F | Thick underlayer + | 15 μm CrN + | ~640 | >90 | 0.0008 | 0 | 100 |
| | Thick ta-C | 6 μm ta-C | | | | | |
| G | Thick underlayer + | 15 μm CrN + | ~320 | >95 | 0.0065 | ~2 | 60 |
| | Thick | 15 μm CrC + | | | | | |
| | multilayer + | 15 μm DLC | | | | | |
| | Thick DLC | | | | | | |
| H | taC/graded DLC | Thin Cr + | ~170 | >90 | 0.0237 | ~29 | 0 |
| | | 2 μm ta-C + | | | | | |
| | | 4 μm DLC | | | | | |
| I | Thick underlayer + | 7 μm CrN + | ~171 | >95 | 0.0016 | ~4 | >80 |
| | taC/graded | 2 μm taC + | | | | | |
| | DLC | 5 μm graded | | | | | |
| | | DLC | | | | | |

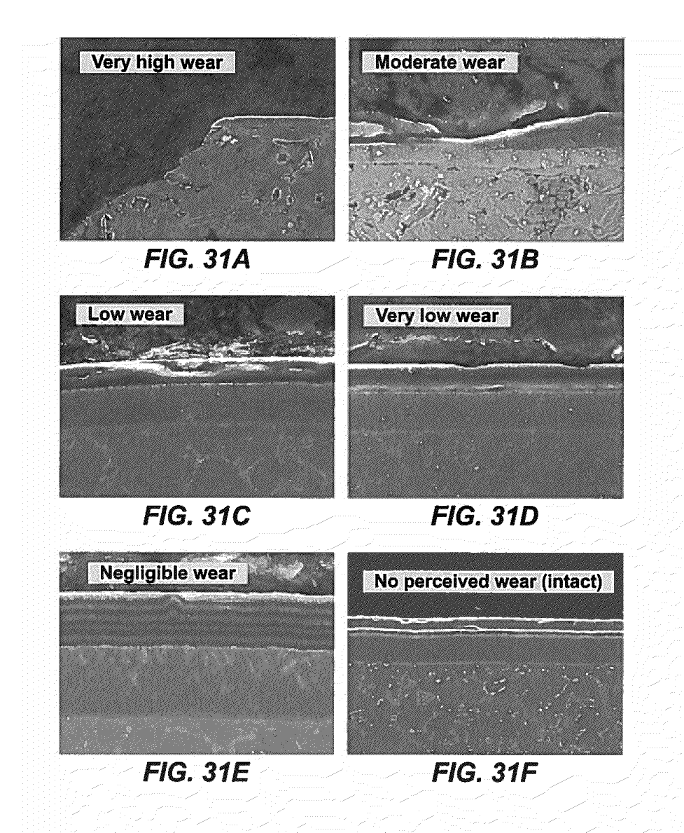

FIG. 31 illustrates microscopy investigations on some selective coatings (A-F from Table 1). Indications of a good coating performance and durability are: low block wear (i.e., good casing friendliness), high % of residual coating after CETR-BOR or ASTM test (i.e. good coating durability in high-load abrasive test), low weight loss and scar depth in ASTM G105 test (i.e. minimal coating removal and/or substrate removal during test).

The beneficial effects of (a) thick underlayers, (b) thick and multilayer composite DLC structures, and (c) superhard top layer coatings (terminal layers) are apparent from the results presented in this study. The cumulative effects of these approaches may yield a coating architecture (e.g., similar to architecture E, F) with the significantly improved overall durability among the evaluated specimens, in test conditions designed to simulate high loading/abrasion environments. When using weight loss in ASTM tests as a measure, it can be seen that Architecture E (thick underlayer+thick multilayer DLC) is approximately 20 times better than Architecture A (thin DLC) In addition, architecture F (thick underlayer+thick ta-C) is approximately 70-100 times better than Architecture A (thin DLC) in terms of overall durability as measured by resistance to wear/abrasion in the G105 test. The significant improvement in abrasion resistance using thick underlayer and thick coating was also apparent for the superhard ta-C coating (Architecture I vs. Architecture H).

### Illustrative Example 10

In another example, drilling tests were conducted with drilling subs equipped with test samples of coatings. The configuration of the test equipment was as shown at the top of FIG. 3, with a hardbanded area on a short sub configured with drilling tool joints. Each such test specimen was prepared as follows: obtain test sub, apply hardbanding to the tool joint using standard industry practices, grind and polish the hardbanding to obtain a surface finish better than 1.0 μm Ra, clean and prepare tool joint for coating in a PVD chamber, mask areas of the subs not to be coated, insert subs in chamber, and deposit multi-layer low friction coating.

There were two test series. Several of the improvements presented in this disclosure were conceived and tested in a laboratory environment. Representative results of these tests are provided in Table 3. Tests 1A and 1B used a first generation coating on two grades of hardbanding material. After about 93,000 ft. of travel, including both distance rotated and distance reciprocated, the first generation coating was completely removed on the specimens with the softer hardbanding (57 HRc (Rockwell C)), but on a specimen with a harder grade of hardbanding (65 HRc) there was about 15% of partial coating remaining. Both of these samples used the same first generation coating, and the only difference between these results was the hardness of the hardbanding underlayer.

In a second test series, new test subs were prepared in the same manner as the first subs. However, since there was an apparent correlation of longevity with hardness of the hardbanding, all subs were prepared with harder hardbanding material. However, there was a strong preference for a non-cracking hardbanding, and the hardest non-cracking hardbanding was selected. Two subs with different coatings applied on top of this hardbanding were prepared. In similar wells in the same field, with very similar deviated well profiles, the results showed that even though the total travel distance was greater, only a small amount of coating was removed during these tests, and most of the coating remained after more than 85,000 and 115,000 ft. of travel in the two second generation coating tests.

These test results were interpreted as follows: (1) Improvements resulting from using the techniques described in this disclosure provided a significant improvement in coating durability; and (2) Increased hardness of the hardbanding underlayer promotes coating durability. The role of hardbanding hardness was most clearly demonstrated in Test 1, however, the hardness of the underlayer in the second test series contributed to longer life as well. The deformation of the coating is less when a sand grain impinges on the coating if it is supported by a harder underlayer.

TABLE 3
Summary of underlayer hardness and test results

| | Coating | Underlayer | Approximate Feet | Coating |
|---|---|---|---|---|
| Test | Generation | Hardness | of Travel | Remaining |
| 1A | 1 | 57 HRc | 93,000 ft. | 0% |
| 1B | 1 | 65 HRc | 93,000 ft. | <15% |
| 2A | 2 | 61-63 HRc | 115,700 ft. | 99% |
| 2B | 2 | 61-63 HRc | 85,300 ft. | 95% |

### Coating Outer (Terminal) Layer Enhancements

The above coatings, methods, and coated bodies may be still further enhanced by modifying the coating process to mitigate areas, points, or regions within the outer coating layer(s) that may be susceptible to actual and potential stress concentrations. As demonstrated above, areas of stress concentration can be sources of coating delamination, cracking, fracture, or other failure mechanisms. Roughness features, surface irregularities, cracks in the coating or body, and other non-smooth irregularities on bodies to be coated or within coating layers may often translate or propagate these irregularities through and into adjacent coating layers. Surface irregularities of a body and/or layer have been determined to actually propagate through layers and into adjacent layers and into layer interfaces. Thereby, the coating layers may be subject to areas of stress concentration at each of these points of irregularity, resulting in potential points of failure initiation.

As the outer surface layer of the coating is the layer most in direct contact with wear surfaces and/or abrasive materials, stress irregularities that are inherently present within the outer surface layer, even at the interface of the coating surface layer (terminal layer) with an immediately adjacent underlayer, are areas within the coating that are at most at risk for complex stress concentration and consequent failure. Another objective of the methods and materials of this disclosure is to create an outer layer on the coating (the outer layer referred to herein as a “terminal layer”) that exhibits reduced irregularities therein and reduced irregularities at the interface with adjacent underlayer(s). The terminal layer should be applied to a surface that is essentially smooth (either inherently or by polishing), having a surface roughness Ra of preferably not more than 1.0 micrometer, or not more than 0.5 micrometers, or not more than 0.25 micrometers. Thereby, a terminal layer is provided as an outer layer of the coating that is not plagued from the onset with inherent stress concentration points originating from adjacent layers or the body. Additionally, it has been learned that intermediate or “underlayers” between the terminal layer and the body (and including the body surface if no underlayer is present) should also be of sufficient hardness to support the terminal layer against deformations due to point loading to avoid stress cracking or embrittlement cracking at the points of stress loading incurred during use. The improved coating may thereby deliver both improved stress uniformity through the outer terminal layer and underlayer, and exhibits improved stress management within the layers, due to reduced stress “concentration” points transmitted through adjacent layers and across interfaces. An intermediate step of polishing the layer(s) (e.g., the body and/or underlayer(s)) to receive the terminal low-friction layer (a.k.a.—terminal layer) to a surface roughness of not greater than 1.0 or not greater than 0.5, or even more preferably not greater than 0.25 micrometers Ra prior to deposition of the terminal layer thereon has been determined to provide improved coating stress tolerance and life. If desired, the terminal layer itself may be polished to similar values after deposition of the terminal layer thereon.

Proper cleaning of the device to remove the manufacturing, coating, and/or polishing components is another important step in the coating process. Cleaning of the device (body or one or more of the layers) to be coated may occur prior to one or more PVD, PACVD, and CVD coating process steps. The cleaning step includes: ultrasonication, chemical solvent bath (acidic or basic in nature), water bath, organic solvent, surfactant, detergent, forced air, mechanical wiping, etching, argon etching, plasma etching, ion etching, with argon, oxygen, hydrogen, or combinations, nitrogen, neon, inert gas ions, baking or extended temperature annealing to remove organic volatiles and grease. The optional processing steps of cleaning and polishing may occur beneficially at any step in the coating operation. Typically, it is beneficial to polish the device as one step after the device has been manufactured, followed by a cleaning step prior to coating of the device. Some coating processes may warrant intermediate or terminal layer coating polishing, depending on the process used and the intended application for the device.

Surprisingly, it has been determined that merely polishing a body to be coated alone is insufficient to mitigate stress areas within the coating. What has been learned is that for hard coatings such as those disclosed herein, the level of polishing should be substantial, so as to provide the maximum Ra of 0.25 micrometers prior to application of the terminal layer thereon. Such degree of smoothness of the underlayer has been determined as providing the proper foundation for application of a terminal layer that exhibits substantially similar uniformity and improved stress dispersion throughout the terminal layer. Often, after application of the terminal layer onto the polished layer, the terminal layer will itself inherently exhibit a surface roughness of not greater than 0.25 micrometers Ra after application of the terminal layer, without further polishing or treatment. In event some further polishing or treatment is needed, the amount of further polishing or treatment that is required is greatly reduced, as compared to the amount required for an outer layer that is merely applied to a coating layer or surface having an Ra of greater than 0.25.

In one aspect according to the present disclosure, a coated device is produced, such as a tool for use in abrasive or friction-prone services, the coated device comprising a structural body, at least a portion of which is to be coated. A coating is included on at least a portion of the body, the coating including a terminal ultra-low friction layer, and at least one underlayer positioned between the terminal ultra-low friction layer and the body; wherein prior to the addition of the underlayer, the body comprises a surface roughness of greater than 1.0 or even greater than 2.0 micrometers Ra; wherein prior to application of the terminal layer the at least one underlayer and/or body is polished to comprise a surface roughness of less than or equal to 1.0 or even more preferably not greater than 0.25 micrometers Ra prior to application of the terminal layer. In many embodiments, after addition of the terminal layer, the coating comprises a surface roughness of less than or equal to 1.0 micrometers Ra, or less than or equal to 0.5 micrometers Ra, or less than or equal to 0.25 micrometers Ra, and a coefficient of friction of less than or equal to 0.15.

In another aspect, portions of the body are coated and selected portions of the body are not coated. In yet another aspect a coated portion of the body comprises a body edge that provides a chamfered, rounded, or smoothed body shape transition across the body edge to avoid coating on or in sharp body edges, thereby mitigating stress concentrations at the edge or corner. In many embodiments, the terminal ultra-low friction terminal layer comprises a diamond like coating (DLC)

The relative smoothness of interfaces between various layers in the coating is another important factor. It has been found that non-graded interfaces may create sources of weaknesses including one or more of the following: stress concentrations, voids, residual stresses, spallation, delamination, fatigue cracking, poor adhesion, chemical incompatibility, mechanical incompatibility. Graded interfaces allow for a gradual change in the thickness or even of a “mixing overlap” of the material and physical properties between layers, which reduces the concentration of sources of weakness. One non-limiting exemplary way to create a graded interface during a manufacturing process is to gradually stop the processing of a first layer while simultaneously gradually commencing the processing of a second layer. The thickness of the graded interface can be optimized by varying the rate of change of processing conditions. The thickness of the graded interface may range from 0.01 to 10 μm, or 0.05 to 9 μm, or 0.1 to 8 μm, or 0.5 to 5 μm. Alternatively the thickness of the graded interface may range, for example, from 5% to 95% of the thickness of the thinnest adjacent layer. For these reasons, it is anticipated that a terminal layer(s) may beneficially be applied to underlayers using a grading technique or process.

According to another aspect disclosed herein, a coated device may be prepared according to a method comprising: providing a body having a surface roughness of greater than 0.25 micrometers Ra on a portion of the body for receiving a coating thereon; applying at least one underlayer to the body; polishing the at least one underlayer to comprise a surface roughness of less than or equal to 0.25 micrometers Ra; thereafter, applying a terminal ultra-low friction layer to the at least one underlayer, wherein after addition of the terminal layer the coating inherently comprises a surface roughness of less than or equal to 0.25 micrometers Ra and a coefficient of friction of less than or equal to 0.15.

The method may further comprise providing a body initially having a surface roughness of from greater than 0.25 micrometers Ra to 2.0 micrometers Ra, or from 0.25 to 1.2 micrometers, or from 0.25 to 1.0 micrometers, Ra. A key step in the process is ensuring that an underlayer between the body and preferably immediately prior to the terminal is layer provides a surface roughness of not greater than 0.25 micrometers Ra. After addition of the terminal layer, the coated device may then provide a terminal layer surface roughness of also not greater than 0.25 micrometers Ra, or even not greater than 0.20 in some embodiments, without requiring further additional polishing or finishing to the outer surface of the coating to achieve this level of surface roughness. Thereby, the terminal ultra-low friction layer provides an outer layer to the coating, this outer layer providing improved performance verses prior art outer layers by having mitigated stress concentrations within the terminal layer (both during coating application and use) and uniform stress distribution throughout the terminal layer during device use. In other embodiments, the body may also be provided with at least one of a hardbanding, boriding, nitriding, or body surface treatment layer between the coating and the body.

Applicants have attempted to disclose all embodiments and applications of the disclosed subject matter that could be reasonably foreseen. However, there may be unforeseeable, insubstantial modifications that remain as equivalents. While the present disclosure has been described in conjunction with specific, exemplary embodiments thereof, it is evident that many alterations, modifications, and variations will be apparent to those skilled in the art in light of the foregoing description without departing from the spirit or scope of the present disclosure. Accordingly, the present disclosure is intended to embrace all such alterations, modifications, and variations of the above detailed description.

All patents, test procedures, and other documents cited herein, including priority documents, are fully incorporated by reference to the extent such disclosure is not inconsistent with this disclosure and for all jurisdictions in which such incorporation is permitted.

When numerical lower limits and numerical upper limits are listed herein, ranges from any lower limit to any upper limit are contemplated.

What is claimed is:

1. A coated device comprising:
a body;
a coating on at least a portion of a surface of the body, wherein the coating comprises,
a terminal layer, and
at least one underlayer positioned between the terminal layer and the body, the underlayer comprising a hardness of greater than 61 HRc;
wherein prior to the addition of the terminal layer, at least one of the body and the underlayer is polished to a surface roughness of less than or equal to 1.0 micrometer Ra.

2. The coated device of claim 1, wherein prior to application of the terminal layer the at least one underlayer comprises at least one of a hardbanding, boriding, nitriding, or carburizing and is polished to a surface roughness of less than or equal to 0.5 micrometer Ra.

3. The coated device of claim 1, wherein prior to application of the terminal layer the at least one underlayer comprises at least one of a hardbanding, boriding, nitriding, or carburizing and has a Rockwell hardness of at least 61 HRc and is polished to a surface roughness of less than or equal to 1.0 micrometer Ra.

4. The coated device of claim 1, wherein the at least one underlayer has a Rockwell hardness of at least 63 HRc.

5. The coated device of claim 1, wherein the at least one underlayer has a Rockwell hardness of at least 65 HRc.

6. The coated device of claim 1, wherein prior to application of the terminal layer the at least one underlayer is polished to a surface roughness of less than or equal to 0.5 micrometers Ra.

7. The coated device of claim 1, wherein prior to application of the terminal layer the at least one underlayer is polished to a surface roughness of less than or equal to 0.25 micrometers Ra.

8. The coated device of claim 1, wherein prior to application of the underlayer, the body is polished to a surface roughness of less than or equal to 0.5 micrometers Ra.

9. The coated device of claim 1, wherein prior to application of the underlayer, the body is polished to a surface roughness of less than or equal to 0.25 micrometers Ra.

10. The coated device of claim 1, wherein prior to application of the terminal layer the at least one underlayer comprises at least one of a hardbanding, boriding, nitriding, or carburizing layer, that has a Rockwell hardness of greater than 61 HRc and is polished to a surface roughness of less than or equal to 0.25 micrometers Ra.

11. The coated device of claim 1, wherein after addition of the terminal layer the coating inherently comprises a surface roughness of less than or equal to 0.25 micrometers Ra and a coefficient of friction of less than or equal to 0.15.

12. The coated device of claim 1, wherein after addition of the terminal layer the coating inherently comprises a coefficient of friction of less than or equal to 0.15.

13. The coated device of claim 1, wherein after addition of the terminal layer the coating is polished to comprise a coefficient of friction of less than or equal to 0.15.

14. The coated device of claim 1, wherein after addition of the terminal layer the coating is polished to comprise a surface roughness of less than or equal to 0.25 micrometers Ra.

15. The coated device of claim 1, wherein only selected portions of the body are coated and other portions of the body are masked to avoid coating.

16. The coated device of claim 1 wherein a coated portion of the body that comprises a body edge provides a chamfered, rounded, or smoothed body shape transition across the body edge to avoid coating on or in sharp body edges.

17. The coated device of claim 1 wherein after addition of the terminal layer, the coated device is polished to comprise a surface roughness of less than 0.20 microns Ra.

18. The coated device of claim 1, wherein the undercoating further comprises at least one of a hardbanding, boriding, nitriding, or carburizing surface treatment to the body.

19. The coated device of claim 1 wherein the body includes recessed features relative to a normal surface of the body, the recessed features ranging in depth from 1 mm to 5 mm and providing for passage of abrasive particles therethrough.

20. The coated device of claim 1, wherein a surface of the body includes a repeating arrangement of at least one of grooves, slots, recessed dimples, proud dimples, raised bands, raised faces, and combinations thereof, relative to a normal surface of the body.

21. The coated device of claim 1, wherein the coating further comprises a buttering layer including at least one of a buffer layer, an adhesive layer, and combinations thereof.

22. The coated device of claim 1, wherein the coating further comprises at least one layer that is graded at an interface of the at least one layer with the body or another immediately adjacent layer.

23. The coated device of claim 22, wherein the terminal layer is graded at the interface between the terminal layer and the underlayer.

24. The coated device of claim 13 wherein the underlayer is graded at the interface between the underlayer and the body.

25. The coated device of claim 1, wherein the terminal layer overlaps the underlayer directly to the body and the terminal layer is graded at an interface between the terminal layer and the body.

26. The coated device of claim 1, wherein the coating is applied to the body in a repeating patterned fashion with respect to uncoated areas of the body.

27. The coated device of claim 1 wherein the coating further comprises one or more additional layers intermediate the body and the terminal layer.

28. The coated device of claim 1, wherein the terminal layer comprises at least one of an amorphous alloy, an electroless nickel-phosphorous composite, graphite, MoS.sub.2, WS.sub.2, a fullerene based composite, a boride based cermet, a quasicrystalline material, a diamond based material, diamond-like-carbon (DLC), boron nitride, carbon nanotubes, graphene sheets, metallic particles of high aspect ratio (i.e. relatively long and thin), ring-shaped materials including carbon nanorings, oblong particles and combinations thereof.

29. The coated device of claim 20, wherein the at least one of the underlayer and the terminal layer comprises at least one of diamond based material that is chemical vapor deposited (CVD) diamond and polycrystalline diamond compact (PDC).

30. The coated device of claim 1, wherein the terminal layer comprises diamond-like-carbon (DLC).

31. The coated device of claim 30, wherein the diamond-like-carbon (DLC) is chosen from: ta-C, ta-C:H, DLCH, PLCH, GLCH, Si-DLC, Ti-DLC, Cr-DLC, N-DLC, O-DLC, B-DLC, Me-DLC, F-DLC, S-DLC and combinations thereof.

32. The coated device of claim 1, wherein the terminal ultra-low friction layer provides a surface energy less than 1 J/m.sup.2.

33. The coated device of claim 1, wherein the terminal layer on at least a portion of the exposed outer surface of the body assembly provides a hardness greater than 400 VHN.

34. The coated device of claim 1, wherein the coating provides at least 3 times greater wear resistance than an uncoated device.

35. The coated device of claim 1, wherein a water contact angle of the terminal layer is inherently greater than 60 degrees.

36. The coated device of claim 1, wherein a thickness of the terminal layer is in a range of from 0.5 microns to 5000 microns.

37. The coated device of claim 1, wherein a thickness of each layer of the coating is in a range of from 0.001 to 5000 microns.

38. The coated device of claim 1, wherein the underlayer further comprises at least one of a metal, alloys, carbide, nitride, carbo-nitride, boride, sulfide, silicide, and oxide of at least one of silicon, aluminum, copper, molybdenum, titanium, chromium, tungsten, tantalum, niobium, vanadium, zirconium, hafnium, and combinations thereof.

39. The coated device of claim 1, wherein the underlayer further comprises a buttering layer comprising at least one of a stainless steel, a chrome-based alloy, an iron-based alloy, a cobalt-based alloy, a titanium-based alloy, or a nickel-based alloy, alloys or carbides or nitrides or carbo-nitrides or borides or silicides or sulfides or oxides of at least one of the following elements: silicon, titanium, chromium, aluminum, copper, iron, nickel, cobalt, molybdenum, tungsten, tantalum, niobium, vanadium, zirconium, hafnium, and combinations thereof.

40. The coated device of claim 1, wherein at least one of the layers of the coating is formed by one or more processes chosen from: PVD, PACVD, CVD, ion implantation, carburizing, nitriding, boronizing, sulfiding, siliciding, oxidizing, an electrochemical process, an electroless plating process, a thermal spray process, a kinetic spray process, a laser-based process, a friction-stir process, a shot peening process, a laser shock peening process, a welding process, a brazing process, an ultra-fine superpolishing process, a tribochemical polishing process, an electrochemical polishing process, and combinations thereof.

41. The coated device of claim 1, wherein the body comprises two substantially coaxial cylindrically shaped bodies that are both coated with the coating and that are in relative motion with respect to each other and are in at least intermittent contact with each other.

42. The coated device of claim 1, wherein the body comprises at least one of an iron based material, carbon steel, steel alloy, stainless steel, Al-base alloy, Ni-base alloy, Ti-base alloy, Tg-based alloy, ceramics, cermets, polymers, tungsten carbide cobalt, and combinations thereof.

43. A method of preparing a coated device, the method comprising:
providing a body to be coated on at least a portion of a surface of the body;
polishing the body to comprise a surface roughness of less than or equal to 1.0 micrometer Ra;
applying a coating to the at least a portion of the surface of the body, wherein applying the coating comprises;
applying at least one underlayer to the polished body, the at least one underlayer comprising a hardness of at least 61 HRc;
polishing at least one of the at least one underlayer and the body to comprise a surface roughness of less than or equal to 1.0 micrometers Ra;
thereafter, applying a terminal layer to the polished at least one of the underlayer and the body.

44. The method of claim 43, wherein prior to application of the terminal layer the at least one underlayer comprises at least one of a hardbanding, boriding, nitriding, and carburizing.

45. The method of claim 44, wherein prior to application of the terminal layer the at least one of a hardbanding, boriding, nitriding, and carburizing is polished to a surface roughness of less than or equal to 0.5 micrometer Ra.

46. The method of claim 44, wherein prior to application of the terminal layer the at least one of a hardbanding, boriding, nitriding, and carburizing is polished to a surface roughness of less than or equal to 0.25 micrometer Ra.

47. The method of claim 43, wherein prior to application of the coating, the body is polished to comprise a surface roughness of less than or equal to 0.5 micrometers Ra.

48. The coated device of claim 43, wherein prior to application of the terminal layer the at least one underlayer comprises at least one of a hardbanding, boriding, nitriding, or carburizing and has a Rockwell hardness of at least 61 HRc and is polished to a surface roughness of less than or equal to 1.0 micrometer Ra.

49. The method of claim 43, wherein the applied at least one underlayer has a Rockwell hardness of at least 63 HRc.

50. The method of claim 43, wherein the applied at least one underlayer has a Rockwell hardness of at least 65 HRc.

51. The method of claim 43 wherein prior to application of the terminal layer, the method further comprises polishing the at least one underlayer to a surface roughness of less than or equal to 0.5 micrometers Ra.

52. The method of claim 43, wherein prior to application of the terminal layer the method further comprises polishing the at least one underlayer to a surface roughness of less than or equal to 0.25 micrometers Ra.

53. The method of claim 43, wherein prior to application of the terminal layer the at least one underlayer comprises at least one of a hardbanding, boriding, nitriding, or carburizing layer, that has a Rockwell hardness of greater than 61 HRc and is polished to a surface roughness of less than or equal to 0.25 micrometers Ra.

54. The method of claim 43, wherein after addition of the terminal layer the coating inherently comprises a surface roughness of less than or equal to 0.25 micrometers Ra.

55. The method of claim 43, wherein after addition of the terminal layer the coating inherently comprises a coefficient of friction of less than or equal to 0.15.

56. The method of claim 43, further comprising after addition of the terminal layer polishing the coating to comprise a coefficient of friction of less than or equal to 0.15.

57. The method of claim 43, further comprising after addition of the terminal layer polishing the terminal layer to comprise a surface roughness of less than or equal to 0.25 micrometers Ra.

58. The method of claim 43, further comprising masking portions of the body to coat only selected portions of the body.

59. The method of claim 43, further comprising preparing the body by providing a chamfered, rounded, or smoothed body shape transition across a body edge to avoid coating on or in sharp body edges.

60. The method of claim 43, wherein the undercoating further comprises at least one of a hardbanding, boriding, nitriding, or carburizing surface treatment to the body.

61. The method of claim 43, further comprising providing the body with recessed features relative to a normal surface of the body, the recessed features ranging in depth from 1 mm to 5 mm and providing for passage of abrasive particles therethrough.

62. The method of claim 43, further comprising providing the body with a repeating arrangement of at least one of grooves, slots, recessed dimples, proud dimples, raised bands, raised faces, and combinations thereof, relative to a normal surface of the body.

63. The method of claim 43, wherein the coating further comprises a buttering layer including at least one of a buffer layer, an adhesive layer, and combinations thereof.

64. The method of claim 43, further comprising applying at least one of the underlayer and the terminal layer with graded thickness at an interface with at least one of an adjacent layer and the body.

65. The method of claim 43, further comprising applying the terminal layer in a graded fashion at an interface between the terminal layer and the underlayer.

66. The method of claim 43, further comprising applying the underlayer in a graded fashion at the interface between the underlayer and the body.

67. The method of claim 43, further comprising applying the terminal layer to overlap an edge of the underlayer directly to the body and applying the terminal layer in a graded fashion at an interface between the terminal layer and the body.

68. The method of claim 43, further comprising applying the coating to the body in a repeating pattern fashion with respect to uncoated areas of the body.

69. The method of claim 43, further comprising applying an additional layer in the coating, intermediate the body and the terminal layer.

70. The method of claim 43, wherein the terminal layer comprises at least one of an amorphous alloy, an electroless nickel-phosphorous composite, graphite, MoS.sub.2, WS.sub.2, a fullerene based composite, a boride based cermet, a quasicrystalline material, a diamond based material, diamond-like-carbon (DLC), boron nitride, carbon nanotubes, graphene sheets, metallic particles of high aspect ratio (i.e. relatively long and thin), ring-shaped materials including carbon nanorings, oblong particles and combinations thereof.

71. The method of claim 43, wherein the at least one of the underlayer and the terminal layer comprises at least one of diamond based material that is chemical vapor deposited (CVD) diamond and polycrystalline diamond compact (PDC).

72. The method of claim 43, wherein the terminal layer comprises diamond-like-carbon (DLC).

73. The method of claim 72, wherein the diamond-like-carbon (DLC) is chosen from: ta-C, ta-C:H, DLCH, PLCH, GLCH, Si-DLC, Ti-DLC, Cr-DLC, N-DLC, O-DLC, B-DLC, Me-DLC, F-DLC, S-DLC and combinations thereof.

74. The method of claim 43, further comprising applying the terminal layer with a thickness of in a range of from 0.5 microns to 5000 microns.

75. The method of claim 43, further comprising applying each layer of the underlayer with a thickness range of from 0.001 to 5000 microns.

76. The method of claim 43, further comprising providing the underlayer with at least one of a metal, alloys, carbide, nitride, carbo-nitride, boride, sulfide, silicide, and oxide of at least one of silicon, aluminum, copper, molybdenum, titanium, chromium, tungsten, tantalum, niobium, vanadium, zirconium, hafnium, and combinations thereof.

77. The method of claim 43, further comprising providing the underlayer with a buttering layer comprising at least one of a stainless steel, a chrome-based alloy, an iron-based alloy, a cobalt-based alloy, a titanium-based alloy, or a nickel-based alloy, alloys or carbides or nitrides or carbo-nitrides or borides or silicides or sulfides or oxides of at least one of the following elements: silicon, titanium, chromium, aluminum, copper, iron, nickel, cobalt, molybdenum, tungsten, tantalum, niobium, vanadium, zirconium, hafnium, and combinations thereof.

78. The method of claim 43, further comprising forming at least one of the layers of the coating by one or more processes chosen from: PVD, PACVD, CVD, ion implantation, carburizing, nitriding, boronizing, sulfiding, siliciding, oxidizing, an electrochemical process, an electroless plating process, a thermal spray process, a kinetic spray process, a laser-based process, a friction-stir process, a shot peening process, a laser shock peening process, a welding process, a brazing process, an ultra-fine superpolishing process, a tribochemical polishing process, an electrochemical polishing process, and combinations thereof.

79. The method of claim 78, further comprising applying the diamond-like-carbon (DLC) by at least one of physical vapor deposition, chemical vapor deposition, and plasma assisted chemical vapor deposition coating techniques.

80. The method of claim 79, wherein the physical vapor deposition coating method is selected from at least one of RF-DC plasma reactive magnetron sputtering and ion beam assisted coating.

81. The method of claim 43, further comprising cleaning the body after polishing and prior to applying the terminal layer.

82. The method of claim 43, further comprising cleaning the underlayer after polishing prior to applying the terminal layer.
